(19) United States
(12) Patent Application Publication
(10) Pub. No.: US 2026/0025971 A1
(43) Pub. Date: Jan. 22, 2026

(54) ADVANCED 3D MEMORY CELLS AND ARRAY ARCHITECTURES AND PROCESSES

(71) Applicant: NEO Semiconductor, Inc., San Jose, CA (US)

(72) Inventor: Fu-Chang Hsu, San Jose, CA (US)

(21) Appl. No.: 18/939,458

(22) Filed: Nov. 6, 2024

Related U.S. Application Data
(60) Provisional application No. 63/671,793, filed on Jul. 16, 2024.
(60) Provisional application No. 63/672,104, filed on Jul. 16, 2024.
(60) Provisional application No. 63/672,260, filed on Jul. 17, 2024.
(60) Provisional application No. 63/672,718, filed on Jul. 18, 2024.
(60) Provisional application No. 63/675,195, filed on Jul. 24, 2024.
(60) Provisional application No. 63/676,913, filed on Jul. 30, 2024.
(60) Provisional application No. 63/704,214, filed on Oct. 7, 2024.

(51) Int. Cl. H10B 12/00

(52) U.S. Cl. CPC H10B 12/20; H10B 12/01

(57) ABSTRACT

Various advanced 3D memory cells, array architectures, and processes are disclosed. In an embodiment, a method includes forming a stack comprising alternating layers of first and second materials, forming a hole through the alternating layers of the stack, and removing portions of the second material around the hole to form recesses in the second material around the hole, filling the recesses with a third material, and diffusing dopants from the second material into the first material while the third material acts as a hard mask. In another embodiment, a cell structure comprises a stack comprising alternating layers of a first material and a second material, a hole through the alternating layers of the stack, recesses in the second material around the hole, a third material filling the recesses, and dopants diffused from the second material into the first material while the third material acts as a hard mask.

### CROSS REFERENCE TO RELATED APPLICATIONS

This application claims the benefit of priority under 35 U.S.C. 119(e) based upon U.S. Provisional Patent Application having Application No. 63/671,793 filed on Jul. 16, 2024, and entitled “3D Cell and Array Architectures and Processes,” and U.S. Provisional Patent Application having Application No. 63/672,104 filed on Jul. 16, 2024, and entitled “3D Cell and Array Architectures and Processes,” and U.S. Provisional Patent Application having Application No. 63/672,260 filed on Jul. 17, 2024, and entitled “3D Cell and Array Architectures and Processes,” and U.S. Provisional Patent Application having Application No. 63/672,718 filed on Jul. 18, 2024, and entitled “3D Cell and Array Architectures and Processes,” and U.S. Provisional Patent Application having Application No. 63/675,195 filed on Jul. 24, 2024, and entitled “3D Cell and Array Architectures and Processes,” and U.S. Provisional Patent Application having Application No. 63/676,913 filed on Jul. 30, 2024, and entitled “3D Cell and Array Architectures and Processes,” and U.S. Provisional Patent Application having Application No. 63/704,214 filed on Oct. 7, 2024, and entitled “3D Cell and Array Architectures and Processes,” all of which are hereby incorporated herein by reference in their entireties.

### FIELD OF THE INVENTION

The exemplary embodiments of the present invention relate generally to the field of memory, and more specifically to memory cells and array structures and associated processes.

### BACKGROUND OF THE INVENTION

With the increasing complexity and density of electronic circuits, memory size, complexity, and cost are important considerations. One approach to increase memory capacity is to use three-dimensional (3D) array structures. The 3D array structure has been successfully used in NAND flash memory today. However, for dynamic random-access memory (DRAM), due to its special one-transistor-one-capacitor (1TIC) cell structure, a cost-effective 3D array structure has not been realized.

### SUMMARY

In various exemplary embodiments, advanced three-dimensional (3D) memory cells, array structures, and associated processes are disclosed. In one embodiment, a method is provided for forming a cell structure. The method comprises forming a stack comprising alternating layers of a first material and a second material, forming a hole through the alternating layers of the stack, and removing portions of the layers of the second material around the hole to form recesses in the second material around the hole. The method also comprises filling the recesses with a third material and diffusing dopants from the third material into the first material.

Furthermore, in accordance with the embodiments, a cell structure is provided that comprises a stack comprising alternating layers of a first material and a second material, a hole through the alternating layers of the stack, recesses in the second material around the hole, a third material filling the recesses, and dopants diffused from the third material into the first material.

Still further, in accordance with the embodiments, a cell structure is provided that is formed by a process of forming a stack comprising alternating layers of a first material and a second material, forming a hole through the alternating layers of the stack, removing portions of the layers of the second material around the hole to form recesses in the second material around the hole, filling the recesses with a third material, and diffusing dopants from the third material into the first material.

In another embodiment, a method for forming a cell structure is provided that comprises forming a stack comprising alternating layers of a first material and a second material, forming a hole through the alternating layers of the stack, and removing portions of the second material around the hole to form recesses in the second material around the hole. The method also comprises filling the recesses with a third material and diffusing dopants from the second material into the first material while the third material acts as a hard mask.

Furthermore, a cell structure is provided that comprises a stack comprising alternating layers of a first material and a second material, a hole through the alternating layers of the stack, recesses in the second material around the hole, a third material filling the recesses, and dopants diffused from the second material into the first material while the third material acts as a hard mask.

Still further, a cell structure is provided that is formed by a process of forming a stack comprising alternating layers of a first material and a second material, forming a hole through the alternating layers of the stack, removing portions of the layers of the second material around the hole to form recesses in the second material around the hole, filling the recesses with a third material, and diffusing dopants from the second material into the first material while the third material acts as a hard mask.

Additional features and benefits of the exemplary embodiments of the present invention will become apparent from the detailed description, figures and claims set forth below.

### BRIEF DESCRIPTION OF THE DRAWINGS

The exemplary embodiments of the present invention will be understood more fully from the detailed description given below and from the accompanying drawings of various embodiments of the invention, which, however, should not be taken to limit the invention to the specific embodiments, but are for explanation and understanding only.

FIG. 1A shows an embodiment of a cell structure for a three-dimensional (3D) NOR-type array constructed according to the invention.

FIG. 1B shows an embodiment of an inner cell structure of the cell shown in FIG. 1A.

FIG. 1C shows another embodiment of a cell structure constructed according to the invention.

FIG. 1D shows the cell structure of FIG. 1C with portions of the cell removed.

FIG. 1E shows another embodiment of a cell structure constructed according to the invention.

FIG. 1F shows the inner cell structure of the cell shown in FIG. 1E with portions of the cell removed.

FIG. 1G shows another embodiment of a cell structure constructed according to the invention.

FIG. 1H shows the inner cell structure of the cell shown in FIG. 1G with portions of the cell removed.

FIG. 1I shows another embodiment of a cell structure constructed according to the invention.

FIG. 1J shows the inner cell structure of the cell shown in FIG. 1I with portions of the cell removed.

FIG. 1K shows another embodiment of a cell structure constructed using a junction-less thin-film transistor according to the invention.

FIG. 1L shows an embodiment of a cross-section view of the cell structure shown in FIG. 1K taken along the cross-section indicator A-A′.

FIG. 1M shows another embodiment of the cell structure using a junction-less thin-film transistor according to the invention.

FIG. 1N shows a cross-section view of the cell structure shown in FIG. 1M taken along cross-section indicator A-A′.

FIG. 1O shows another embodiment of the cell structure using a junction-less thin-film transistor according to the invention.

FIG. 1P shows a cross-section view of the cell structure shown in FIG. 1O taken along cross-section indicator A-A′.

FIG. 1Q shows an exemplary embodiment of a three-dimensional (3D) NOR-type memory cell structure using a floating body cell (FBC) configuration in accordance with the invention.

FIG. 1R shows the cell structure shown in FIG. 1Q with a front gate and a gate dielectric layer removed.

FIG. 1S shows a cell formed using a PMOS transistor.

FIG. 1T shows an embodiment of an array structure based on the cell structure shown in FIG. 1Q.

FIG. 1U shows another embodiment of an array structure according to the invention.

FIG. 1V shows an equivalent circuit diagram for the array structure shown in FIG. 1T.

FIG. 1W shows another embodiment of an equivalent circuit diagram of the array structure shown in FIG. 1T.

FIG. 2A shows another embodiment of a cell structure for a 3D NOR-type flash memory constructed according to the invention.

FIG. 2B shows the inner cell structure of the cell shown in FIG. 2A with portions of the cell removed.

FIG. 2C shows another embodiment of a cell structure for 3D non-volatile random-access memory constructed according to the invention.

FIG. 2D shows the inner cell structure of the embodiment shown in FIG. 2C with portions of the cell removed.

FIGS. 3A-C show embodiments of a 3D array structure constructed according to the invention.

FIGS. 4A-I show embodiments of brief process steps to form a 3D array comprising the cell structure shown in FIG. 1A in accordance with the invention.

FIGS. 5A-C show embodiments of brief process steps to form an array using the cell structure shown in FIG. 1E according to the invention.

FIGS. 6A-F show embodiments of brief process steps to form an array using the cell structure shown in FIG. 1I according to the invention.

FIGS. 7A-D show embodiments of brief process steps to form an array comprising the cell structure shown in FIG. 1I according to the invention.

FIGS. 8A-E show embodiments of brief process steps to form an array comprising the cell structure shown in FIG. 1G according to the invention.

FIGS. 9A-C show embodiments of brief process steps to form the cell structure shown in FIGS. 1E-F according to the invention.

FIGS. 10A-E show embodiments of brief process steps that are performed to form an array comprising the cell structure shown in FIG. 1K according to the invention.

FIGS. 11A-D show embodiments of brief process steps configured to form an array comprising the cell structure shown in FIG. 1M according to the invention.

FIGS. 12A-E show embodiments of brief process steps configured to form an array comprising the cell structure shown in FIG. 1O according to the invention.

FIGS. 13A-G show embodiments of brief process steps to form an array using the cell structure shown in FIG. 1E according to the invention.

FIGS. 14A-K show embodiments of brief process steps to form an array using the cell structure shown in FIG. 1E according to the invention.

FIGS. 14L-P show embodiments of process steps to form the drain regions of the cells.

FIGS. 15A-C shows embodiments of brief process steps configured to form an array using the cell structure shown in FIG. 1C according to the invention.

FIGS. 16A-C show embodiments of process steps configured to dope source lines and drain regions together.

FIGS. 17A-F shows embodiments of complete process steps for the source line diffusion process shown in FIGS. 14F-I.

FIGS. 18A-B shows embodiments of cell structures after the diffusion processes shown in FIGS. 14F-I and FIGS. 17A-F.

FIGS. 19A-B shows some examples of the processes of phosphorus diffusion and boron diffusion, respectively.

FIGS. 20A-K shows embodiments of brief process steps to form an array using the cell structure shown in FIG. 1E according to the invention.

FIGS. 21A-L show process steps performed using a single cell to demonstrate the process steps shown in FIGS. 14A-F and FIGS. 16A-C.

FIGS. 22A-J show embodiments of brief process steps using a single cell to demonstrate the process steps shown in FIGS. 20A-K.

FIGS. 23A-F show embodiments of process steps to form the cell structure shown in FIG. 1E.

FIGS. 24A-F show embodiments of process steps to form the cell structure shown in FIG. 1E.

FIGS. 25A-F show embodiments of process steps to form the cell structure shown in FIG. 1E.

FIGS. 26A-F show embodiments of brief process steps performed to form the cell structure shown in FIG. 1E.

FIGS. 27A-E show embodiments of process steps performed to form the cell structure shown in FIG. 1E.

### DETAILED DESCRIPTION

Those of ordinary skilled in the art will realize that the following detailed description is illustrative only and is not intended to be in any way limiting. Other embodiments of the present invention will readily suggest themselves to skilled persons having the benefit of this disclosure. Reference will now be made in detail to implementations of the exemplary embodiments of the present invention as illustrated in the accompanying drawings. The same reference indicators or numbers will be used throughout the drawings and the following detailed description to refer to the same or like parts.

In various exemplary embodiments, three-dimensional (3D) memory cells, array structures, and associated processes are disclosed. For example, 3D NOR-type cells and array structures and processes are disclosed. The various embodiments of the invention can be applied to many technologies. For example, aspects of the invention can be applied to dynamic random-access memory (DRAM) using floating-body cells (FBC), NOR-type flash memory, Ferroelectric random-access memory (FRAM), resistive random-access memory (RRAM), phase change memory (PCM), magneto-resistive random-access memory (MRAM), and memory elements called ‘synapses’ in in-memory computing or neural network arrays for artificial intelligence (AI) applications. In addition, embodiments of the invention are applicable to other memory applications not listed.

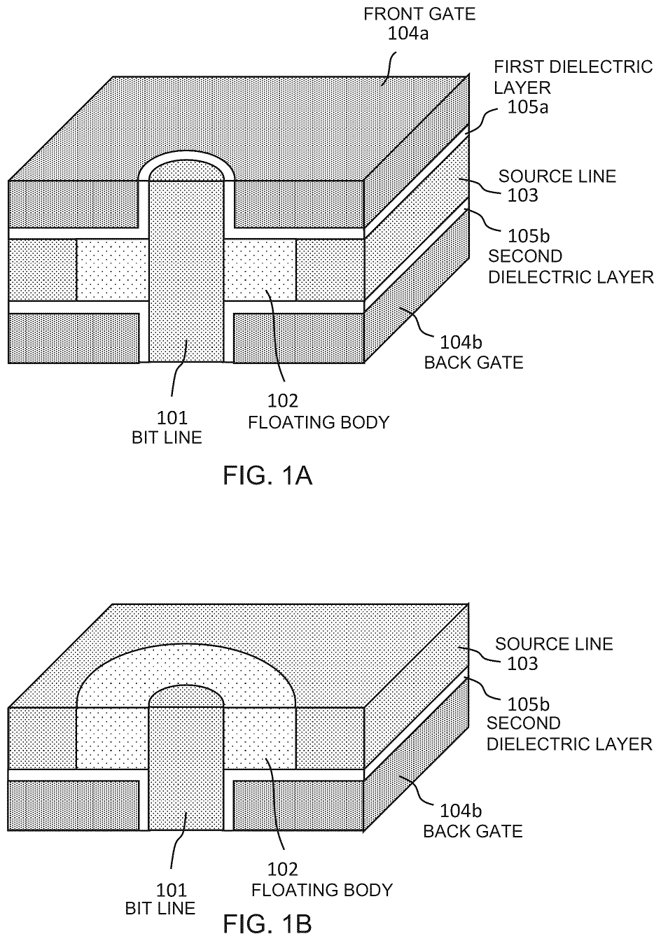

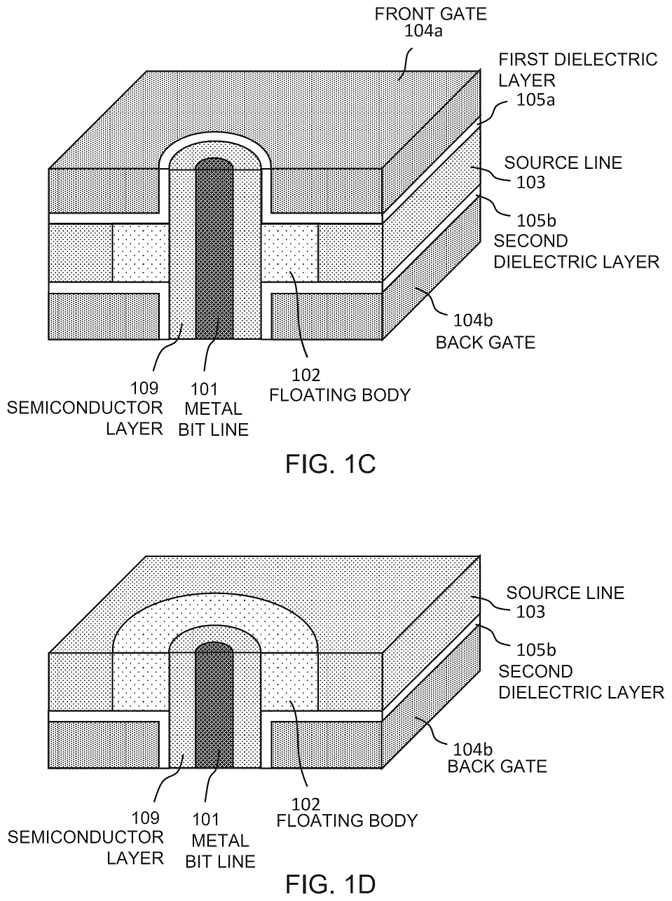

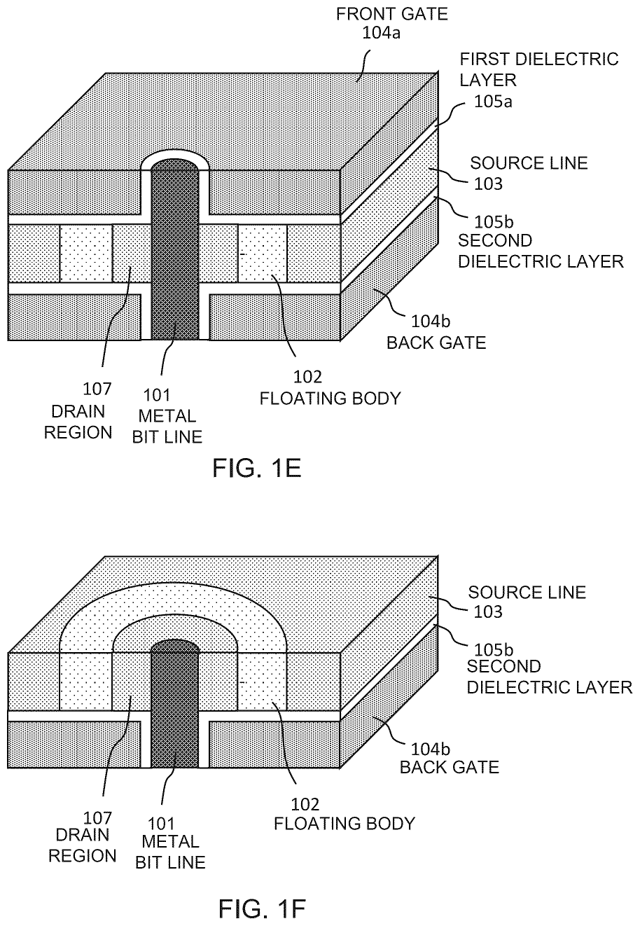

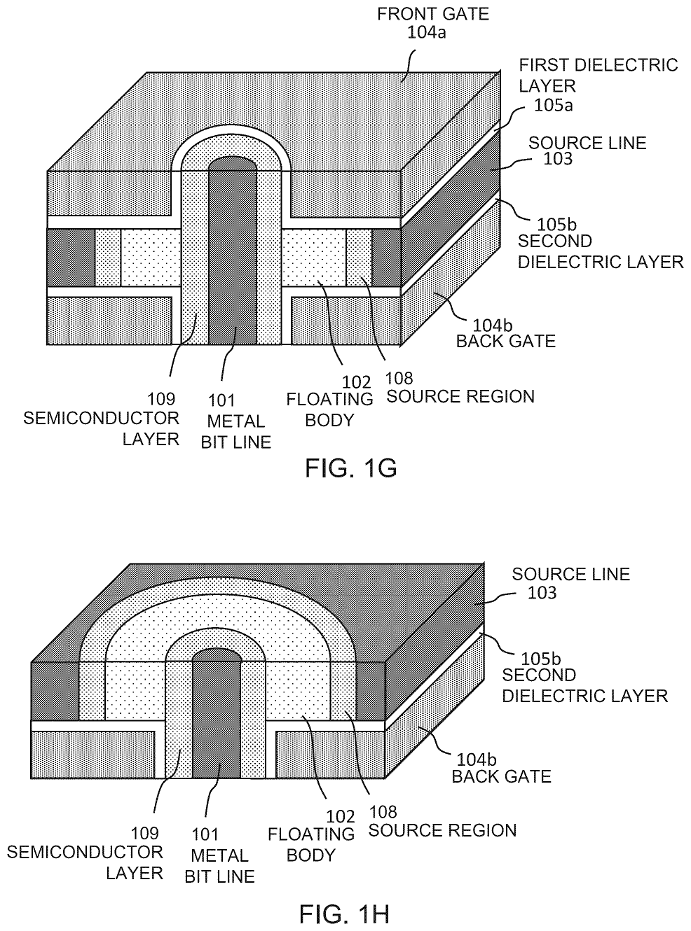

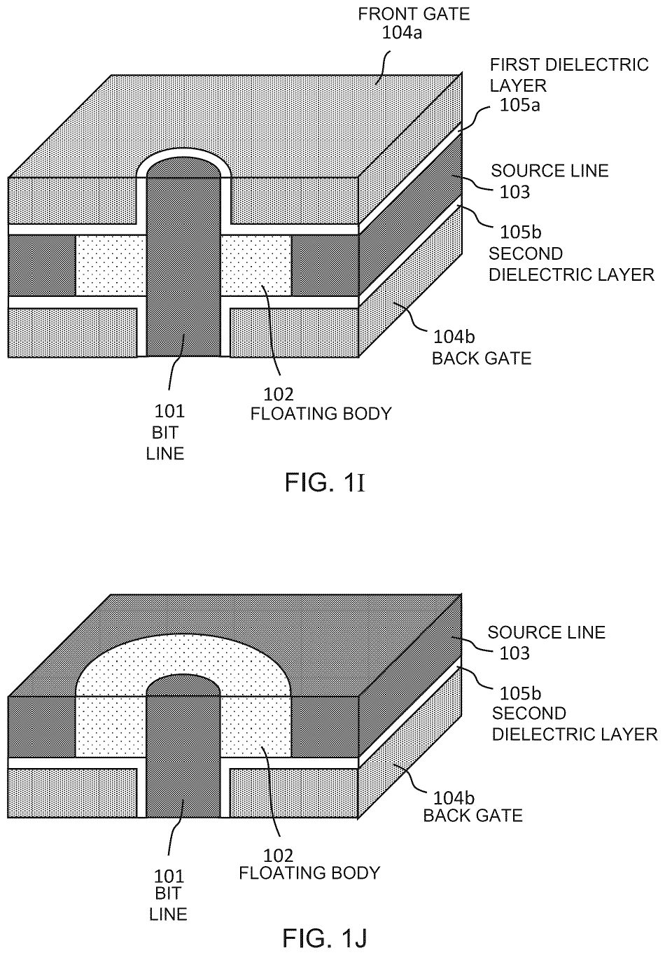

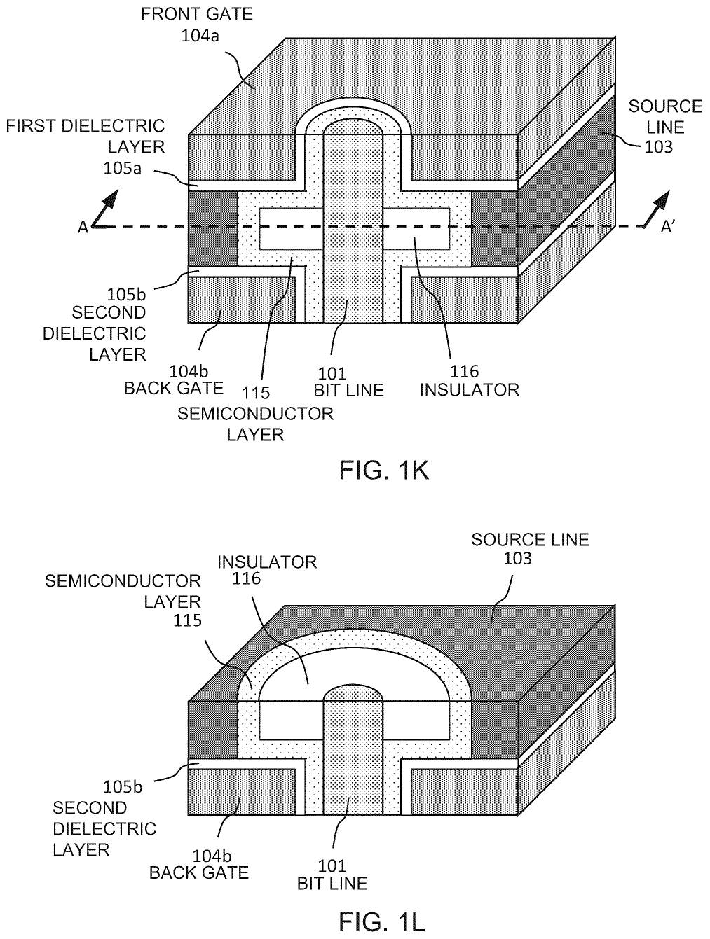

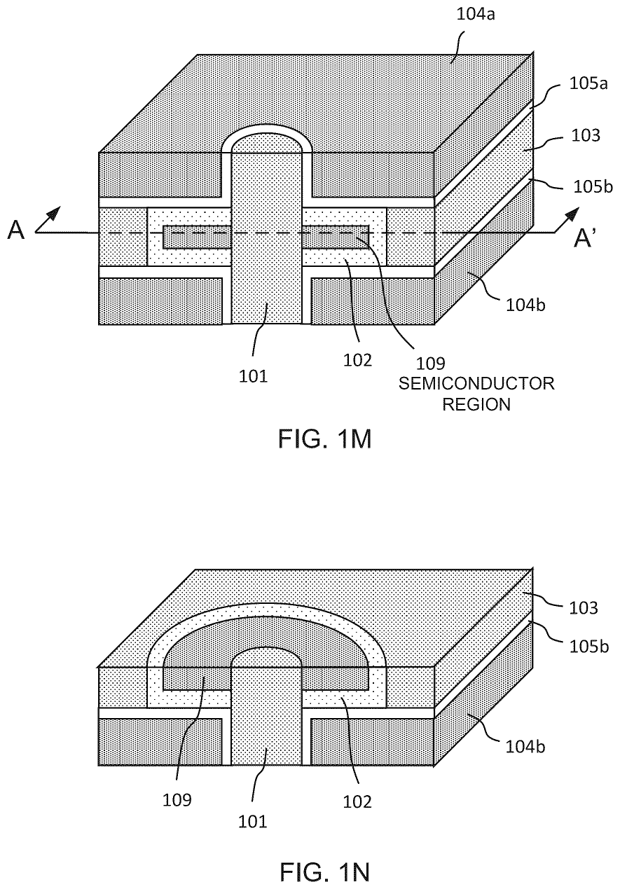

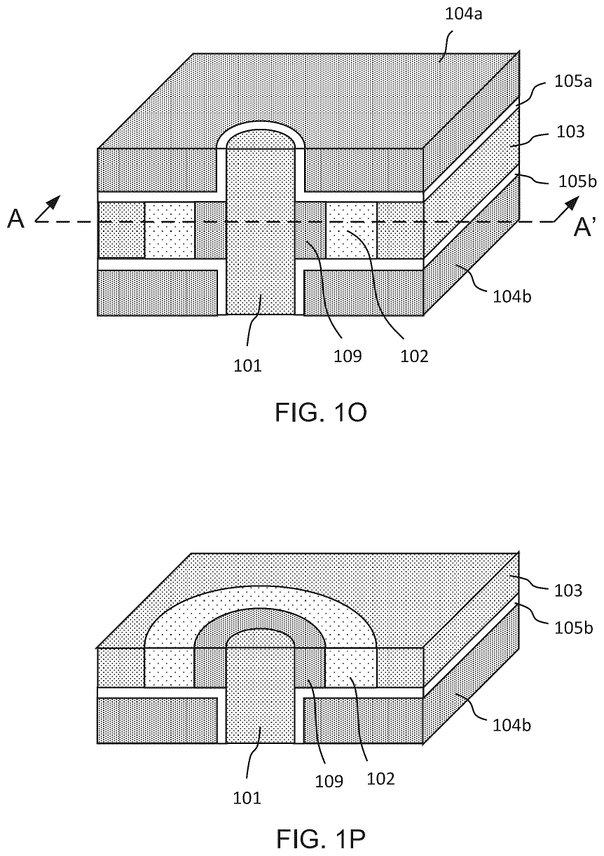

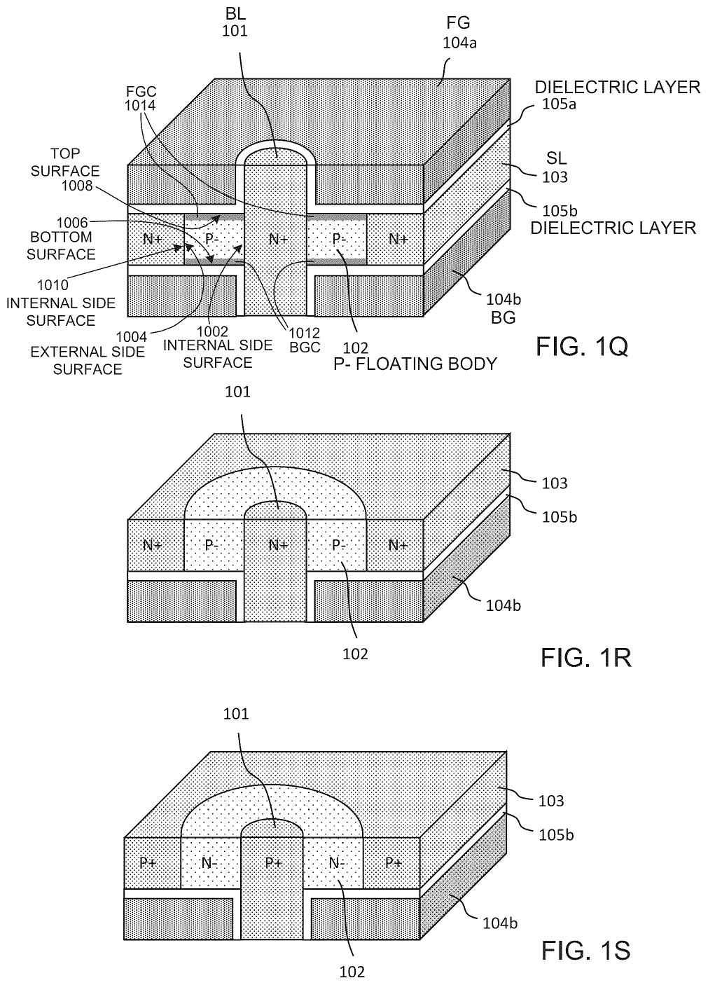

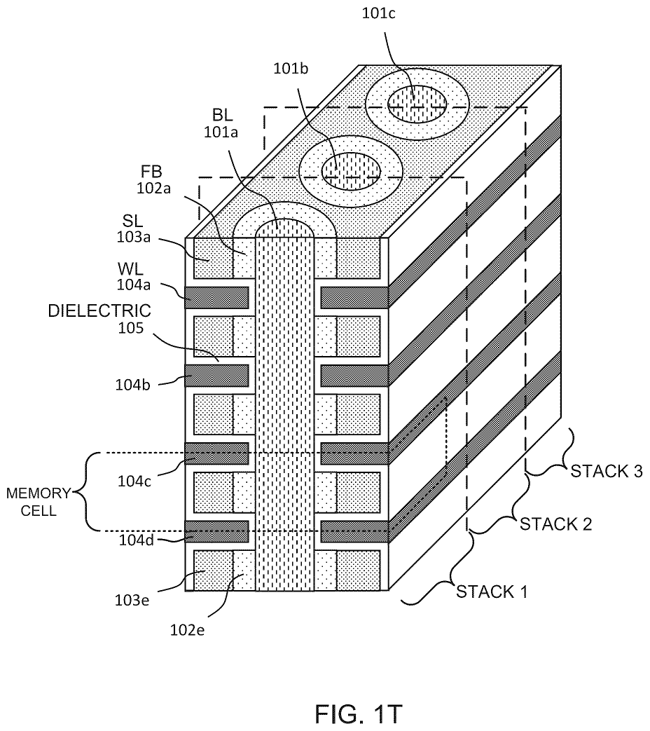

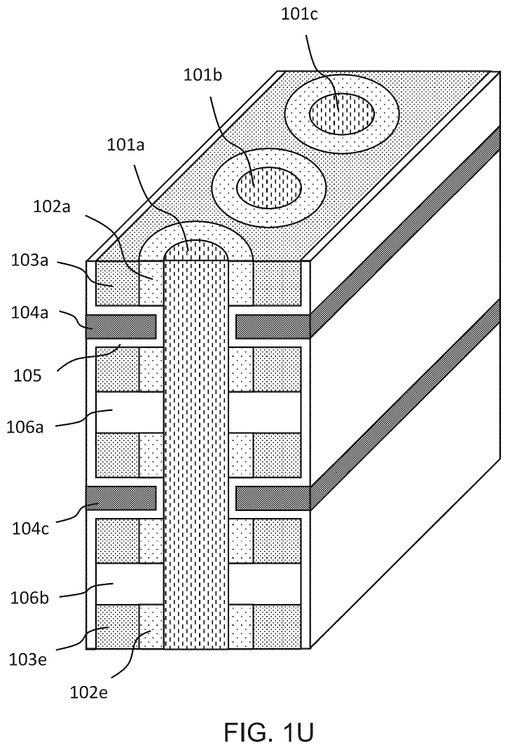

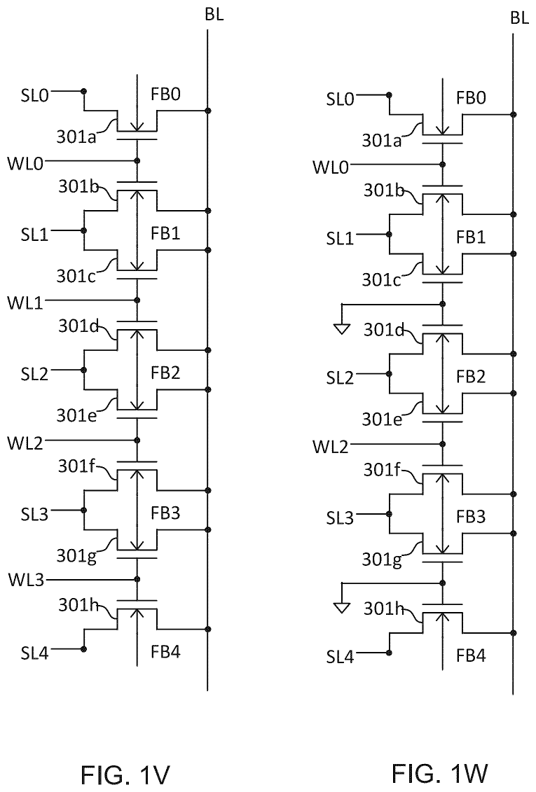

FIG. 1A shows an embodiment of a cell structure for a three-dimensional (3D) NOR-type array constructed according to the invention. The cell structure shown in FIG. 1A comprises a semiconductor layer that forms a vertical bit line (BL) 101 that comprises silicon or polysilicon, a floating body 102 formed of silicon or polysilicon and a horizontal source line (SL) 103 formed of silicon or polysilicon. The cell also comprises a front gate 104a, a back gate 104b, a first gate dielectric layer 105a, and a second gate dielectric layer 105b. In one embodiment, the gates 104a and 104b are formed of conductor material, such as metal or heavily doped polysilicon. The front gate 104a and back gate 104b can be connected to horizontal word lines (WL).

The cell can be formed as either an NMOS or PMOS transistor. For an NMOS cell embodiment, the bit line 101 and the source line 103 have N+ type of doping and the floating body 102 has P− type of doping. For the PMOS cell embodiment, the bit line 101 and the source line 103 have P+ type of doping and the floating body 102 has N− type of doping.

FIG. 1B shows an embodiment of the inner cell structure of the cell shown in FIG. 1A with the front gate 104a, the gate dielectric layer 105a, and a portion of the BL 101 removed. Although the embodiments show that the shapes of the bit line 101 and floating body 102 are circular, in other embodiments, the bit line 101 and the floating body 102 can have any suitable shapes, such as square, rectangular, triangular, hexagon, etc. These variations are withing the scope of the embodiments.

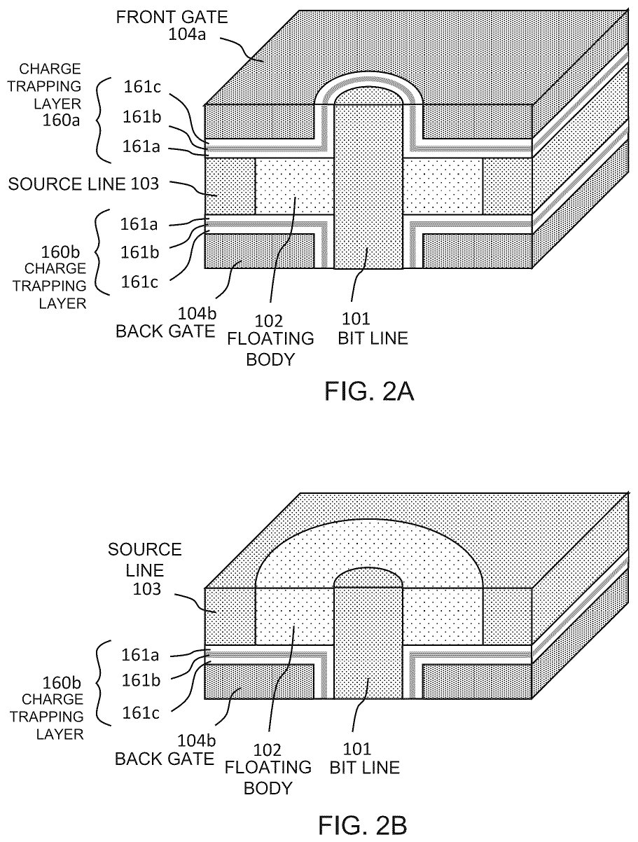

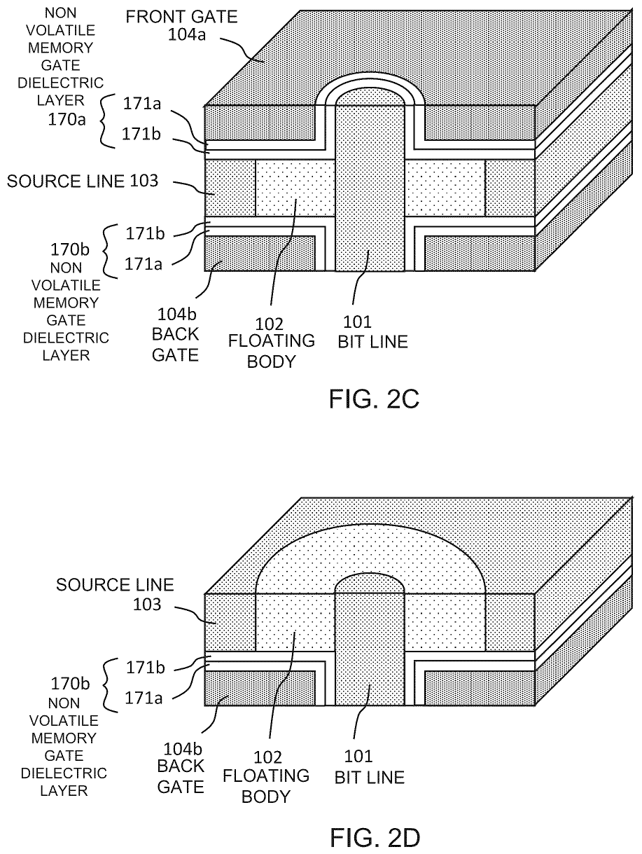

Depending on the cell types and technologies, the gate dielectric layers 105a and 105b can be formed of a variety of different materials and structures. For example, in one embodiment, the cell may be formed as a floating-body cell for DRAM application. For this embodiment, the gate dielectric layers 105a and 105b are thin gate oxide layers or high-K material layers, such as hafnium oxide (HfO2). In another embodiment, the gate dielectric layers 105a and 105b are formed from other suitable materials to form NOR-type flash memory, ferroelectric random-access memory (FRAM), resistive random-access memory (RRAM), phase-change memory (PCM), magneto-resistive random-access memory (MRAM), and others. as shown in FIG. 2A-D.

FIG. 1C shows another embodiment of a cell structure constructed according to the invention. This embodiment is similar to the embodiment in FIG. 1A except that a metal vertical bit line 101 is formed of a metal core in the center of the semiconductor layer 109 to reduce the bit line resistance.

FIG. 1D shows the cell structure of FIG. 1C with the front gate 104a and gate dielectric layer 105a and a portion of the metal BL 101 and the semiconductor layer 109 removed.

FIG. 1E shows another embodiment of a cell structure constructed according to the invention. This embodiment is similar to the embodiments shown in FIGS. 1C-D except that a drain region 107 is formed around the side of the metal bit line 101 as shown. In an embodiment, the drain region 107 is formed of silicon or polysilicon with the opposite type of heavy doping as the doping of the floating body 102. For example, the ‘opposite type of doping’ means that P-type (positive) doping is the opposite of N-type (negative) doping. For example, if the floating body 102 comprises P-type doping, the drain region 107 comprises N-type doping, which is the opposite type of doping. If the floating body 102 comprises N-type doping, the drain region 107 comprises P-type doping, which is the opposite type of doping. The terms ‘heavy doping’ and ‘light doping’ are relative terms that describe the amount of doping. When a semiconductor is doped with excess electrons or holes, it is called a heavily doped semiconductor, indicated by N+ or P+, respectively. When a semiconductor is doped with a small amount of electrons or holes, it is called a lightly doped semiconductor, indicated by N− or P−, respectively. As shown in FIG. 1E, the vertical bit line hole is filled with metal to form the metal bit line 101 to reduce the bit line resistance.

FIG. 1F shows the inner cell structure of the cell shown in FIG. 1E with the front gate 104a, the gate dielectric layer 105a, and a portion of the metal bit line 101 removed.

FIG. 1G shows another embodiment of a cell structure constructed according to the invention. This embodiment is similar to the embodiments shown in FIGS. 1C-D except that the source line 103 is formed of conductor material, such as metal to reduce the source line resistance. A source region 108 comprising semiconductor material, such as silicon or polysilicon, is formed between the metal source line 103 and the floating body 102. The source region 108 has the opposite type of heavy doping from the doping of the floating body 102.

FIG. 1H shows the inner cell structure of the cell shown in FIG. 1G with the front gate 104a and the gate dielectric layer 105a, and a portion of the metal BL 101 and the semiconductor layer 109 removed.

FIG. 1I shows another embodiment of a cell structure constructed according to the invention. This embodiment is similar to FIGS. 1A-B except that the bit line 101 and the source line 103 are formed of metal. A floating body 102 is formed of semiconductor material, such as silicon or polysilicon. In one embodiment, the floating body 102 has N+ or P+ type of heavy doping. This forms a junction-less cell transistor. In another embodiment, the floating body 102 has N− or P− type of light doping. This forms a Schottky-junction cell transistor.

FIG. 1J shows the inner cell structure of the cell shown in FIG. 1I with the front gate 104a, the gate dielectric layer 105a, and a portion of the BL 101 removed.

FIG. 1K shows another embodiment of a cell structure constructed using a junction-less thin-film transistor according to the invention. This embodiment is similar to the embodiments shown in FIGS. 1A-B except that a semiconductor layer 115 comprising silicon, polysilicon, germanium (Ge), indium gallium zinc oxide (IGZO), tungsten-doped indium oxide semiconductor, or any other suitable semiconductor material surrounds the BL 101 and an insulator 116 that comprises oxide or nitride. In one embodiment, the semiconductor layer 115 has N-type or P-type of heavy doping to form the channel of the cell transistor. In one embodiment, the bit line 101 and the source line 103 are formed of conductor material, such as metal or heavily doped polysilicon. FIG. 1K also shows a cross-section indicator A-A′.

FIG. 1L shows an embodiment of a cross-section view of the cell structure shown in FIG. 1K taken along the cross-section indicator A-A′ shown in FIG. 1K.

FIG. 1M shows another embodiment of the cell structure using a junction-less thin-film transistor according to the invention. This embodiment is similar to the embodiments shown in FIGS. 1A-B except for a semiconductor region 109. The semiconductor region 109 is formed of a different material from the floating body 102. For example, if the floating body 102 is formed of silicon or polysilicon, the semiconductor region 109 is formed of silicon germanium (SiGe), silicon carbide (SiC), or any other suitable semiconductor materials. This configuration forms a heterostructure junction between the two materials and forms a quantum well inside the semiconductor region 109 to store the electric charge, such as holes. This increases the data retention time of the cell.

FIG. 1N shows a cross-section view of the cell structure shown in FIG. 1M taken along cross-section indicator A-A′ shown in FIG. 1M.

FIG. 1O shows another embodiment of the cell structure using a junction-less thin-film transistor according to the invention. This embodiment is similar to the embodiments shown in FIGS. 1M-N except that the semiconductor region 109 is formed in a different shape. The semiconductor region 109 is formed of a different material from the floating body 102. For example, if the floating body 102 is formed of silicon or polysilicon, the semiconductor region 109 is formed of silicon germanium (SiGe), silicon carbide (SiC), or any other suitable semiconductor materials. This forms a heterostructure junction between the two materials and forms a quantum well inside the semiconductor region 109 to store the electric charge, such as holes. This increases the data retention time of the cell.

FIG. 1P shows a cross-section view of the cell structure shown in FIG. 1O taken along cross-section indicator A-A′ shown in FIG. 1O.

FIG. 1Q shows an exemplary embodiment of a three-dimensional (3D) NOR-type memory cell structure using a floating body cell (FBC) configuration in accordance with the invention. For example, a 3D NOR-type array can comprise multiple layers of floating-body cell arrays to increase the memory capacity. A floating-body cell is basically a transistor with floating body. The floating body stores electric charges, such as electrons or holes to represent the data. The cell structure comprises a control gate, a drain, a source, and a floating body. In the 3D memory array, the control gate, drain, and source of the cells are connected to a word line (WL), bit line (BL), and source line (SL), respectively.

In the cell structure shown in FIG. 1Q, an N+ silicon or polysilicon forms a bit line (BL) 101 and a P− floating body 102 is used for charge storage. An N+ silicon or polysilicon forms a source line (SL) 103. The cell may be formed as a dual-gate transistor shown in FIG. 1Q or a single-gate transistor as shown in FIG. 1R. For the dual-gate transistor shown in FIG. 1Q, the cell structure comprises two control gates called a front gate 104a and a back gate 104b, respectively. Both the front gate 104a and the back gate 104b are coupled to the floating body 102 through gate dielectric layers 105a and 105b, respectively. The gate dielectric layer is an insulating layer between the gate and the body of the transistor. When a proper voltage is applied to the front gate 104a or the back gate 104b, a front gate channel (FGC) 1014 or a back gate channel (BGC) 1012 are formed in the surface of the floating body 102 under the gate dielectric layer 105a and 105b to conduct current between the bit line 101 and source line 103. In an embodiment, the front gate 104a and back gate 104b are connected to different word lines (WL).

In an embodiment, the P− floating body 102 comprises multiple surfaces as shown in FIG. 1Q. An internal side surface 1002 surrounds and connects to the BL 101. An external side surface 1004 connects to the source line 103. A top surface 1008 connects to the dielectric layer 105a, and a bottom surface 1006 connects to the dielectric layer 105b. Thus, in one embodiment, a memory cell structure is provided that includes a first semiconductor material BL 101, a floating body semiconductor material 102 having an internal side surface 1002 that surrounds and connects to the first semiconductor material BL 101, and a second semiconductor material SL 103 having an internal side surface 1010 that surrounds and connects to the floating body semiconductor material 102. The memory cell structure also includes a first dielectric layer 105a connected to a top surface 1008 of the floating body material 102, a second dielectric layer 105b connected to a bottom surface 1006 of the floating body material 102, a front gate 104a connected to the first dielectric layer 105a, and a back gate 104b connected to the second dielectric layer 105b. In various embodiments, minor modifications can be made to the disclosed structures, such as adding a lightly doped drain (LDD), halo implantation, pocket implantation, or channel implantation that are all included within the scope of the invention.

FIG. 1R shows the cell structure shown in FIG. 1Q with the front gate 104a, the gate dielectric layer 105a, and a portion of the bit line 101 removed. The P− floating body 102 forms a donut shape as shown. Although this embodiment shows that the shapes for the bit line 101 and floating body 102 are circular, it is obvious that they have any desired shape, such as square, rectangle, triangle, hexagon, etc. These variations shall remain in the scope of the invention.

In one embodiment, the cell structure comprises only one single gate, as shown in FIG. 1R. The floating body 102 is coupled to only one gate 104b as shown. An embodiment of a 3D array structure using this cell structure embodiment is shown in FIG. 1T.

The embodiment shown in FIG. 1Q uses an NMOS transistor as the cell. In another embodiment, shown in FIG. 1S, the cell is formed using a PMOS transistor. The bit line 101, floating body 102, and source line 103 are formed by P+, N−, and P+ materials, respectively.

FIG. 1T shows an embodiment of an array structure based on the cell structure shown in FIG. 1Q. The array structure comprises vertical bit lines 101a to 101c and floating bodies 102a to 102e. The array structure also comprises source lines 103a to 103e and word lines 104a to 104d. The array structure also includes dielectric layer 105 comprising a gate oxide or high-K material, such as HfOx.

In an embodiment, a three-dimensional (3D) memory array comprises a plurality of memory cells separated by a dielectric layer to form a stack of memory cells. For example, FIG. 1T shows a 3D array having three stacks of memory cells and a particular “memory cell” is identified. Each memory cell in the stack of memory cells comprises a bit line 101 formed from one of a first semiconductor material and a first conductor material, a floating body semiconductor material 102 having an internal side surface that surrounds and connects to the bit line, a source line 103 formed from one of a second semiconductor material and a second conductor material having an internal side surface that surrounds and connects to the floating body semiconductor material 102, and a word line 104 formed from a third conductor material that is coupled to the floating body semiconductor 102 through a dielectric layer 105 to form a gate of the memory cell. Additionally, the bit lines of the stack of memory cells are connected to form a vertical bit line (e.g., 101a).

FIG. 1U shows another embodiment of an array structure according to the invention. This embodiment is similar to the embodiment shown in FIG. 1T except that the cells are single-gate transistors. Also shown in FIG. 1U are insulating layers 106a and 106b that are formed from material, such as oxide.

FIG. 1V shows an equivalent circuit diagram for the array structure shown in FIG. 1T. For example, the equivalent circuit shows transistors 301a-h that are formed by the array structure shown in FIG. 1T. Referring again to the array structure in FIG. 1T, the word line structures 104a to 104d are connected to word lines WL0-WL3. The floating bodies structures 102a to 102e are the floating bodies FB0-FB4. The source line structures 103a to 103e are connected to the source lines SL0-SL4, and the bit line structure 101a is a vertical bit line (BL). In this embodiment, each floating body (e.g., FB0-FB4) is coupled to two word lines. This array requires special bias conditions for read and write operations to avoid two cells being selected at the same time.

FIG. 1W shows another embodiment of an equivalent circuit diagram of the array structure shown in FIG. 1T. This embodiment is similar to the embodiment shown in FIG. 1V except that the odd word lines, WL1, WL3, and so on, are connected to ground. This turns off the transistors 301c, 301d, 301g, and 301h. In this embodiment, each floating body is coupled to one word line only. However, the storage capacity of this embodiment is reduced to one half when compared with the embodiment shown in FIG. 1V.

FIG. 2A shows another embodiment of a cell structure for a 3D NOR-type flash memory constructed according to the invention. This embodiment is similar to the embodiments shown in FIGS. 1A-B except that the gate dielectric layers 105a and 105b are replaced with charge trapping layers 160a and 160b that comprise oxide-nitride-oxide (ONO) layers. In one embodiment, the charge trapping layer 160b comprises a tunnel oxide layer 161a that is thin enough to allow electrons to tunnel through when a high electric field is applied. This changes the threshold voltage of the cells to represent the stored data. A nitride layer 161b traps electrons for data storage. A blocking oxide 161c is thick enough to prevent electrons from tunneling through to the gates 104a and 104b. In another embodiment, the blocking oxide 161c comprises a tunnel oxide layer and the tunnel oxide layer 161a comprises a blocking oxide layer. In this embodiment, during programming, electrons are injected from a selected one of the gates 104a or 104b to the nitride layer 161b.

FIG. 2B shows the inner cell structure of the cell shown in FIG. 2A with the front gate 104a, the charge trapping layer 160a, and a portion of the BL 101 removed.

Although ONO layers 161a-c shown in FIG. 2B are used as an example for the charge-trapping layers 160a and 160b, in other embodiments, the charge-trapping layers 160a and 160b comprise any suitable number of oxide layers and nitride layers. For example, in another embodiment, the charge-trapping layers 160a and 160b comprise oxide-nitride-oxide-nitride-oxide (ONONO) layers. In another embodiment, the charge-trapping layers 160a and 160b comprise only one oxide and one nitride (ON) layers. These variations are within the scope of the embodiments.

In various embodiments, the charge-trapping layers 160a and 160b are also utilized in the other cell embodiments shown in FIGS. 1A-L to replace the gate dielectric layers 105a and 105b to form different types of NOR flash memory cells.

FIG. 2C shows another embodiment of a cell structure for 3D non-volatile random-access memory constructed according to the invention. This embodiment is similar to the embodiments shown in FIGS. 1A-B except that the gate dielectric layers 105a and 105b are replaced with non-volatile memory gate dielectric layers 170a and 170b. In one embodiment, the non-volatile memory gate dielectric layers 170a and 170b comprise multiple layers, such as 171a and 171b.

FIG. 2D shows the inner cell structure of the embodiment shown in FIG. 2C with the front gate 104a, the non-volatile memory gate dielectric layer 170a, and a portion of the BL 101 removed.

In one embodiment that forms a ferroelectric random-access memory (FRAM), the non-volatile memory gate dielectric layer 170b comprises a ferroelectric layer 171a, such as lead zirconate titanate (PZT) or hafnium oxide (HfO2) in orthorhombic crystal phase, or hafnium zirconium oxide (HfZrO2). The layer 171b comprises a dielectric layer, such as hafnium oxide (HfO2). When high voltages are applied to the gates 104a and 104b, the generated electric field alters the pole of the ferroelectric materials in the ferroelectric layer 171a to change the threshold voltage of the cells to represent the stored data.

In another embodiment that forms a resistive random-access memory (RRAM), the non-volatile memory gate dielectric layers 170a and 170b comprise an adjustable resistive layer 171a, such as hafnium oxide (HfOx), titanium oxide (TiOx), or tantalum oxide (TaOx), and a dielectric layer 171b, such as silicon oxide (SiO₂). In another embodiment that forms a phase-change memory (PCM), the non-volatile memory gate dielectric layers 170a and 170b are formed of multiple layers comprising at least one phase-change layer 171a, such as Germanium Antimony Tellurium alloy or chalcogenide glass, Ge2Sb2Te5 (GST), and a heater layer 171b, such as tungsten (W), titanium (Ti), or polysilicon.

In another embodiment, that forms a magneto-resistive random-access memory (MRAM), the non-volatile memory gate dielectric layers 170a and 170 comprise multiple layers including ferromagnetic material 171a and 171b, such as iron-nickle (NiFe) or iron-cobalt (CoFe) alloys, and a tunnel-barrier layer formed such as hafnium oxide (HfO₂) between the layers 171a and 171b. The materials of the non-volatile memory gate dielectric layers 170a and 170b described above are just some examples and any other suitable materials can be used for the non-volatile memory gate dielectric layers 170a and 170b within the scope of the embodiments.

The non-volatile memory gate dielectric layers 170a and 170b shown in this embodiment can be also utilized with all the other cell embodiments shown in FIG. 1A-L to replace the gate dielectric layers 105a and 105b to form various types of non-volatile random-access memory cells.

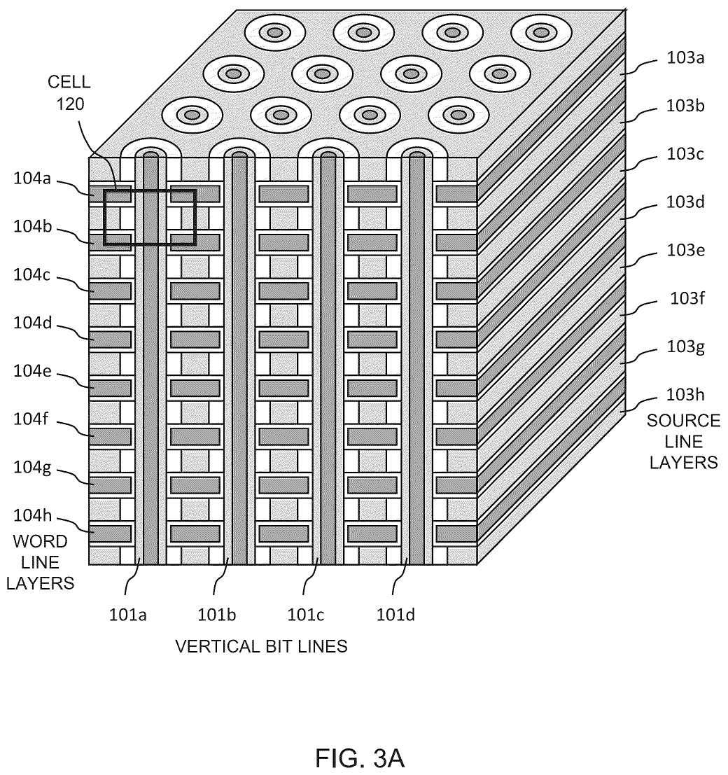

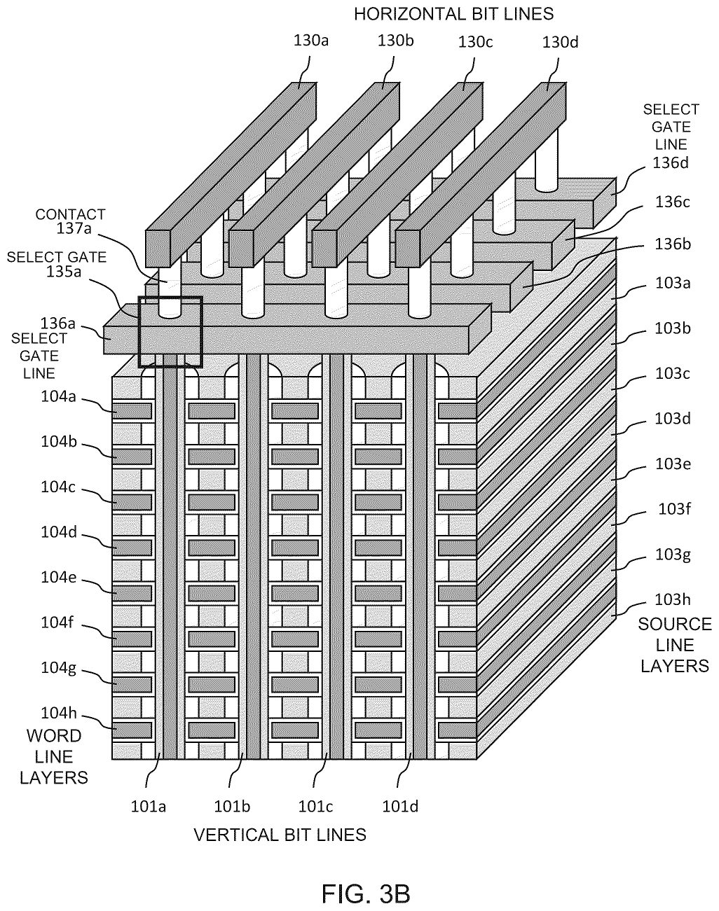

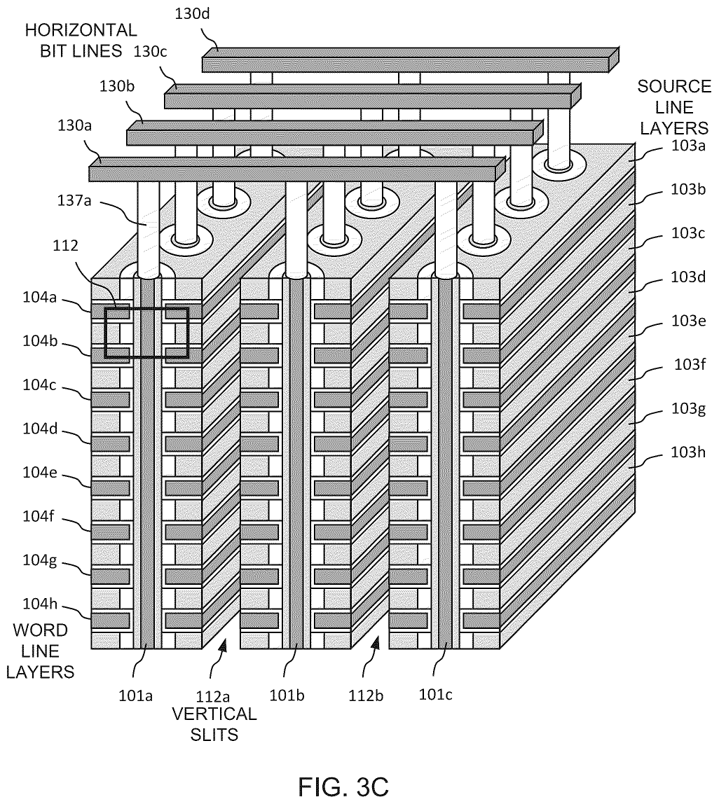

FIGS. 3A-C show embodiments of a 3D array structure constructed according to the invention. FIG. 3A shows a 3D array formed using the cell structures shown in FIGS. 1C-D. However, in other embodiments, the 3D array structure is formed utilizing any other cell structures shown in FIGS. 1A-2D. The 3D array comprises multiple layers of cells stacked vertically. The cells are connected to vertical bit lines, such as vertical bit lines 101a to 101d. The 3D array comprises multiple word line layers 104a to 104h that are connected to the gates of the cells. The 3D array also comprises multiple source line layers 103a to 103h. Each intersection of one of the vertical bit lines 101a to 101d and one of the source lines 103a to 103h forms a cell, such as the cell 120.

FIG. 3B shows an embodiment of a bit line connections to the 3D array structure shown in FIG. 3A that are constructed according to the invention. The vertical bit lines 101a to 101d are connected to horizontal bit lines 130a to 130d through select gates, such as select gate 135a and contacts, such as contact 137a. The horizontal bit lines 130a to 130d are formed of conductor material, such as metal or heavily doped polysilicon. The select gates, such as select gate 135a, are formed of vertical-channel transistors. Select gate lines 136a to 136d are connected to control gates of the vertical channel select gates, such as select gate 135a.

The word line layers 104a to 104h and source line layers 103a to 103h are connected to the word line decoders (not shown) and source line voltage generators (not shown), respectively, by forming staircase structures for the word lines and the source lines at the edge of the array as structured in a conventional 3D NAND flash memory.

FIG. 3C shows another embodiment of the 3D array structure according to the invention. The array is divided into multiple stacks by vertical slits 112a and 112b. Because each stack is connected to different word lines such as 104 to 104h, the vertical bit lines such as 101a to 101c may be connected to the horizontal bit lines 130a to 130d without the vertical select gates such as 135a shown in FIG. 3B.

The 3D array structure can be utilized in various 3D NOR-type memory applications, such as dynamic random-access memory (DRAM) using floating-body cell (FBC), NOR-type flash memory, ferroelectric random-access memory (FRAM), resistive random-access memory (RRAM), phase change memory (PCM), and magneto-resistive random-access memory (MRAM).

Moreover, the 3D array structure can be applied to in-memory computing and 3D neural network arrays for artificial intelligence (AI) applications. For these applications, the vertical bit line 101a to 101d, word line layers 104a to 104h, and the source line layers 103a to 103h are connected to input neuron circuits and output neuron circuits. Besides these applications, the novel 3D cell and array structures constructed according to the invention are suitable for use in any other applications.

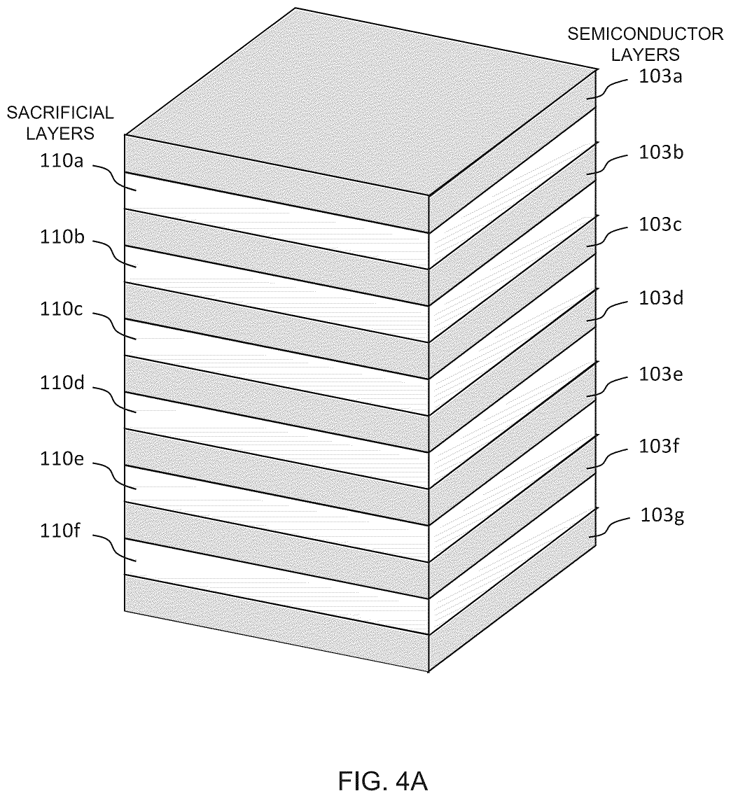

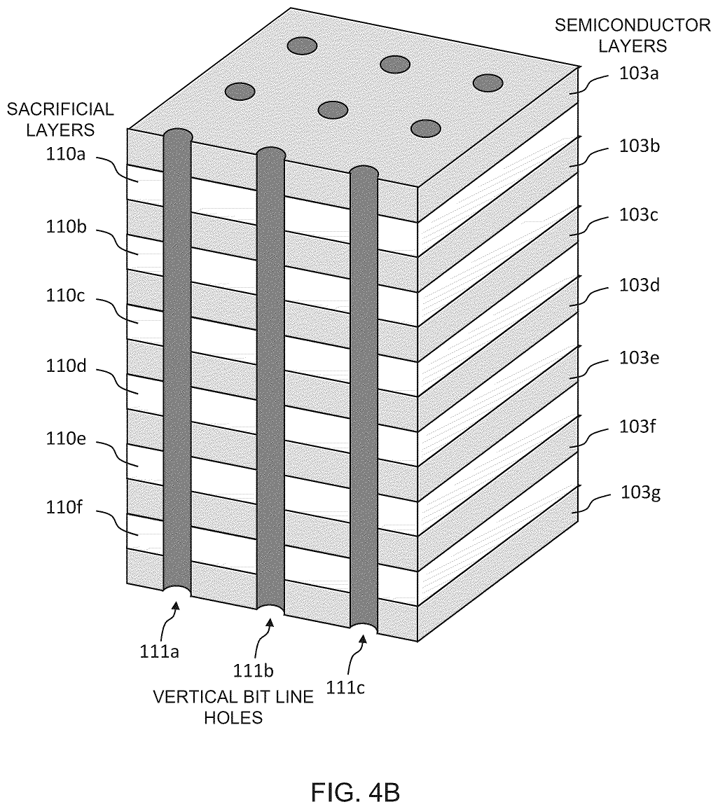

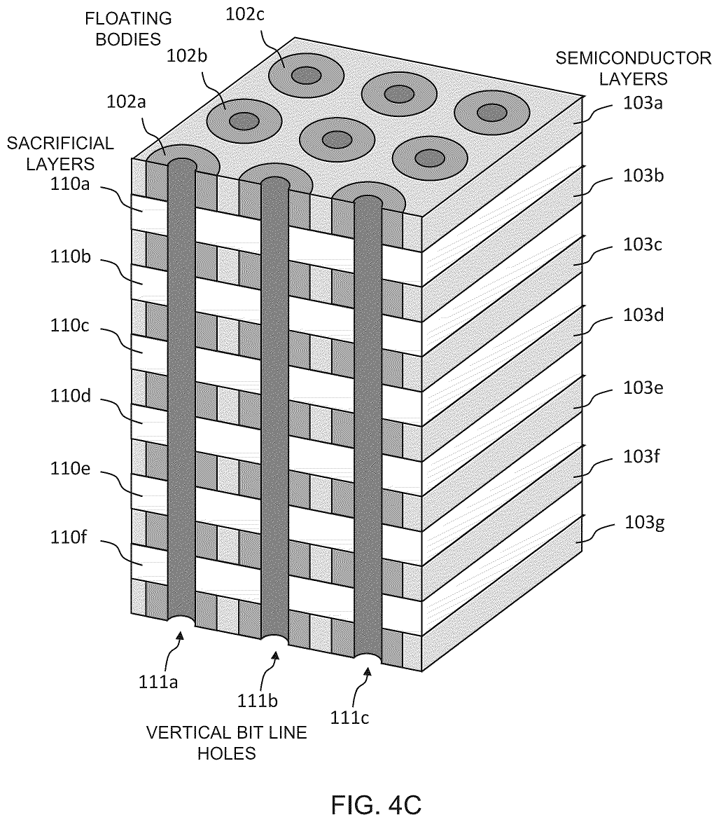

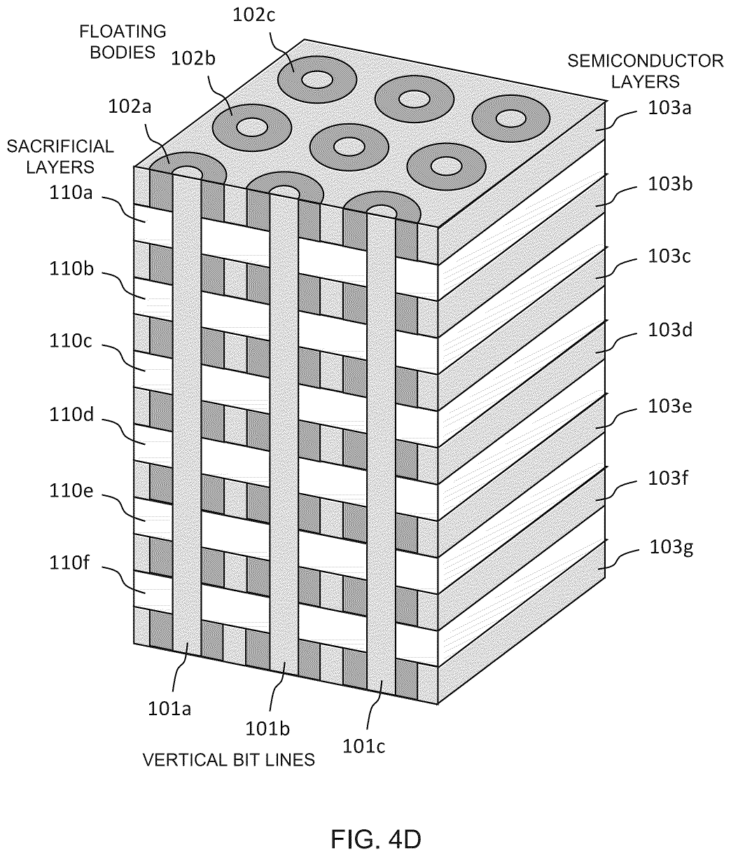

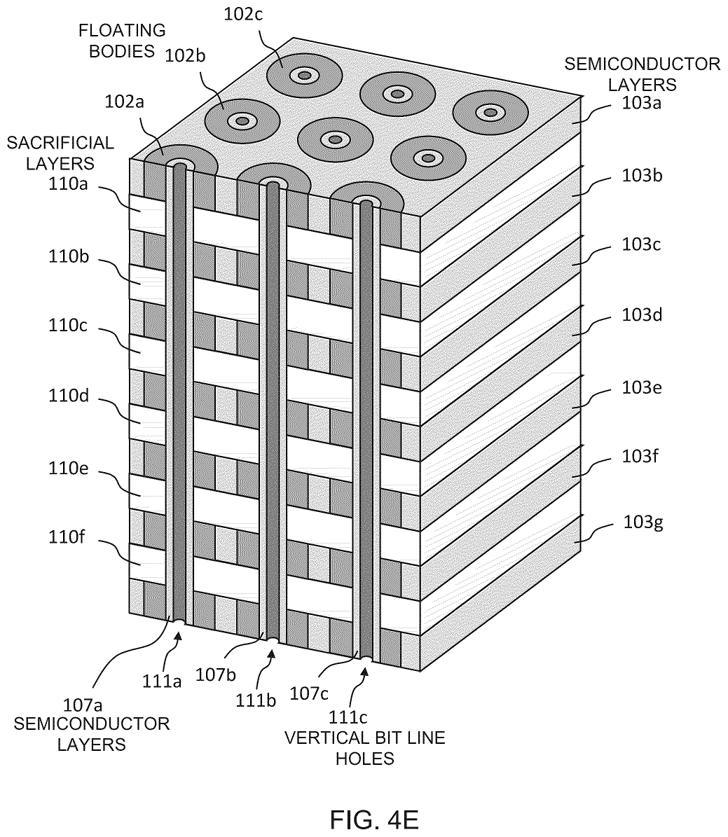

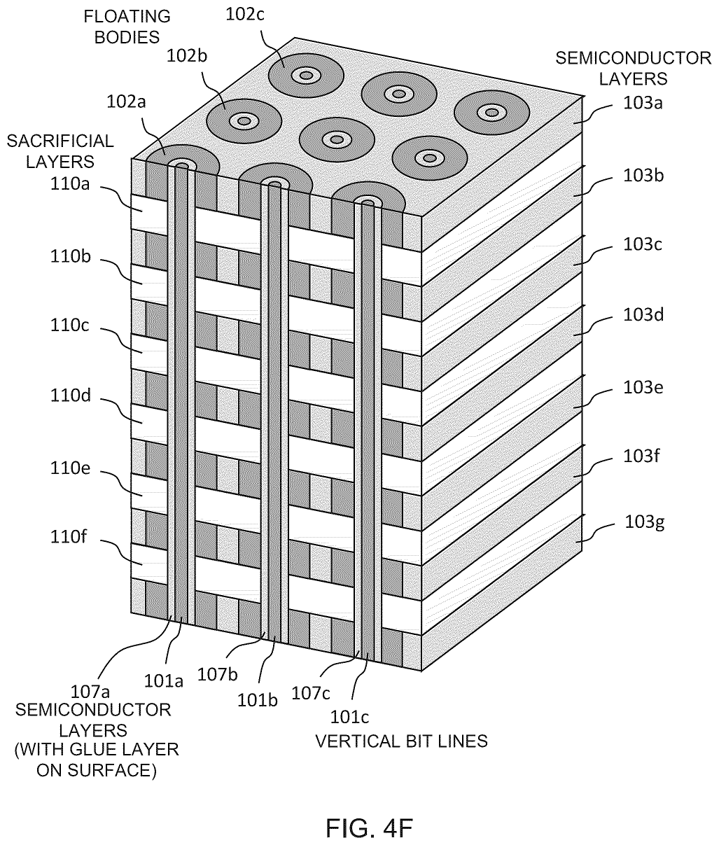

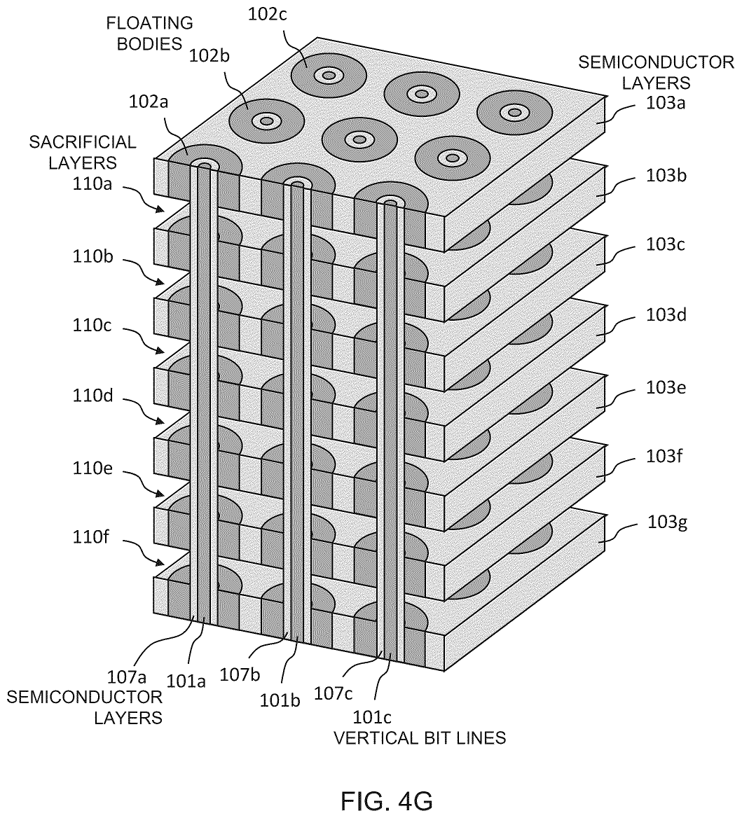

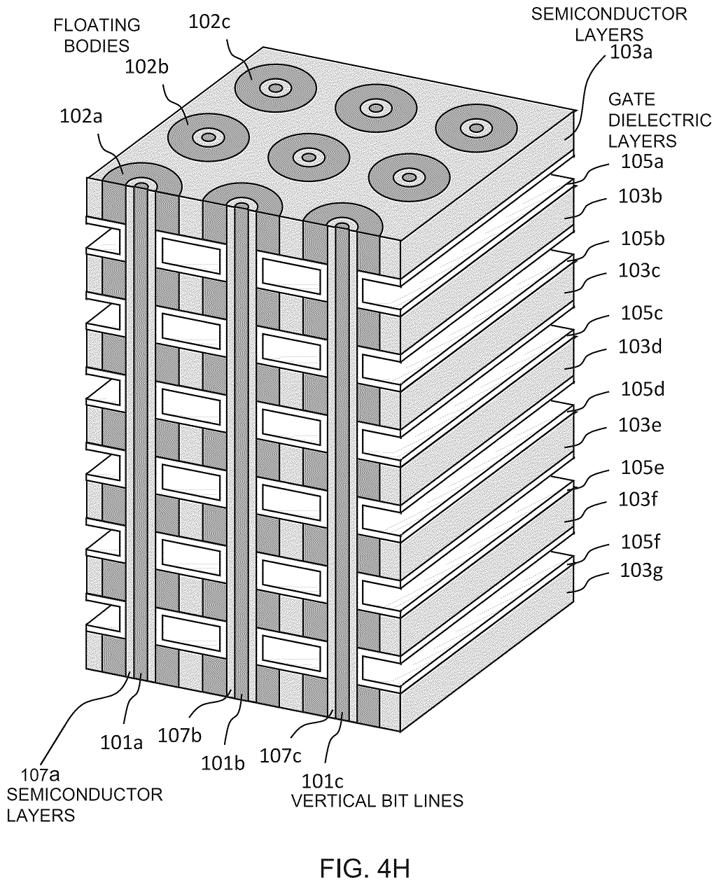

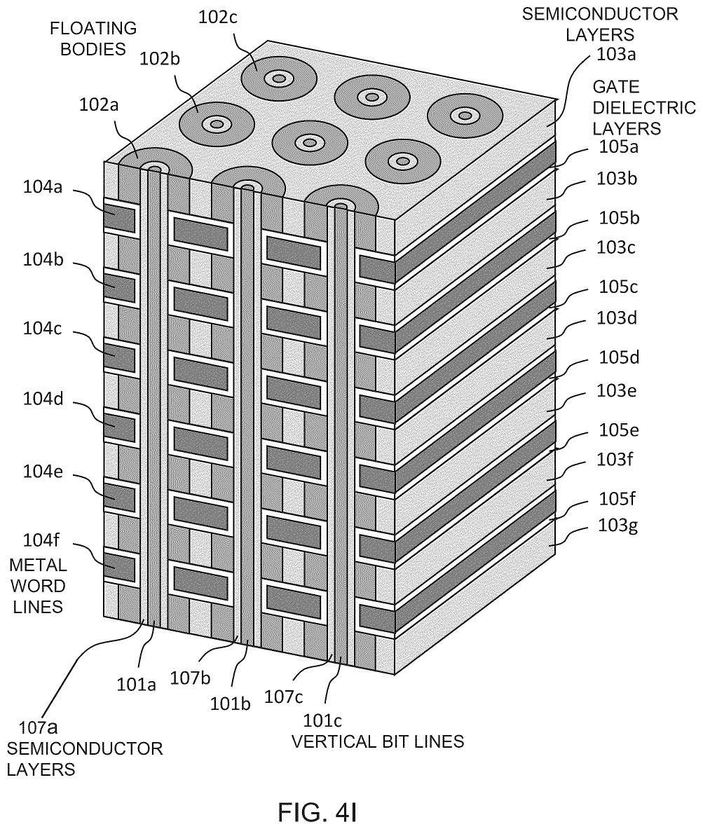

FIGS. 4A-I show embodiments of brief process steps to form a 3D array comprising the cell structure shown in FIG. 1A in accordance with the invention.

FIG. 4A shows how multiple semiconductor layers 103a to 103g and multiple sacrificial layers 110a to 110f are alternately deposited to form a stack. In one embodiment, the semiconductor layers 103a to 103g comprise silicon or polysilicon layers. The sacrificial layers 110a to 110f comprise oxide or nitride layers.

In one embodiment, the semiconductor layers 103a to 103g are formed of amorphous silicon by using atomic layer deposition (ALD), plasma-enhanced atomic layer deposition (PE-ALD), or any other suitable deposition processes, such as chemical vapor deposition (CVD), physical vapor deposition (PVD), low pressure chemical vapor deposition (LPCVD), plasma-enhanced chemical vapor deposition (PECVD), or any other suitable process.

In one embodiment, after deposition, an annealing process is applied to transfer the amorphous silicon into polycrystalline silicon (polysilicon). In one embodiment, the annealing process utilizes low-temperature rapid thermal annealing such as 4 minutes at 700 degrees Celsius or any other suitable annealing processes.

The semiconductor layers 103a to 103g are doped by using in-situ doping process during the deposition. For NMOS cells, N-type of dopants, such as phosphine (PH3) or arsine (AsH3) are added during the deposition process. For PMOS cells, P-type of dopants, such as diborane (B2H6) are added during the deposition process.

In another embodiment, the semiconductor layers 103a to 103g are formed by using a polysilicon deposition process, such as a high thermal decomposition of silane (SiH4) at 580 to 650 degrees Celsius. This process forms the polysilicon layers on the surface of the sacrificial layers 110a to 110f and releases hydrogen (H2).

In another embodiment, the semiconductor layers 103a to 103g are formed by using a silicon epitaxial growth process to form single-crystalline silicon (mono-silicon) on the surface of the sacrificial layers 110a to 110f. This process may take a longer process time because the silicon layers are grown layer by layer.

The sacrificial layers 110a to 110f are formed by using deposition processes, such as atomic layer deposition (ALD), plasma-enhanced atomic layer deposition (PE-ALD), or any other suitable deposition process, such as chemical vapor deposition (CVD), physical vapor deposition (PVD), low pressure chemical vapor deposition (LPCVD), plasma-enhanced chemical vapor deposition (PECVD), or any other suitable process.

FIG. 4B shows how multiple vertical bit line holes (or openings), such as bit line holes 111a to 111c are formed by using photolithography steps to define a pattern, and then using anisotropic etching processes, such as a deep trench process or a dry etch process to etch through the multiple semiconductor layers 103a to 103g and the sacrificial layers 110a to 110f to form the vertical bit line holes 111a to 111c.

FIG. 4C shows how floating bodies, such as floating bodies 102a to 102c are formed by using or collisional plasma doping (PLAD) or plasma immersion ion implantation (PIII), gas-phase doping, or any other suitable doping processes. For NMOS cells, diborane and hydrogen (B2H6/H2) plasma is used to implant boron ions through the vertical bit line holes 111a to 111c into the N-type semiconductor layers 103a to 103g to reverse the doping to form P-floating bodies 102a to 102c. For PMOS cells, phosphine (PH3) or Arsine (AsH3) plasma is used to implant phosphorus or Arsenic ions into the P-type semiconductor layers 103a to 103g to reverse the doping to form the N− floating bodies 102a to 102c.

FIG. 4D shows how the vertical bit line holes, such as bit line holes 111a to 111c shown in FIG. 4C, are filled with semiconductor material, such as heavily doped polysilicon to form vertical bit lines, such as vertical bit lines 101a to 101c. The semiconductor is deposited by using any suitable deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable processes. The semiconductors of the bit lines, such as bit lines 101a to 101c, are doped with the same type of heavy doping of the semiconductor layers 103a to 103g by using an in-situ doping process. For NMOS cells, N-type of dopants, such as phosphine (PH3) or arsine (AsH3) are added during the deposition of the bit lines. For PMOS cells, P-type of dopants, such as diborane (B2H6) are added during the deposition of the bit lines.

FIGS. 4E-F show embodiments of the process steps used to form the cell structure shown in FIG. 1C. After the process step shown in FIG. 4C is performed, a process step shown in FIG. 4E is performed in which semiconductor layers 107a to 107c such as polysilicon or silicon are formed on the sidewall of the vertical bit line holes 111a to 111c by using the deposition processes described with reference to FIG. 4A, such as atomic layer deposition (ALD), plasma-enhanced atomic layer deposition (PE-ALD), or any other suitable deposition processes, or by using epitaxial growth processes to grow a single-crystalline silicon layer. The semiconductor layers 107a to 107c are doped with the same type of heavy doping as the semiconductor layers 103a to 103g by using an in-situ doping process. For NMOS cells, N-type of dopants, such as phosphine (PH3) or arsine (AsH3) are added during the deposition of the semiconductor layers 107. For PMOS cells, P-type of dopants, such as diborane (B2H6) are added during the deposition of the semiconductor layers 107.

FIG. 4F shows how the vertical bit line holes 111a to 111c are filled with a high melting point metal, such as tungsten (W) to form vertical bit lines, such as vertical bit lines 101a to 101c. The tungsten is deposited by using any suitable deposition processes, such as chemical vapor deposition (CVP) reaction with tungsten hexafluoride (WF6) plus hydrogen (H2) and silane (SiH4). The metal bit lines 101a to 101c reduce the bit line resistance.

Before depositing the metal in the vertical bit line holes 111a to 111c, a glue layer (not shown) such as a titanium and titanium nitride (Ti/TiN) layer may be formed on the surface of the semiconductor layer 107a to 107c. The glue layer helps to prevent peeling of the metal bit lines 101a to 101c from the semiconductor layer 107a to 107c and improves the reliability. The TiN and Ti layers are formed by using chemical vapor deposition (CVD) and ion metal plasma (IMP) physical vapor deposition (PVD) process, respectively. In various embodiments, a glue layer, such as the glue layer applied to the semiconductor layer 107 is optional and can be omitted if desired.

FIG. 4G shows how the sacrificial layers 110a to 110f are selectively removed by using an isotropic etching process such as wet etching. If the sacrificial layers 110a to 110f are oxide layers (SiO2), they can be etched by using buffered hydrofluoric acid (HF), ammonium acid (NH4F) or a mixture of hydrofluoric acid (HF) and nitric acid (HNO3). If the sacrificial layers 110a to 110f are nitride layers (Si3N4), they can be etched by using concentrated hot orthophosphoric acid (H3PO4) at a temperature of 150 to 180 degrees Celsius.

FIG. 4H shows how gate dielectric layers 105a to 105f, such as a gate oxide (SiO2) layers or a high-K material layers, such as hafnium oxide (HfO2), zirconium oxide (ZrO2), or titanium oxide (TiO2) are formed on the surface of the sidewall of the spaces that are previously occupied by the sacrificial layers 110a to 110f. The gate dielectric layers 105a to 105f are formed by using thermal oxidation or dry oxidation to grow silicon oxide (SiO2) layers on the surfaces of the semiconductor layers 103a to 103g and the vertical bit lines such as 101a to 101c, or using atomic layer deposition (ALD), plasma-enhanced atomic layer deposition (PE-ALD), or any other suitable deposition processes to deposit a thin layer of the gate dielectric material on the surface of the spaces.

FIG. 4I shows how the spaces that were previously occupied by the sacrificial layers 110a to 110f are filled with metal material, such as tungsten (W), tantalum (Ta), titanium (Ti), niobium (Nb) for NMOS cells, or ruthenium (Ru) for PMOS cells, or the composite of metal nitride such as WN, TaN, and TiN, or heavily doped polysilicon to form the metal word lines (or gates) 104a to 104f of the cell transistors. The metal word lines 104a to 104f are formed by using deposition processes, such as atomic layer deposition (ALD), plasma-enhanced atomic layer deposition (PE-ALD), chemical vapor deposition (CVD), physical vapor deposition (PVD), low pressure chemical vapor deposition (LPCVD), plasma-enhanced chemical vapor deposition (PECVD), or any other suitable processes. As a result, the array comprising a floating-body cell structure as shown in FIG. 1C is formed.

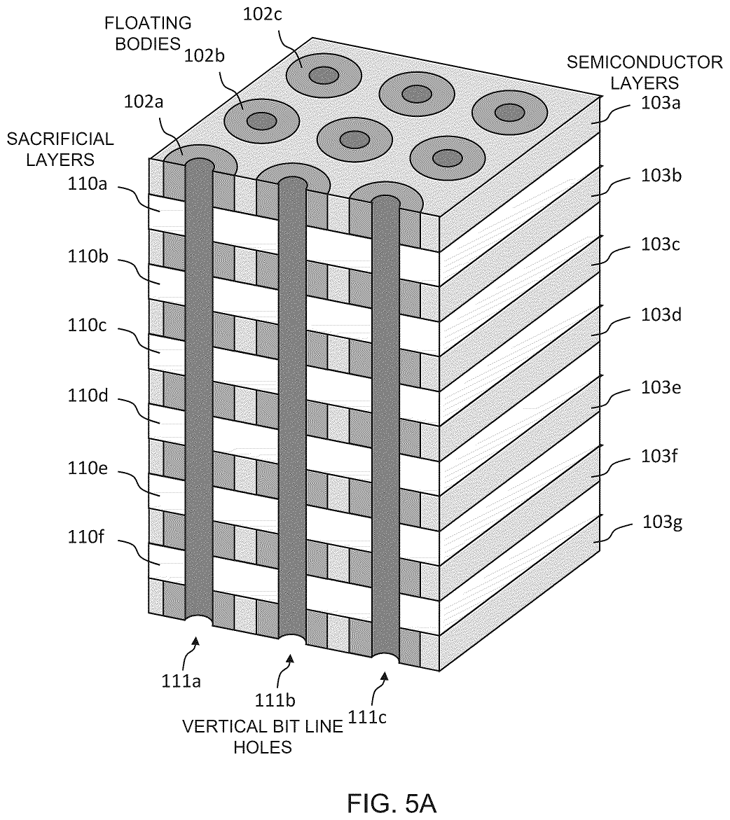

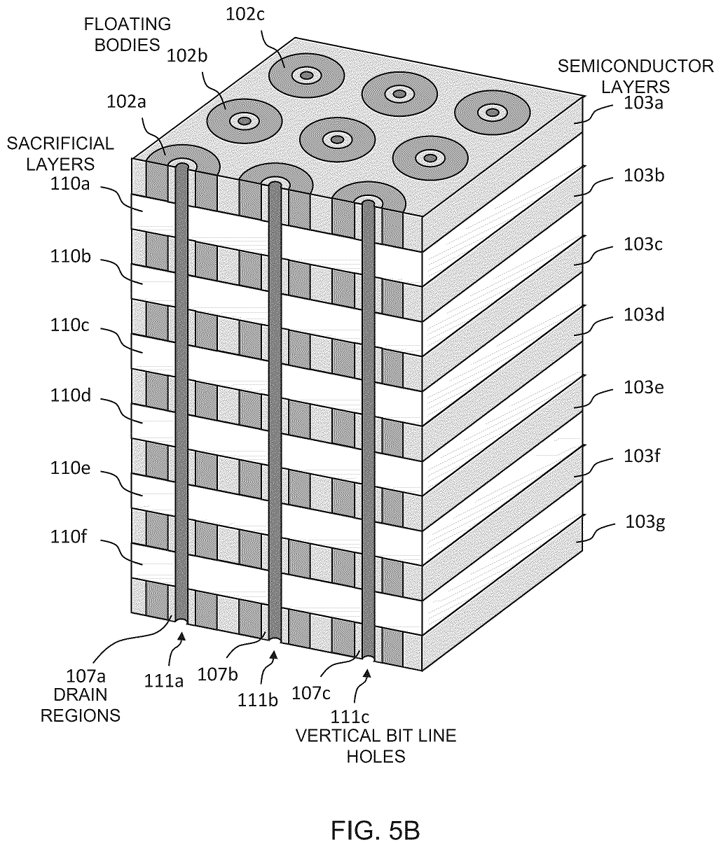

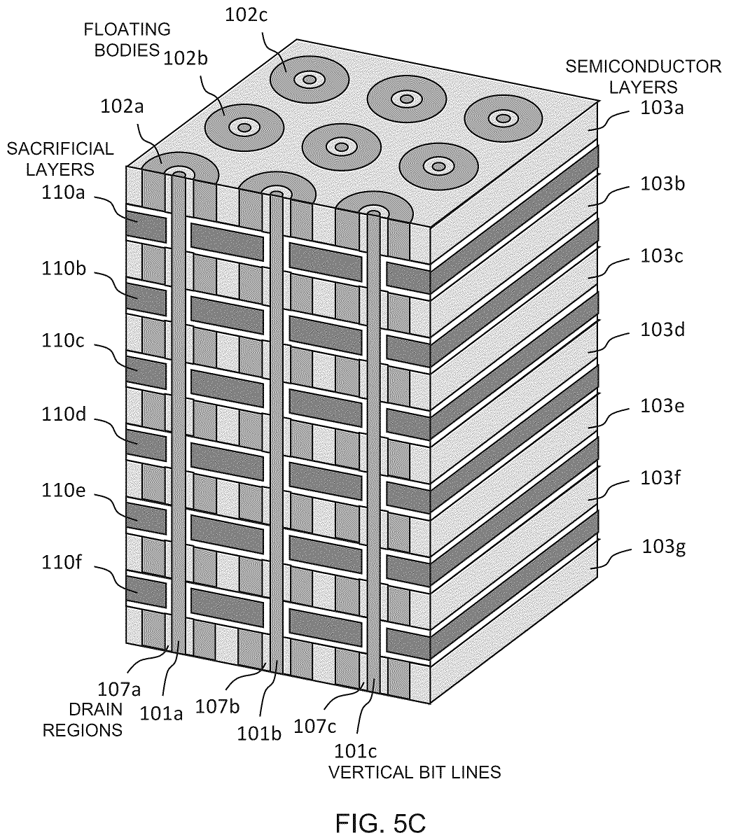

FIGS. 5A-C show embodiments of brief process steps to form an array using the cell structure shown in FIG. 1E according to the invention.

FIG. 5A shows an array structure that is formed after the process step shown in FIGS. 4A-C. The reader is referred to FIGS. 4A-C for a detailed description for forming the array structure shown in FIG. 5A.

FIG. 5B shows how drain regions, such as drain regions 107a to 107c are formed by using plasma doping (PLAD) or gates-phase doping or any other suitable doping processes to dope the opposite type of heavy dopants into the floating bodies, such as floating bodies 102a to 102c. This doping process is performed through the vertical bit line holes, such as bit line holes 111a to 111c. For NMOS cells, phosphine (PH3) or Arsine (AsH3) plasma is used to implant phosphorus or Arsenic ions into the P-type floating bodies, such as 102a to 102c to reverse the doping to form N+ drain regions, such as 107a to 107c. For PMOS cells, diborane and hydrogen (B2H6/H2) plasma is used to implant boron ions into the N-type floating bodies, such as 102a to 102c to reverse the doping to form a P+ drain regions, such as 107a to 107c.

After the process steps described with reference to FIG. 5B are performed, the process steps shown in FIGS. 4F-I are performed to form the array structure shown in FIG. 5C. The reader is referred to FIGS. 4F-I for the detailed description of those process steps. As a result, an array comprising a floating-body cell structure is formed as shown in FIG. 1E.

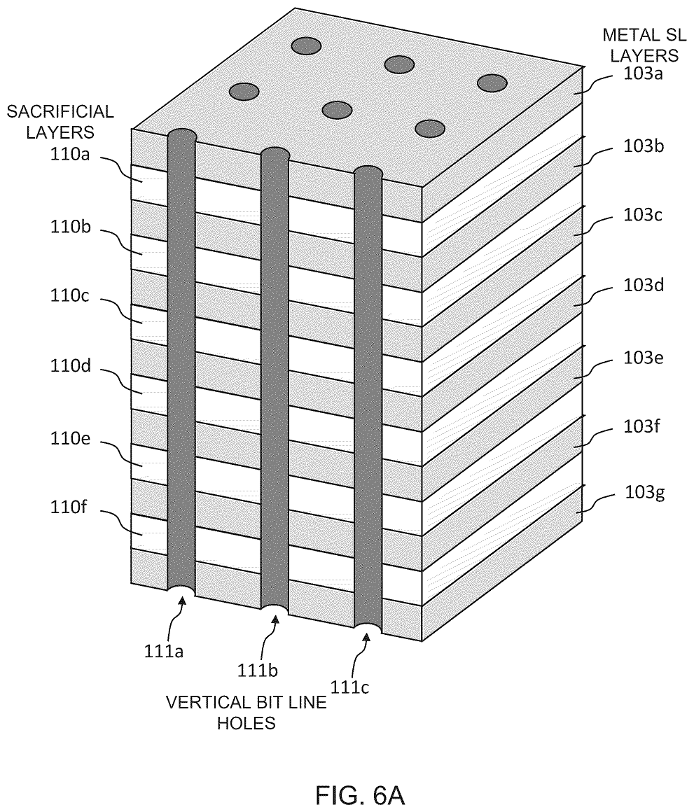

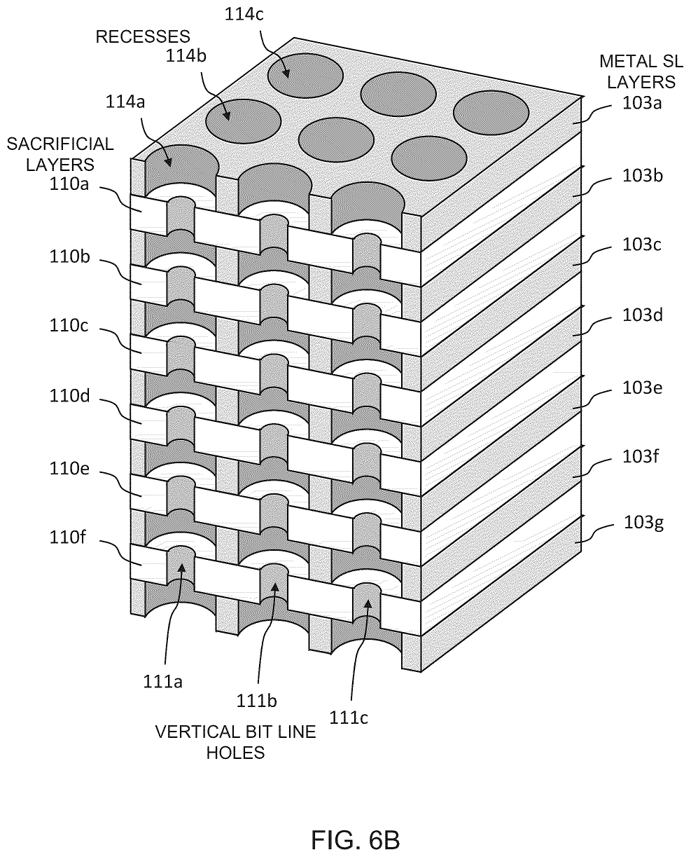

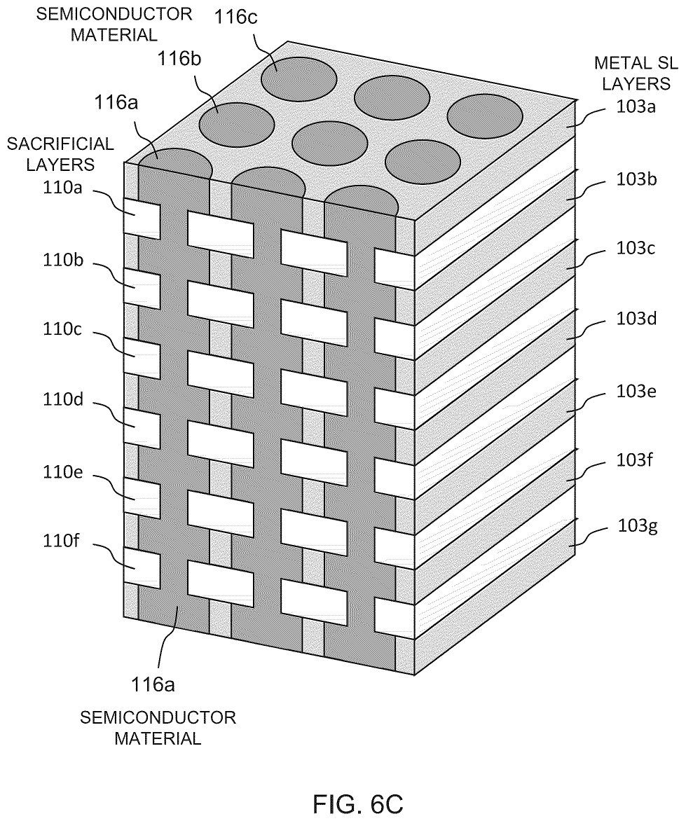

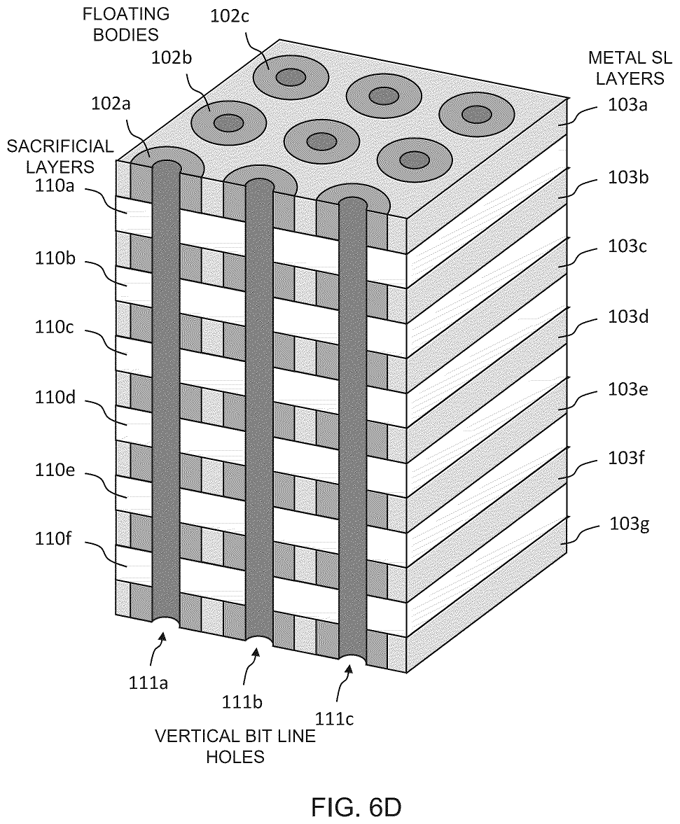

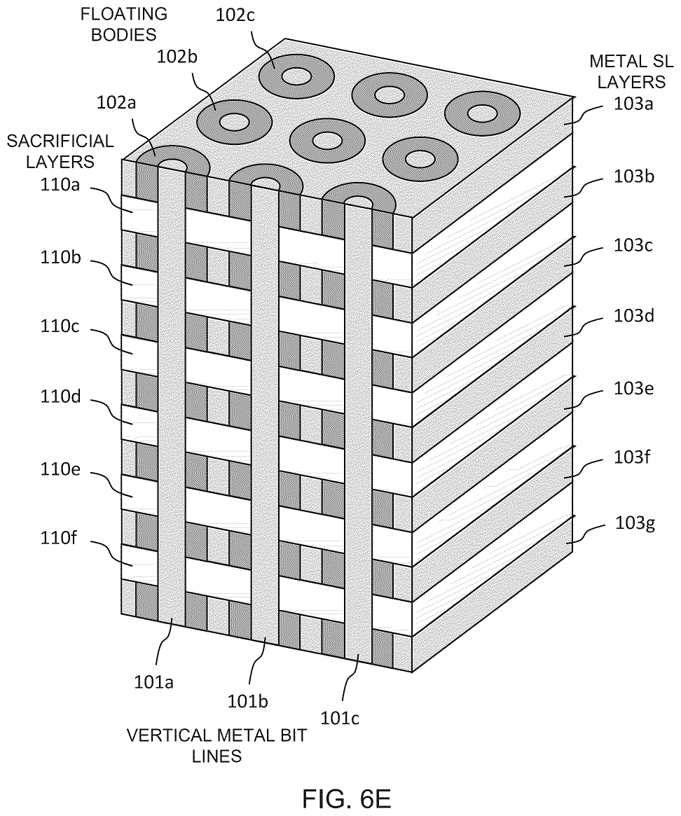

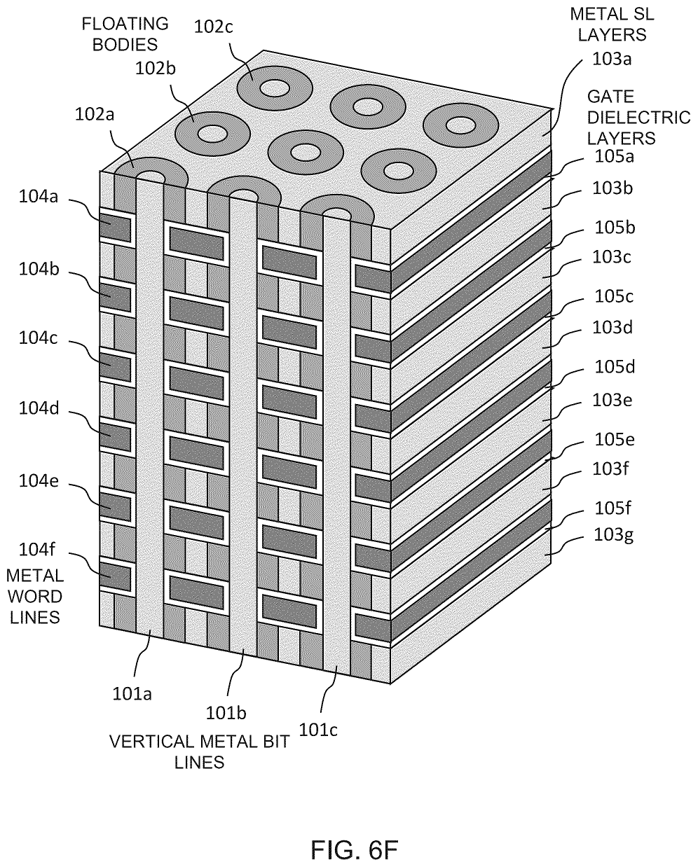

FIGS. 6A-F show embodiments of brief process steps to form an array using the cell structure shown in FIG. 1I according to the invention.

FIG. 6A shows an array structure that is formed after the process steps shown and described with reference to FIGS. 4A-B. The reader is referred to FIGS. 4A-B for the detailed description of the process steps to form the array structure shown in FIG. 6A. In this embodiment, source line (SL) layers 103a to 103g are formed from high melting point metal, such as tungsten (W). The tungsten is deposited by using any suitable deposition process, such as chemical vapor deposition (CVP) reaction with tungsten hexafluoride (WF6) plus hydrogen (H2) and silane (SiH4).

FIG. 6B shows how an isotropic etching process, such as wet etching is performed through the vertical bit line holes, such as 111a to 111c to selectively etch the sacrificial layers 110a to 110f to form recesses, such as recesses 114a to 114c. The dimension of the recesses 114a to 114c are controlled by the etching rate of the etching solution and the etching time. If the first sacrificial layers 110a to 110f are formed of silicon oxide (SiO2), they can be etched by using buffered hydrofluoric acid (HF) with ammonium acid (NH4F) or a mixture of hydrofluoric acid (HF) and nitric acid (HNO3).

FIG. 6C shows how the recesses, such as recesses 114a to 114c and the vertical bit line holes, such as vertical bit line holes 111a to 111c, are filled with semiconductor material 116, such as polysilicon or silicon. In one embodiment, the polysilicon is formed by using a polysilicon deposition process comprising the silicon epitaxial growth process described with reference to FIG. 4A. The reader is referred to FIG. 4A for a detailed description of a polysilicon deposition process. The semiconductor material 116 is doped by using an in-situ doping process. For NMOS cells, N-type of dopants, such as phosphine (PH3) or arsine (AsH3) are added during the deposition process. For PMOS cells, P-type of dopants, such as diborane (B2H6) added during the deposition process.

FIG. 6D shows how an anisotropic etching process, such as dry etching is performed using the sacrificial layers 110a to 110f as hard masks to selectively etch the semiconductor material 116 to re-form the vertical bit line holes, such as vertical bit line holes 11a to 111c. Because this etching process is self-aligned, a high yield can be achieved. After the vertical bit line holes, such as vertical bit line holes 111a to 111c are re-formed, the semiconductor material 116 in the recesses (e.g., such as recesses 114a to 114c) becomes the floating bodies, such as floating bodies 102a to 102c of the cell transistors.

FIG. 6E shows how the vertical bit line holes, such as 111a to 111c are filled with high meting point metal, such as tungsten (W) to form the vertical metal bit lines, such as metal bit lines 101a to 101c. The tungsten is deposited by using any suitable deposition process, such as chemical vapor deposition (CVP) reaction with tungsten hexafluoride (WF6) plus hydrogen (H2) and silane (SiH4).

After filling the vertical bit line holes 111 to form the metal bit lines 101, the process steps shown and described with reference to FIGS. 4G-I are performed to form the array structure shown in FIG. 6F. For example, the sacrificial layers 110 are removed, gate dielectric layers 105 are deposited, and the metal word lines 104 are formed. The reader is referred to FIGS. 4G-I for the detailed description of those process steps. In this embodiment, the vertical bit lines, such as metal bit lines 101a to 101c and the source line layers 103a to 103g are formed of metal. As a result, the array comprising the floating-body cell structure shown in FIG. 1I is formed.

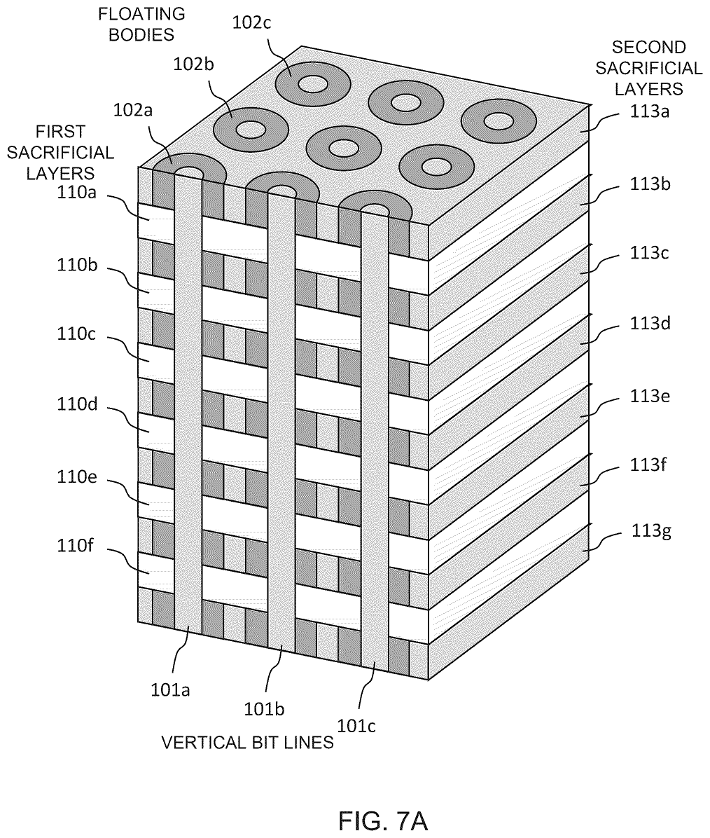

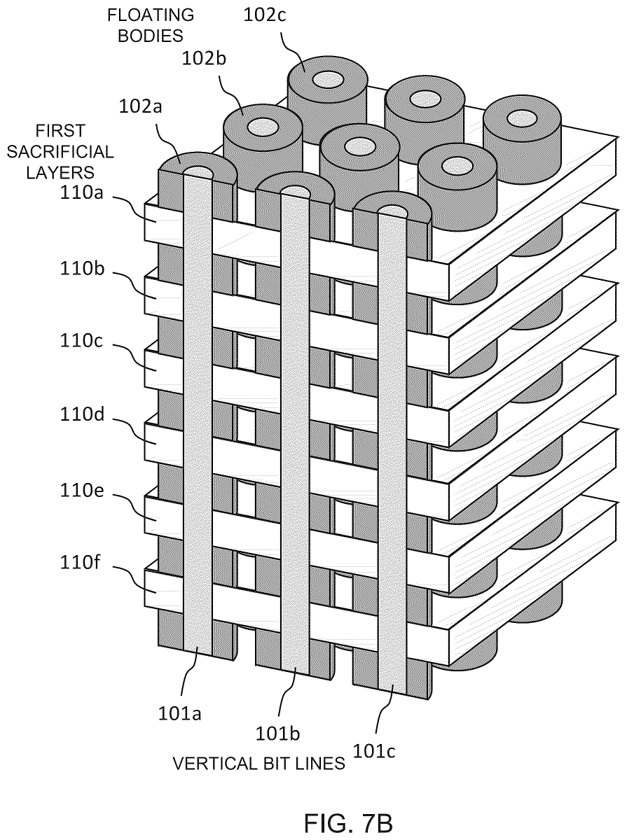

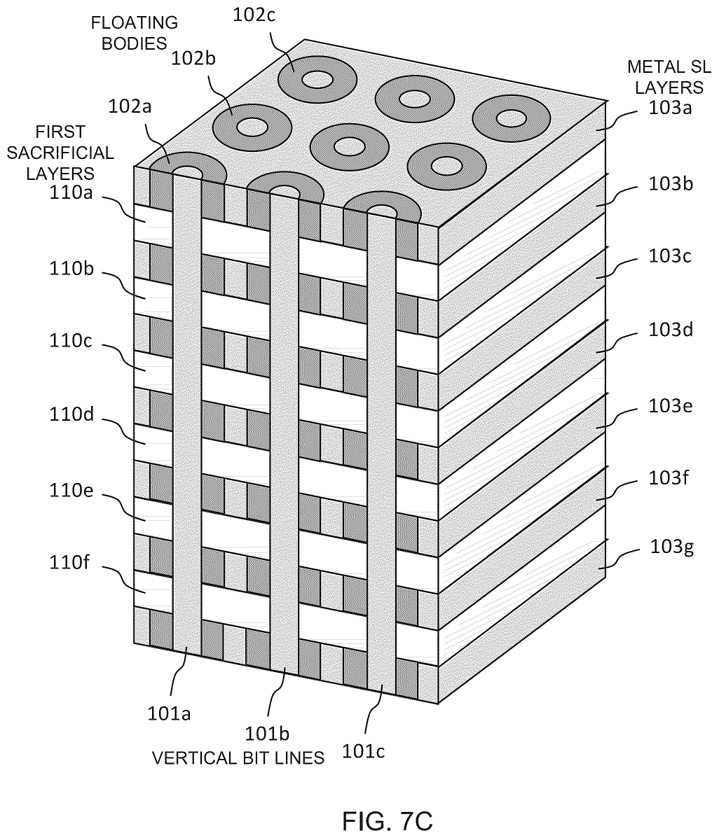

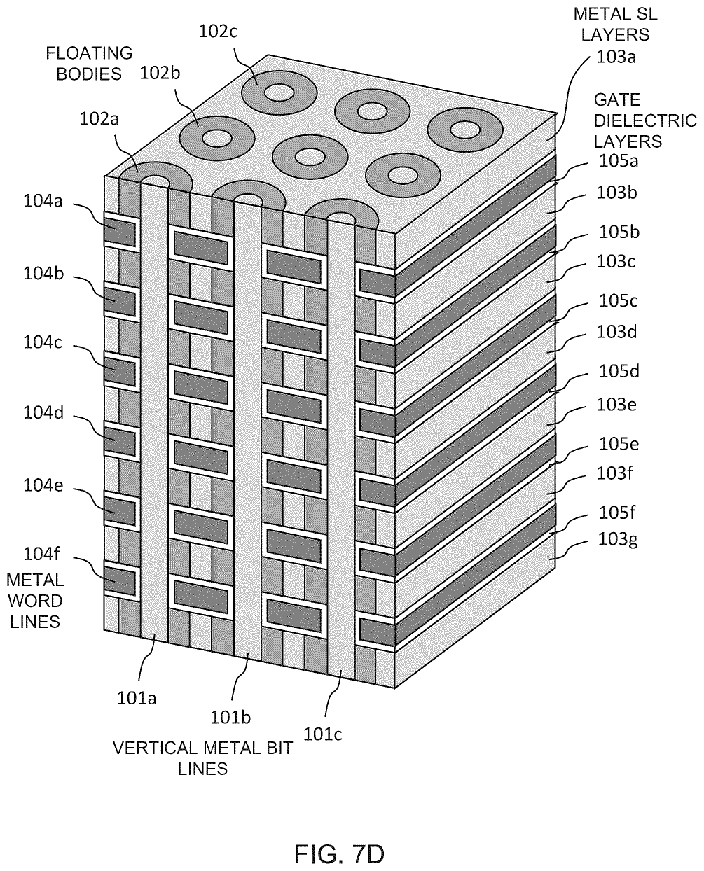

FIGS. 7A-D show embodiments of brief process steps to form an array comprising the cell structure shown in FIG. 1I according to the invention.

FIG. 7A shows an array structure constructed after performing the process steps shown in FIGS. 4A-D. The reader is referred to FIGS. 4A-D for the detailed description of those process steps. In this embodiment, the layers 113a to 113g are formed of a second sacrificial material, such as oxide or nitride. The second sacrificial layers 113a to 113g and the first sacrificial layers 110a to 110f are configured to have different etching selectivity. For example, in one embodiment, the first sacrificial layers 110a to 110f are formed of oxide and the second sacrificial layers 103a to 103g are formed of nitride.

FIG. 7B shows how the second sacrificial layers 113a to 113g are selectively removed by using an isotropic etching process, such as wet etching. If the second sacrificial layers 113a to 113g are formed of silicon oxide (SiO2), they can be etched by using buffered hydrofluoric acid (HF) with ammonium acid (NH4F) or a mixture of hydrofluoric acid (HF) and nitric acid (HNO3).

FIG. 7C shows how a high melting point metal, such as tungsten (W) is deposited to fill the spaces that are previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4).

After the process of depositing the metal described above, the process steps shown and described with reference to FIGS. 4G-I are performed to form the array structure shown in FIG. 7D. For example, the sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure shown in FIG. 1I is formed.

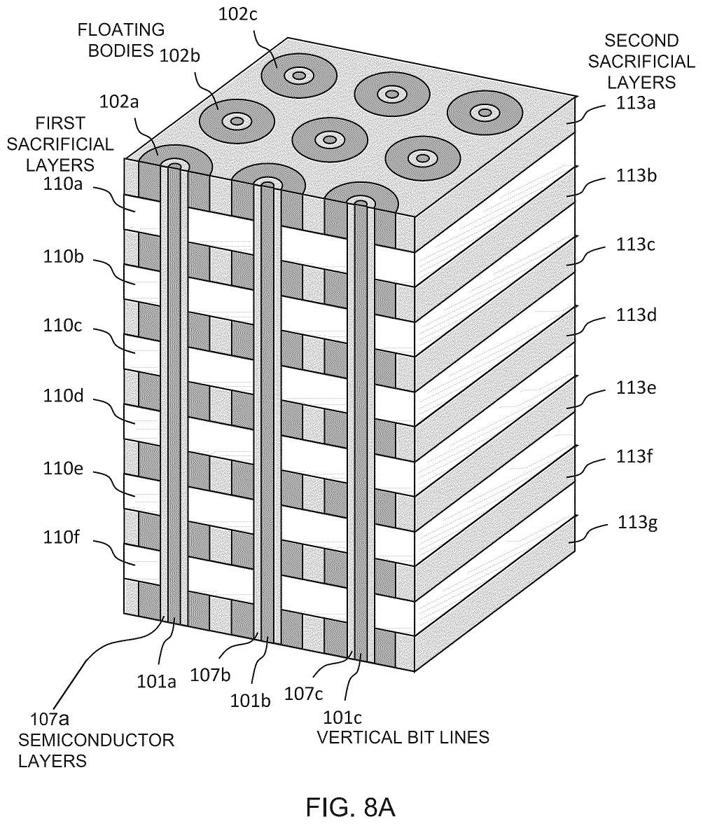

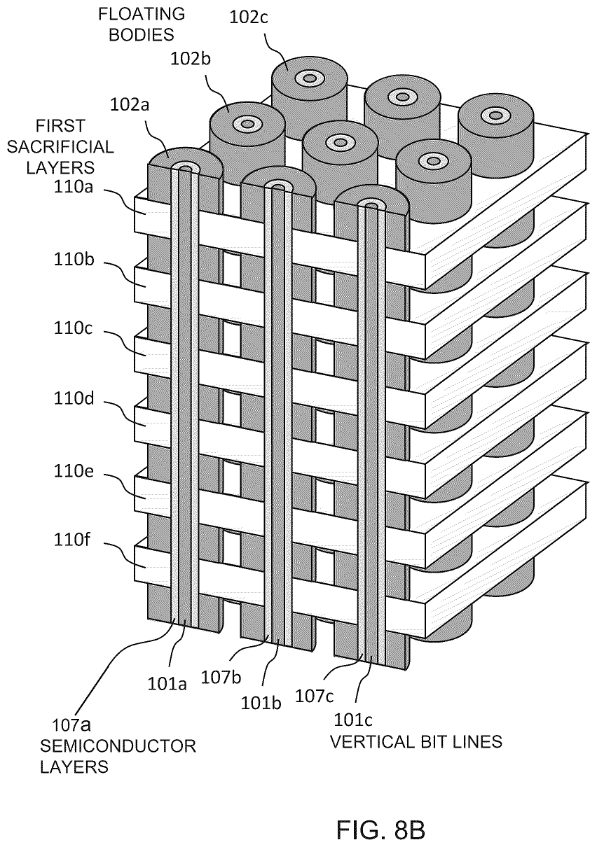

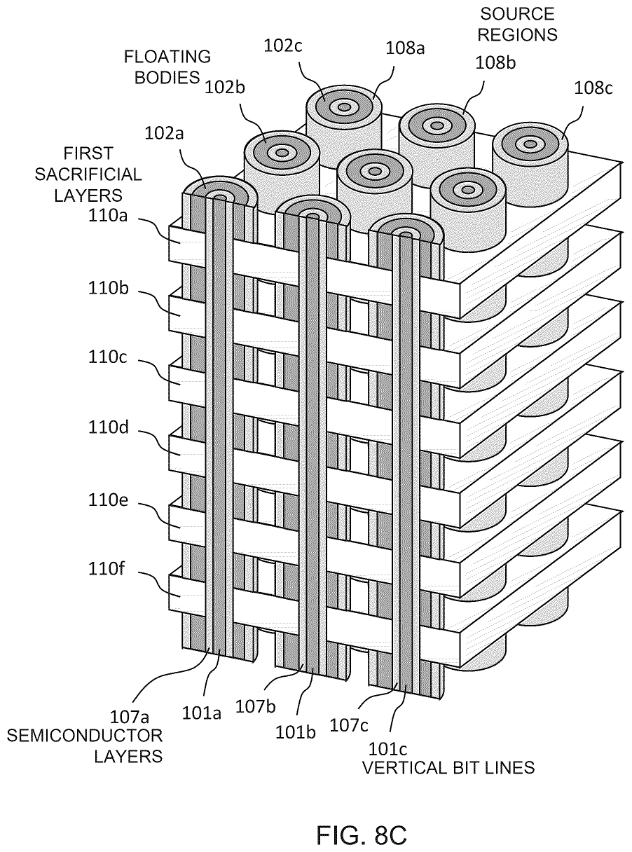

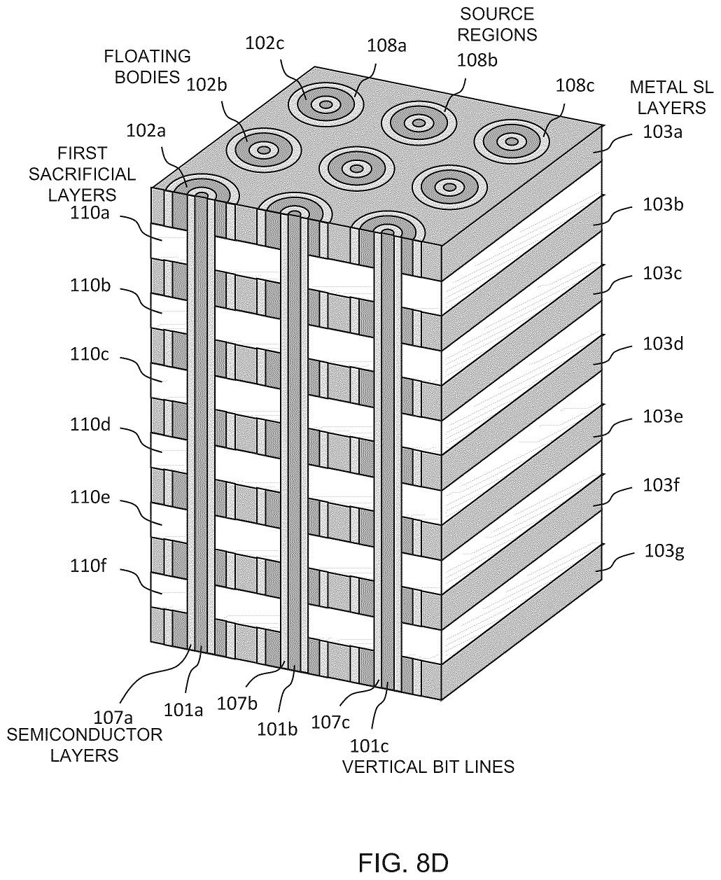

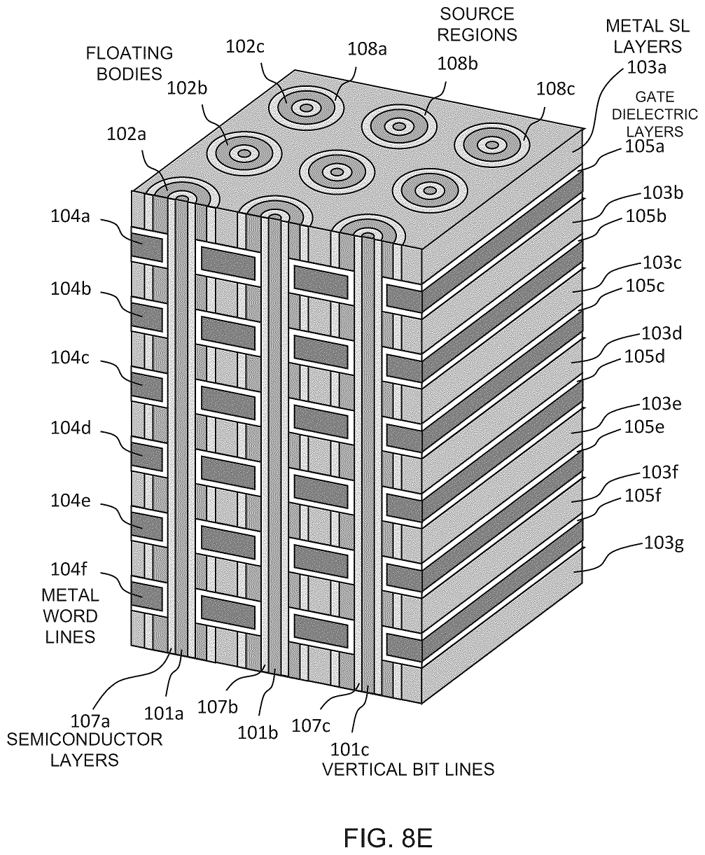

FIGS. 8A-E show another embodiment of brief process steps to form an array comprising the cell structure shown in FIG. 1G according to the invention.

FIG. 8A shows an array structure that is formed after performing the process steps shown in FIGS. 4A-F. The reader is referred to FIGS. 4A-F for the detailed description of the process steps to form this array structure. In this embodiment, the layers 113a to 113g are formed of a second sacrificial material, such as oxide or nitride. The second sacrificial layers 113a to 113g and the first sacrificial layers 110a to 110f are configured to have different etching selectivity. For example, in one embodiment, the first sacrificial layers 110a to 110f are formed of oxide and the second sacrificial layers 103a to 103g are formed of nitride.

FIG. 8B shows how the second sacrificial layers 113a to 113g are selectively removed by using an isotropic etching process, such as wet etching. If the second sacrificial layers 113a to 113g are formed of silicon oxide (SiO2), they can be etched by using buffered hydrofluoric acid (HF) with ammonium acid (NH4F) or a mixture of hydrofluoric acid (HF) and nitric acid (HNO3).

FIG. 8C shows how source regions, such as 108a to 108c are formed by using plasma doping (PLAD) or a gas-phase doping process or any other suitable doping process with the opposite type of heavy dopants to reverse the doping type of the floating bodies, such as 102a to 102c.

FIG. 8D shows how a high melting point metal, such as tungsten (W) is deposited to fill the spaces that were previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4).

After the metal is deposited as described above, the process steps shown in FIGS. 4G-I are performed to form the array structure shown in FIG. 8E. For example, the first sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure shown in FIG. 1G is formed.

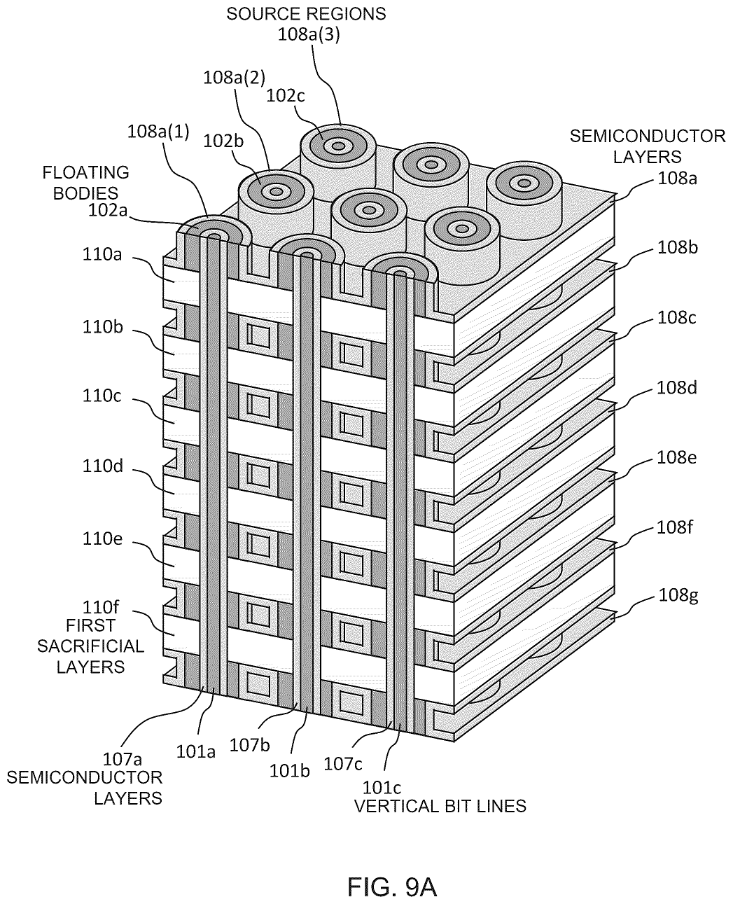

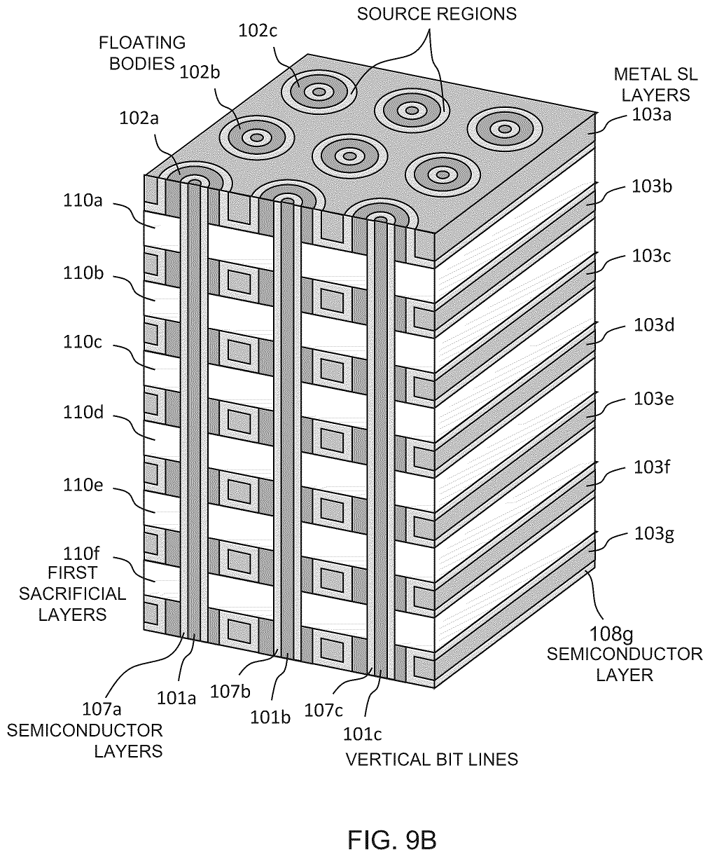

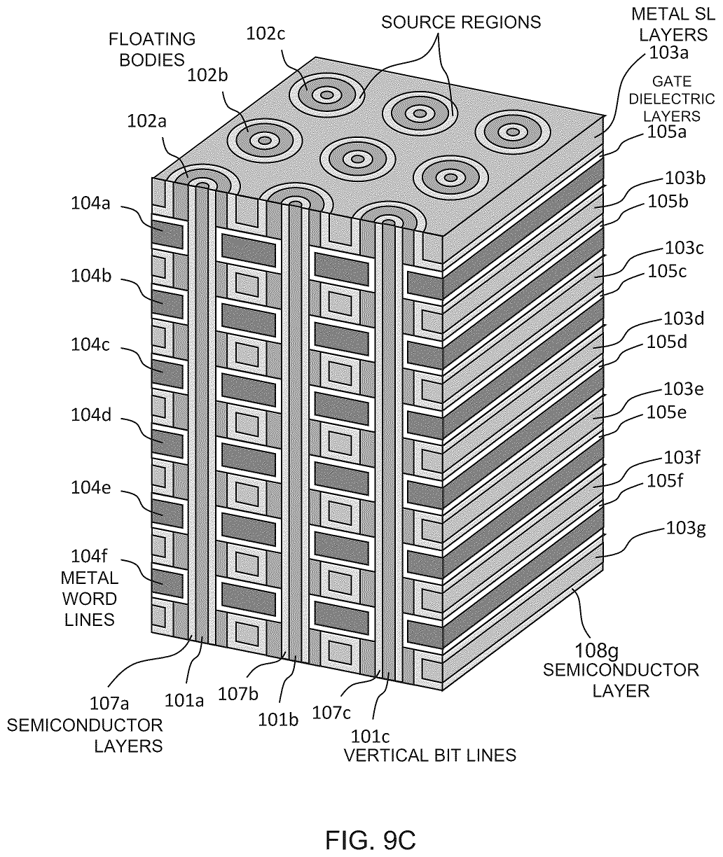

FIGS. 9A-C show alternative embodiments for forming the source regions, such as 108a to 108c for the array having the cell structure shown in FIG. 1G. After the process steps shown and described with reference to FIG. 8B are performed, the process steps shown in FIG. 9A are performed.

FIG. 9A shows how semiconductor layers 108a-g, such as polysilicon or silicon are formed on the surface of the sidewall of the spaces that are previously occupied by the second sacrificial layers 113a to 113g. Each semiconductor layer 108 forms source regions, such as source regions 108a(1) to 108a(3) on the sidewalls of the floating bodies, such as floating bodies 102a to 102c.

In one embodiment, the semiconductor layers 108 are formed by the polysilicon deposition process, or the silicon epitaxial growth process as described with reference to FIG. 4A. The semiconductor layers 108 are doped using an in-situ doping process. For NMOS cells, N-type of dopants, such as phosphine (PH3) or arsine (AsH3) are added during the deposition process. For PMOS cells, P-type of dopants, such as diborane (B2H6) are added during the deposition process.

FIG. 9B shows how a high melting point metal, such as tungsten (W) is deposited to fill the spaces that were previously occupied by the second sacrificial layers 113a to 113g to form the metal source line layers 103a to 103g. The tungsten is deposited by using any suitable deposition process, such as chemical vapor deposition (CVP) reaction with tungsten hexafluoride (WF6) plus hydrogen (H2) and silane (SiH4). After depositing the metal, the process steps shown and described with reference to FIGS. 4G-I are performed to form the array structure shown in FIG. 9C. For example, the first sacrificial layers 110 are removed, gate dielectric layers 105 are deposited, and the metal word lines 104 are formed. The reader is referred to FIGS. 4G-I for the detailed description of those process steps.

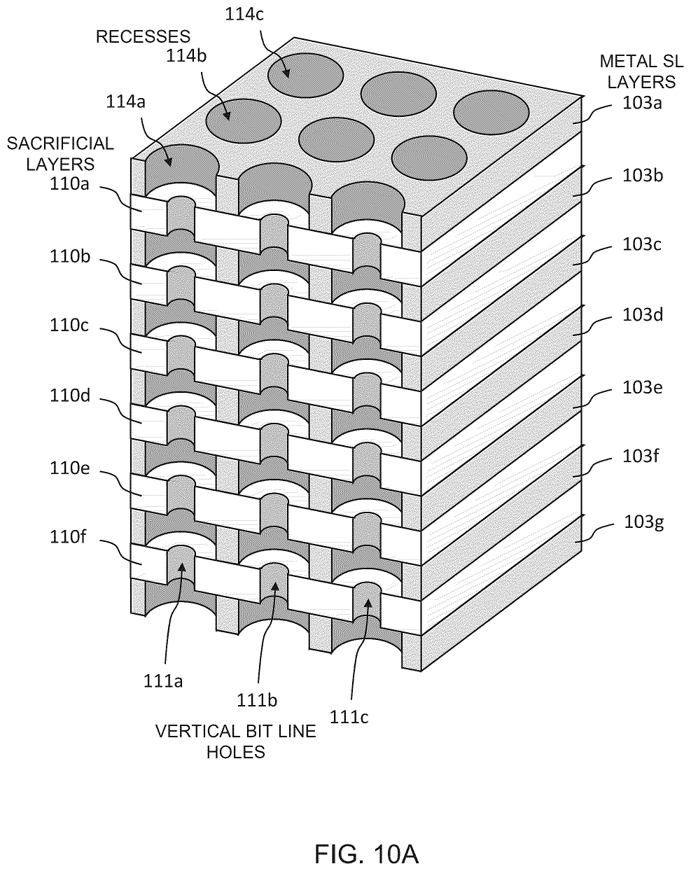

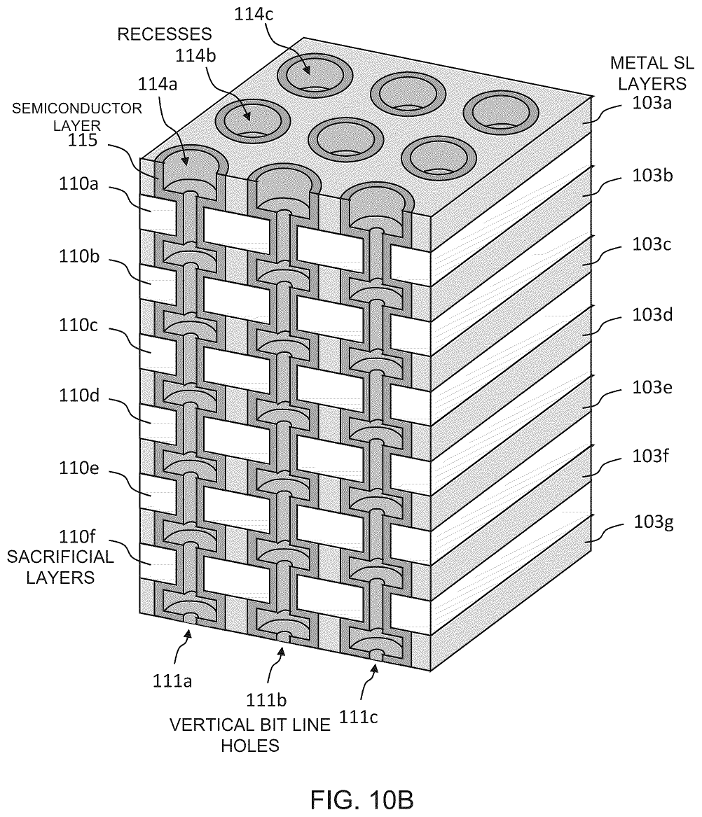

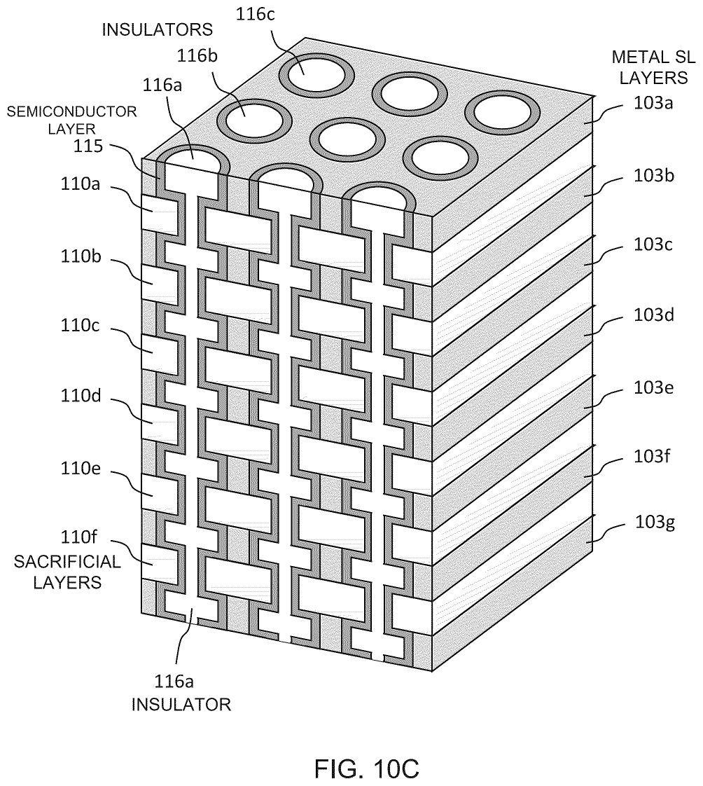

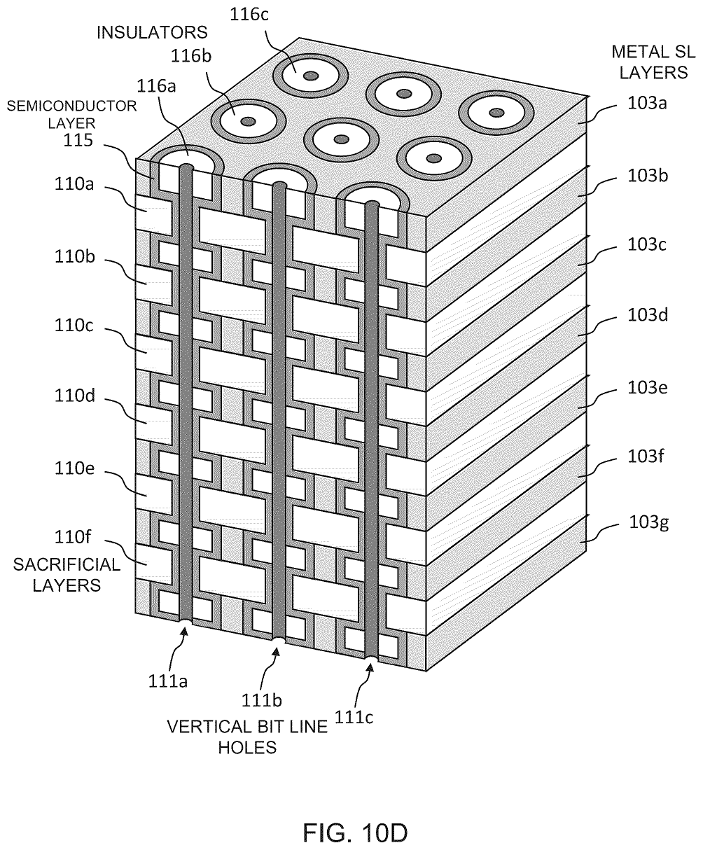

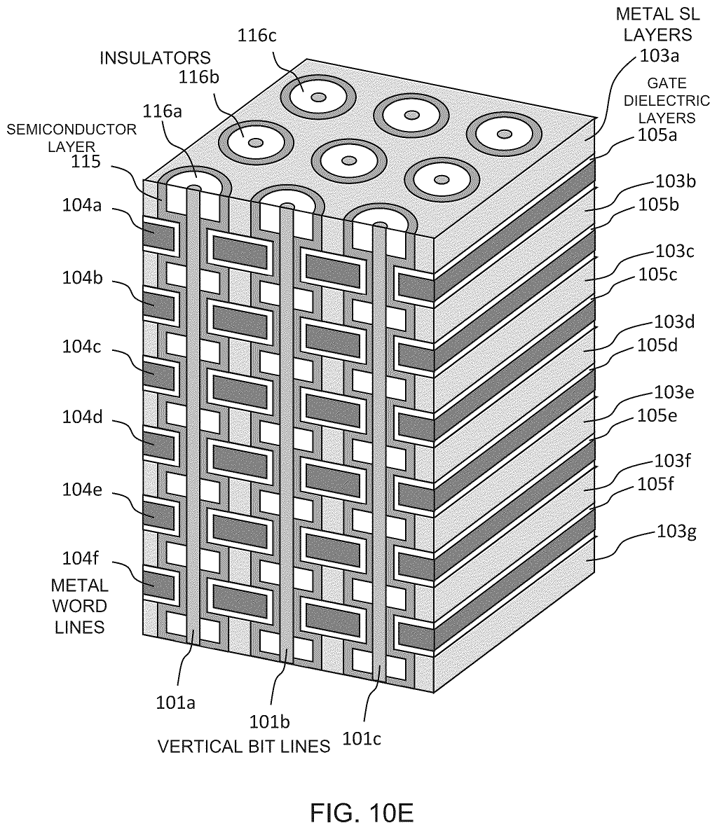

FIGS. 10A-E show another embodiment of brief process steps that are performed to form an array comprising the cell structure shown in FIG. 1K according to the invention.

FIG. 10A shows an array structure constructed after performing the process steps shown in FIGS. 6A-B. The reader is referred to FIGS. 6A-B for the detailed description of the process steps performed to form this array structure.

FIG. 10B shows how a semiconductor layer 115, such as silicon, polysilicon, silicon germanium (SiGe), indium gallium zinc oxide (IGZO), tungsten-doped indium oxide semiconductor, or any other suitable semiconductor material is formed on the surface of the sidewalls of the recesses 114, such as recesses 114a to 114c and the vertical bit line holes, such as 111a to 111c by using an epitaxial process or a deposition process as described with reference to FIG. 4A. The reader is referred to FIG. 4A for the detailed description of those processes.

FIG. 10C shows that after the semiconductor layer 115 is formed, an insulator material 116, such as oxide or nitride is deposited to fill the recesses, such as the recesses 114a to 114c and the vertical bit line holes 111a to 111c.

FIG. 10D shows how an anisotropic etching process, such as dry etching, is performed using the sacrificial layers 110a to 110f and the semiconductor layer 115 as hard masks to selectively etch the insulator material 116 inside the vertical bit line holes, such as bit line holes 111a to 111c. Because this etching process is self-aligned, the process achieves a high yield.

After the etching process described above, the vertical bit line holes, such as bit line holes 111a to 111c are filled with a conductor material, such as metal or polysilicon by using a deposition process to form the vertical bit lines such as bit lines 101a to 101c. Then, the process steps shown and described with reference to FIGS. 4G-I are performed to form the array structure shown in FIG. 10E. For example, the first sacrificial layers 110 are removed, gate dielectric layers 105 are deposited, and the metal word lines 104 are formed. The reader is referred to FIGS. 4G-I for the detailed description of those process steps. As a result, the array comprising a floating-body cell structure as shown in FIG. 1K is formed.

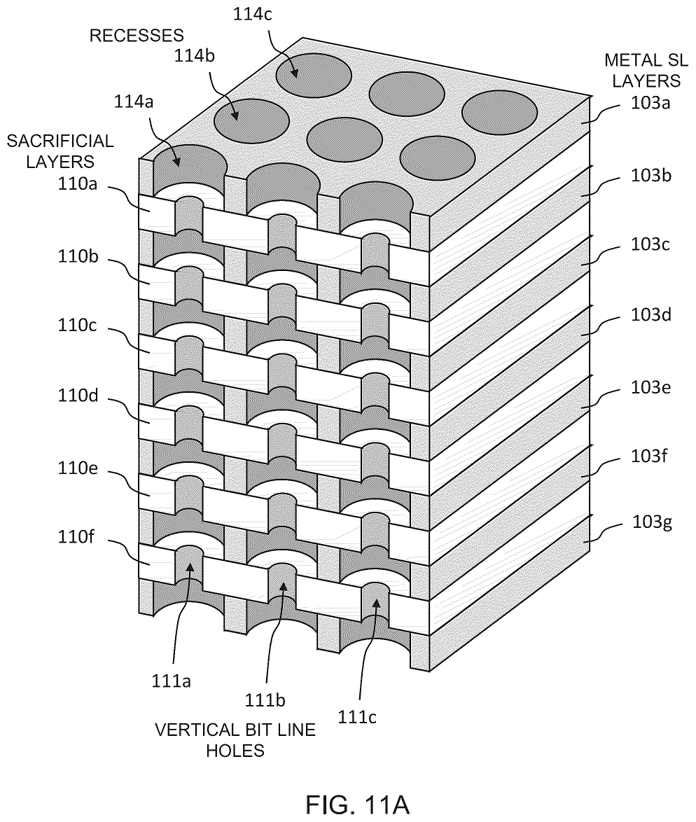

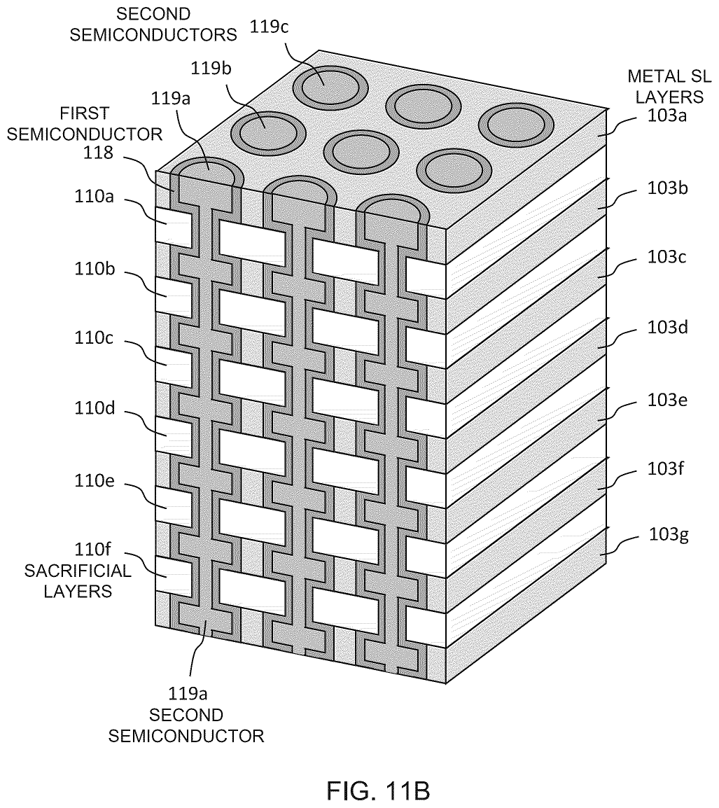

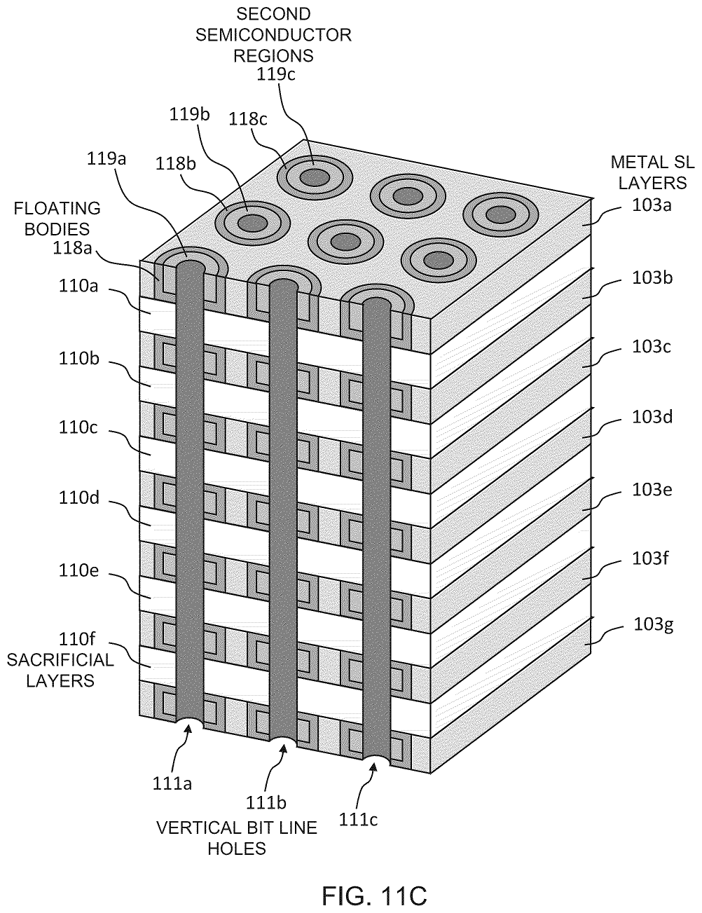

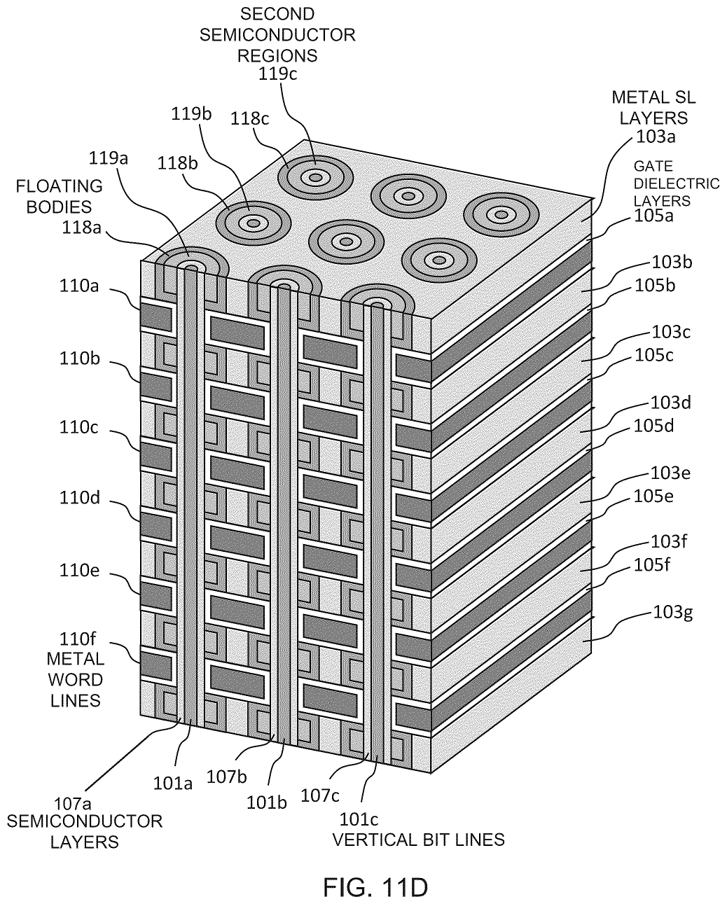

FIGS. 11A-D show another embodiment of brief process steps configured to form an array comprising the cell structure shown in FIG. 1M according to the invention.

FIG. 11A shows an array structure that results after performing the process steps shown in FIGS. 6A-B. The reader is referred to FIGS. 6A-B for the detailed description of the process steps performed to form this array structure.

FIG. 11B shows how a first semiconductor layer 118, such as silicon or polysilicon is formed on the surface of the sidewalls of the recesses, such as recesses 114a to 114c and the vertical bit line holes, such as bit line holes 111a to 111c by using a silicon epitaxial process or a polysilicon deposition process as described with reference to FIG. 4A. The reader is referred to FIG. 4A for the detailed description of those processes.

After the first semiconductor layer 118 is formed, a second semiconductor material 119 is deposited to fill the recesses, such as recesses 114a to 114c and the vertical bit line holes, such as bit line holes 111a to 111c. In one embodiment, the second semiconductor material 119 is different from the first semiconductor layer 118. For example, in one embodiment, the first semiconductor layer 118 is formed of silicon or polysilicon, and the second semiconductor material 119 comprises silicon Germanium (SiGe), silicon carbide (SiC), or any other suitable semiconductor material.

FIG. 11C shows how an anisotropic etching process, such as dry etching is performed using the sacrificial layers 110a to 110f as hard masks to selectively etch the semiconductor layer 118 and the second semiconductor material 119 inside the vertical bit line holes, such as bit line holes 111a to 111c. Because this etching process is self-aligned, it achieves a high process yield. After the vertical bit line holes, such as bit line holes 111a to 111c are formed, the semiconductor layers 118a to 118c become the individual floating bodies of each cell, and the second semiconductor materials 119a to 119c become the second semiconductor regions for electric charge storage.

After the etching process described above, the process steps shown in FIGS. 4E-I are performed to form the array structure shown in FIG. 11D. For example, the first sacrificial layers 110 are removed, gate dielectric layers 105 are deposited, the metal word lines 104 are formed, the semiconductor layers 107 are deposited and the vertical bit line 101 are formed. The reader is referred to FIGS. 4E-I for the detailed description of those process steps. As a result, the array shown in FIG. 11D comprising the floating-body cell structure shown in FIG. 1M is formed.

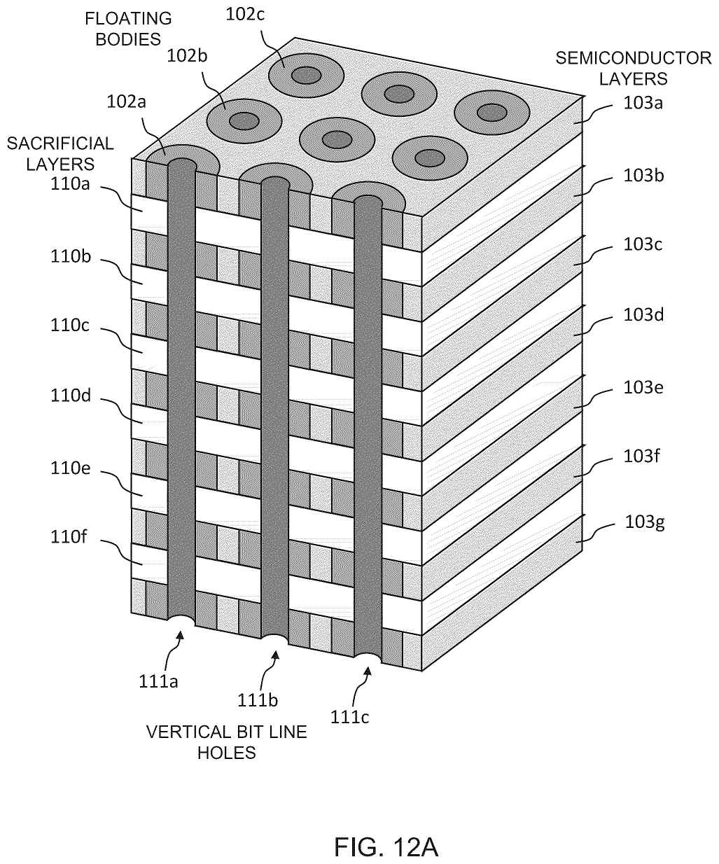

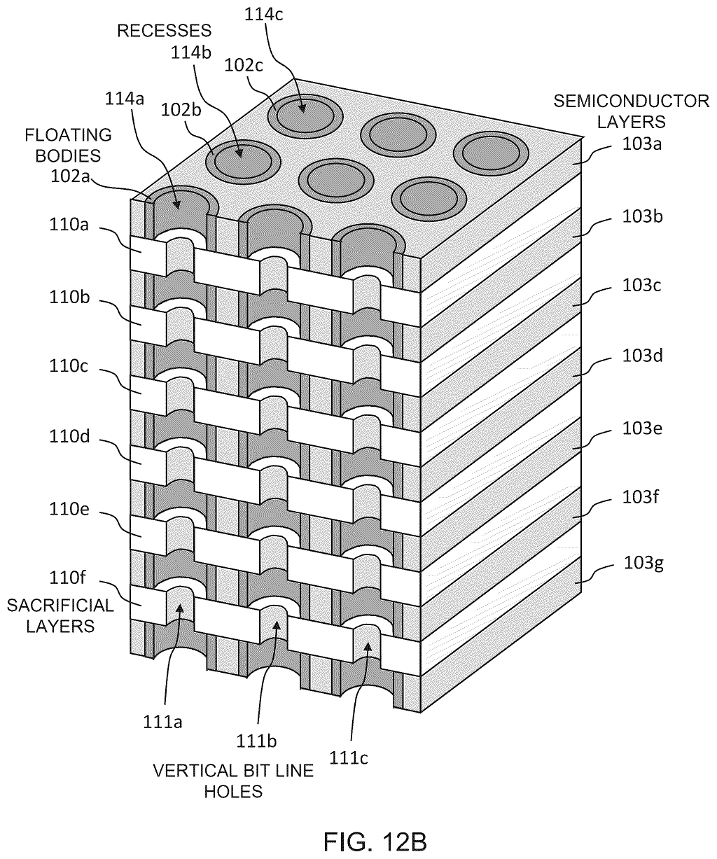

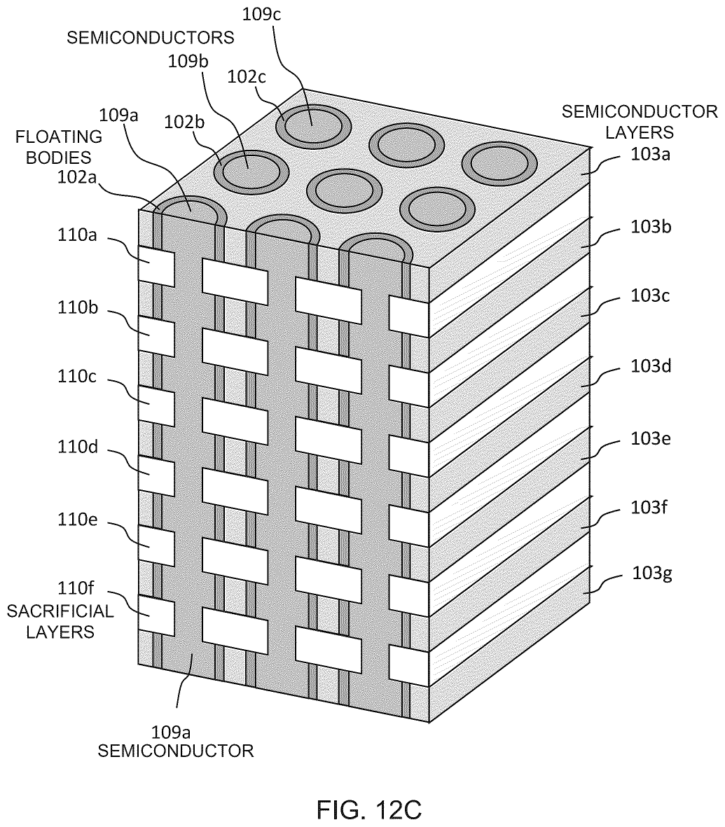

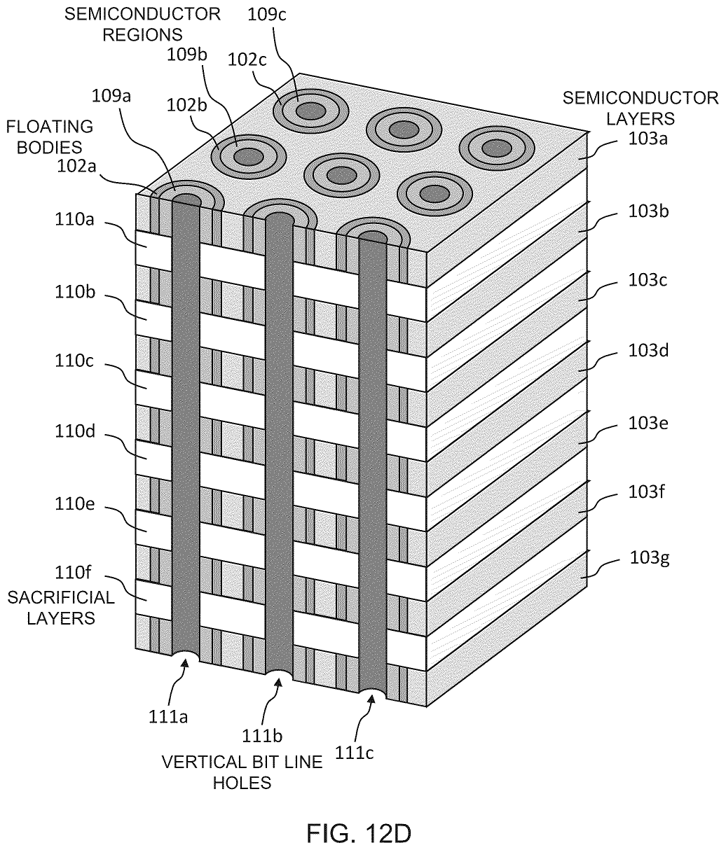

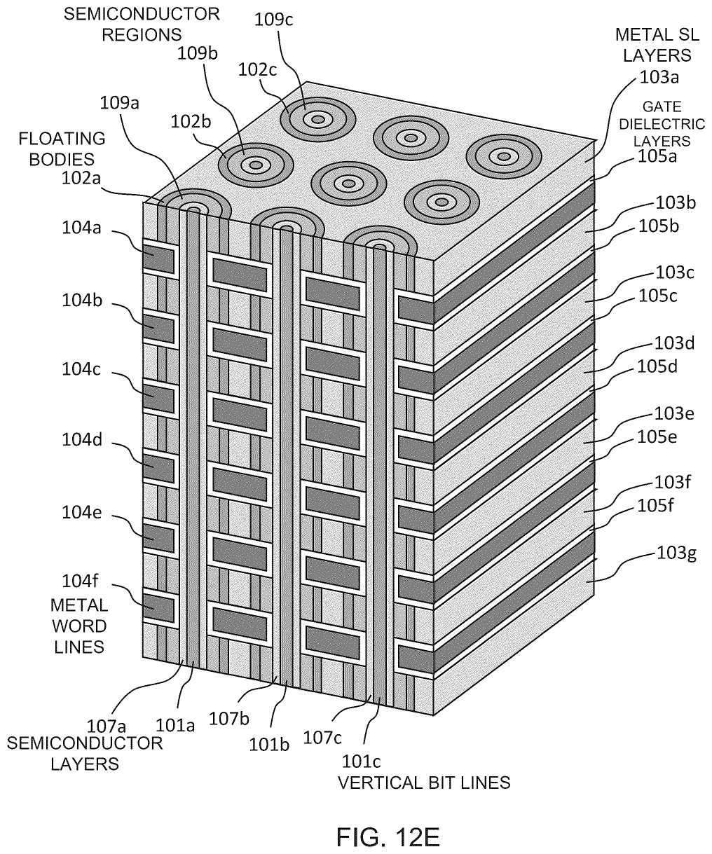

FIGS. 12A-E show another embodiment of brief process steps configured to form an array comprising the cell structure shown in FIG. 1O according to the invention.

FIG. 12A shows an array structure that results after performing the process steps shown in FIGS. 4A-C. The reader is referred to FIGS. 4A-C for a detailed description of the process steps used to form this array structure.

FIG. 12B shows how an isotropic etching process, such as wet etching is performed through the vertical bit line holes, such as bit line holes 111a to 111c to selectively etch the floating bodies, such as floating bodies 102a to 102c to form recesses, such as recesses 114a to 114c. In another embodiment, the floating bodies 102 are formed after the recesses 114 are formed. In this embodiment, after the process steps shown in FIG. 4B are performed, an isotropic etching process, such as wet etching is performed through the vertical bit line holes, such as bit line holes 111a to 111c to selectively etch the semiconductor layers 103a to 103g to form recesses, such as recesses 114a to 114c. Next, an isotropic doping process, such as plasma doping or gas-phase doping is performed to dope the semiconductor layers 103a to 103g with the opposite type of dopants as the semiconductor layers 103a to 103g to form the floating bodies, such as floating bodies 102a to 102c as shown in FIG. 12B.

FIG. 12C shows how a semiconductor material 109, such as semiconductors 109a-c that is different from the material of the floating bodies 102 is deposited by using an appropriate deposition process to fill the vertical bit line holes 111 and the recesses 114. For example, in one embodiment, if the floating bodies 102 are formed of silicon or polysilicon, and the semiconductor material 109 is formed of silicon Germanium (SiGe) or silicon carbide (SiC).

FIG. 12D shows how an anisotropic etching process, such as dry etching is performed using the sacrificial layers 110a to 110f as hard masks to selectively etch the semiconductor material 109 to re-form the vertical bit line holes 111. Because this etching process is self-aligned, it achieves a high process yield. After the vertical bit line holes 111 are re-formed, the residual of the semiconductor material in the recesses becomes the semiconductor regions 109 (e.g., regions 109a to 109c) that form quantum wells to store electric charge, such as by storing holes, as described with reference to FIG. 1O.

FIG. 12E shows an array structure that results after the process steps shown with reference to FIGS. 4E-I are performed. The reader is referred to FIGS. 4E-I for the detailed description of those process steps. For example, the first sacrificial layers 110 are removed, gate dielectric layers 105 are deposited, the metal word lines 104 are formed, the semiconductor layers 107 are deposited and the vertical bit line 101 are formed. As a result, the array shown in FIG. 12E comprising the floating-body cell structure shown in FIG. 1O is formed.

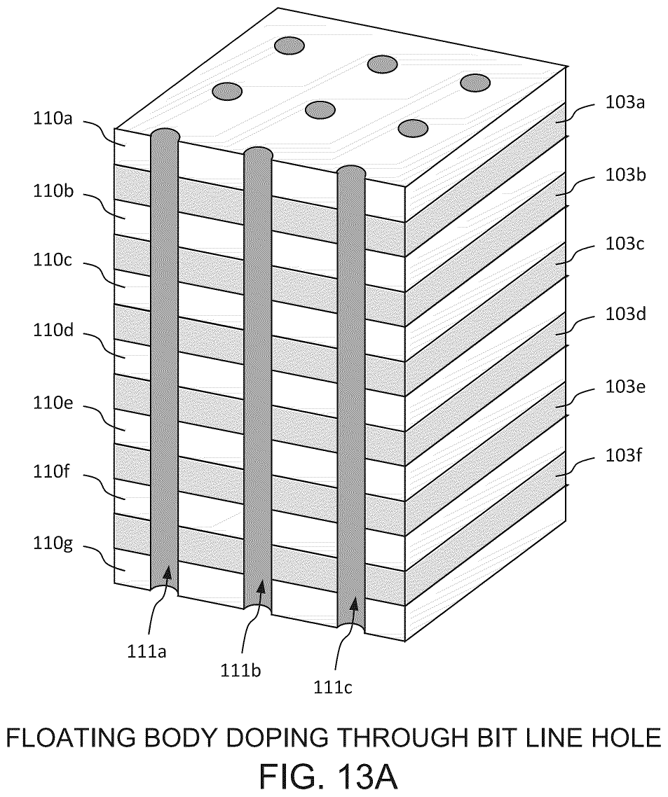

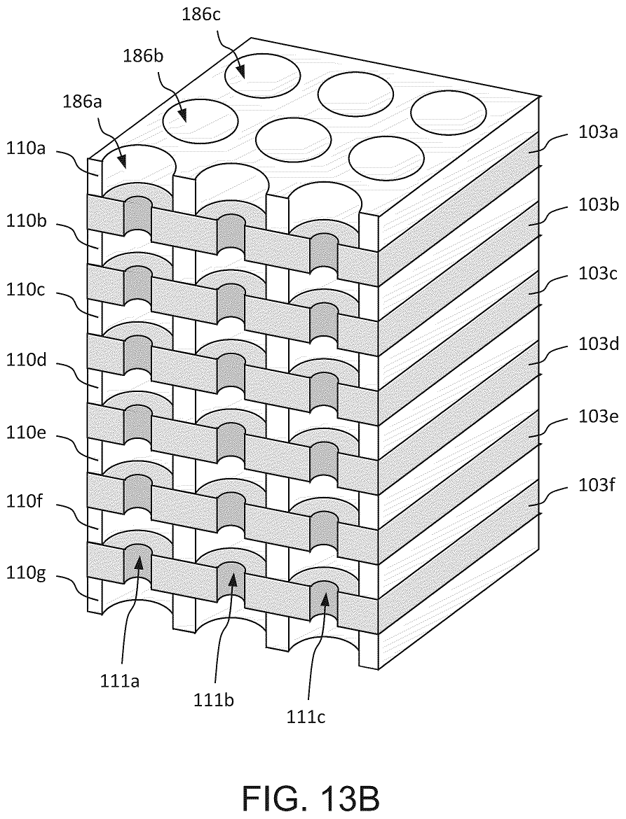

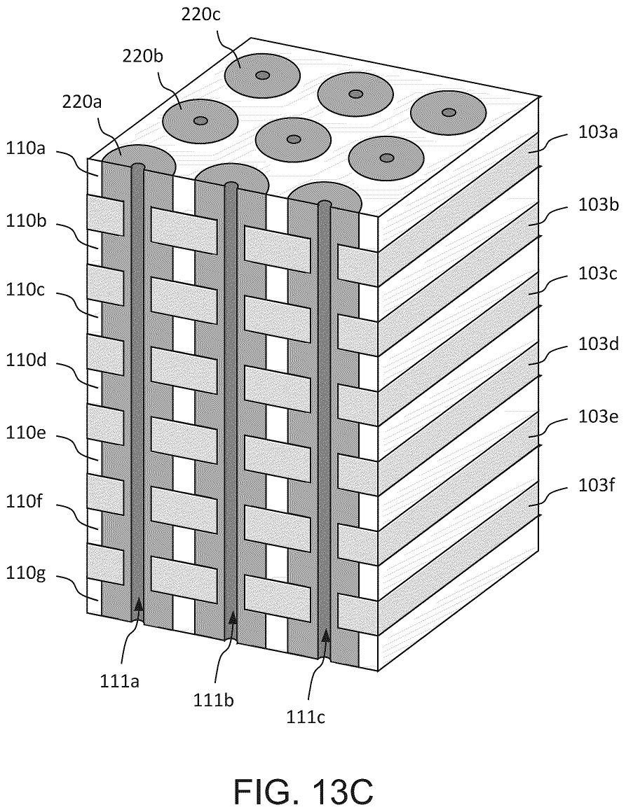

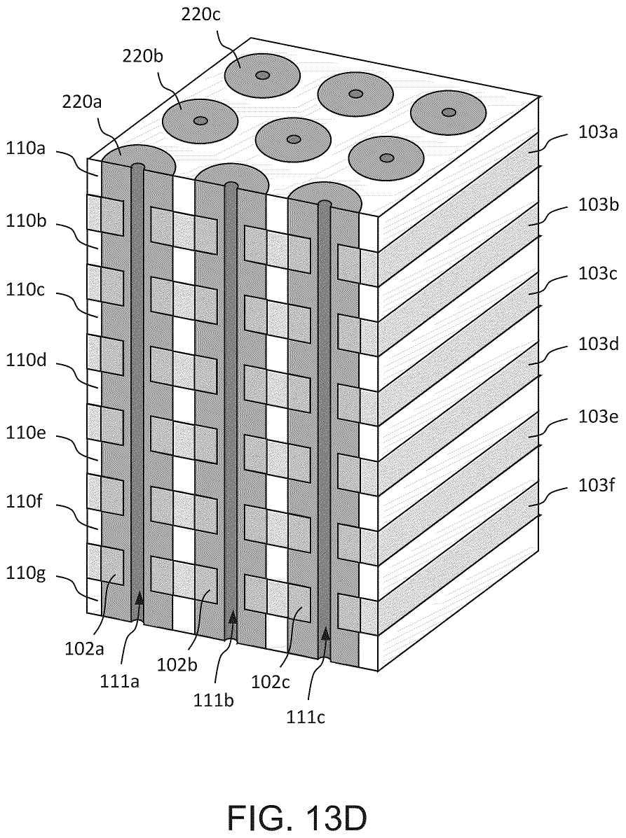

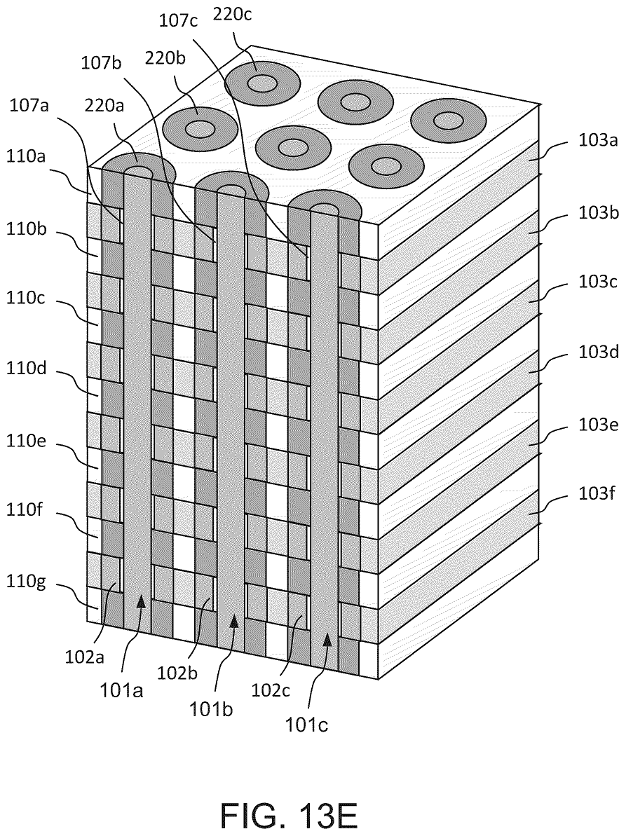

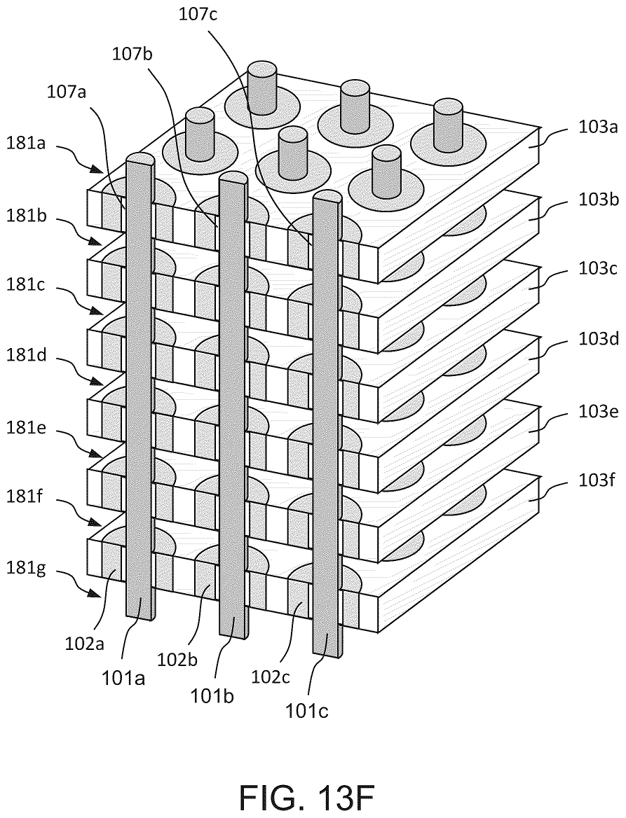

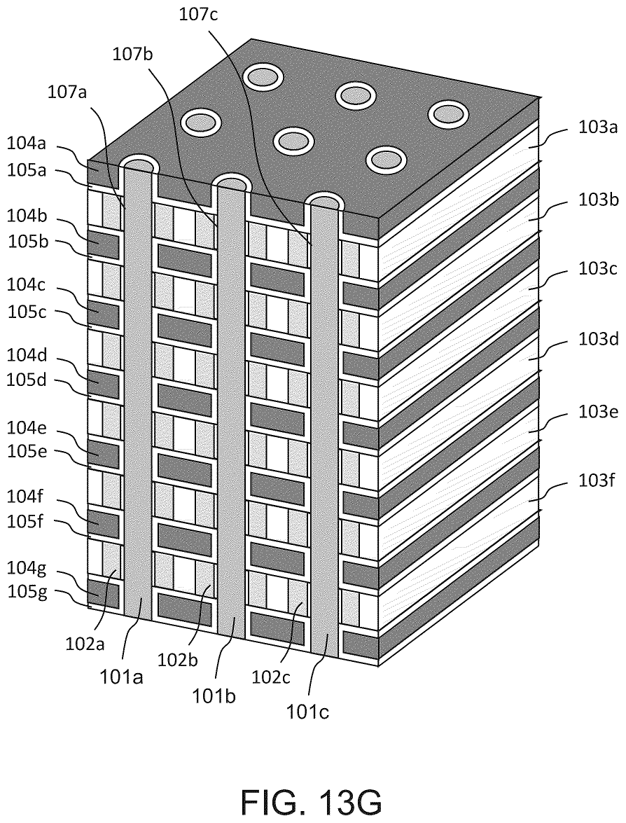

FIGS. 13A-G show embodiments of process steps configured to form an array having the cell structure shown in FIG. 1E according to the invention.

FIG. 13A shows how multiple semiconductor layers 103a to 103f and multiple sacrificial layers 110a to 110g are alternately deposited to form a stack. The semiconductor layers 103a to 103f are formed of any suitable semiconductor material, such as mono-silicon, amorphous silicon, polysilicon, or oxide-based semiconductors, such as indium gallium zinc oxide (IGZO) and many others.

In one embodiment, the semiconductor layers 103a to 103f are lightly doped with P-type of dopants, such as boron or N-type of dopants such phosphorus using in-situ doping processes. In another embodiment, the semiconductor layers 103a to 103f are intrinsic. In one embodiment, the sacrificial layers 110a to 110g are silicon oxide (SiO2) or silicon nitride (Si3N4) layers. The reader is referred to FIG. 4A for a detailed description for forming the semiconductor layers 103a to 103f and the sacrificial layers 110a to 110g.

After deposition of the layers, multiple vertical bit line holes, such as holes 111a to 111c are formed by using photolithography steps to define a pattern, and then using an anisotropic etching process, such as a deep trench process or dry etching process, such as plasma etching or reactive ion etching (RIE) to etch through the multiple semiconductor layers 103a to 103f and the sacrificial layers 110a to 110g.

FIG. 13B shows how an isotropic etching process, such as wet etching, is performed through the vertical bit line holes, such as holes 111a to 111c, to selectively etch the sacrificial layers 110a to 110g to form recesses, such as recesses 186a to 186c. The dimensions of the recesses 186a to 186c are controlled by the etching rate of the etching solution, etching time, and the temperature.

FIG. 13C shows how the recesses, such as recesses 186a to 186c shown in FIG. 13B, are filled with or deposited with thin layer dopant source materials 220a to 220c, such as boron or phosphorus material containing silicon dioxide (SiO2), also called boron silicate glass (BSG) and phosphorus silicate glass (PSG) by using any suitable processes, such as ALD or CVD through the vertical bit line holes 111a to 111c.

FIG. 13D shows how a thermal predeposition and drive-in process is performed to cause dopants to diffuse from the dopant source materials 220a to 220c into the semiconductor layers 103a to 103f to form floating bodies, such as floating bodies 102a to 102c. Compared with the processes shown in FIGS. 4C-D, this approach dopes the semiconductor layers 103a to 103f from three sides (top, bottom, and sideway) instead of from one side only. This process greatly increases the dopant uniformity and achieve a better dopant profile.

FIG. 13E shows how an anisotropic etching process, such as dry etching, is applied to etch the second sacrificial material to re-form the vertical bit line holes, such as vertical bit line holes 111a to 111c. Then, the process steps shown in FIG. 4F or FIG. 5B are performed to form drain regions, such as drain regions 107a to 107c. After that, the vertical bit line holes, such as holes 111a to 111c are filled with conductor material 110a-c, such as any suitable metal material, using an appropriate deposition processes, such as CVD.

FIG. 13F shows how the sacrificial layers 110a to 110g and the dopant source materials such as 220a to 220c are removed by using an isotropic etching process, such as wet etching, to form the spaces 181a to 181g.

FIG. 13G shows how gate dielectric layers 105a to 105g are deposited on the surface of the structure through spaces 181a to 181g using any proper deposition process, such as ALD or CVD. Next, the spaces 181a to 181g are filled with conductor material, such as metal or heavily doped polysilicon by using the proper deposition processes, such as ALD or CVD to form the front gates and back gates 104a to 104g.

Thus, in accordance with the embodiments of the invention described above, a method is provided for forming a cell structure. The method comprises forming a stack comprising alternating layers of a first material and a second material, forming a hole through the alternating layers of the stack, and removing portions of the layers of the second material around the hole to form recesses in the second material around the hole. The method also comprises filling the recesses with a third material and diffusing dopants from the third material into the first material.

Furthermore, in accordance with the embodiments of the invention described above, a cell structure is provided that comprises a stack comprising alternating layers of a first material and a second material, a hole through the alternating layers of the stack, recesses in the second material around the hole, a third material filling the recesses, and dopants diffused from the third material into the first material.

Still further, in accordance with the embodiments of the invention described above, a memory cell structure is provided that is formed by a process of forming a stack comprising alternating layers of a first material and a second material, forming a hole through the alternating layers of the stack, removing portions of the layers of the second material around the hole to form recesses in the second material around the hole, filling the recesses with a third material, and diffusing dopants from the third material into the first material.

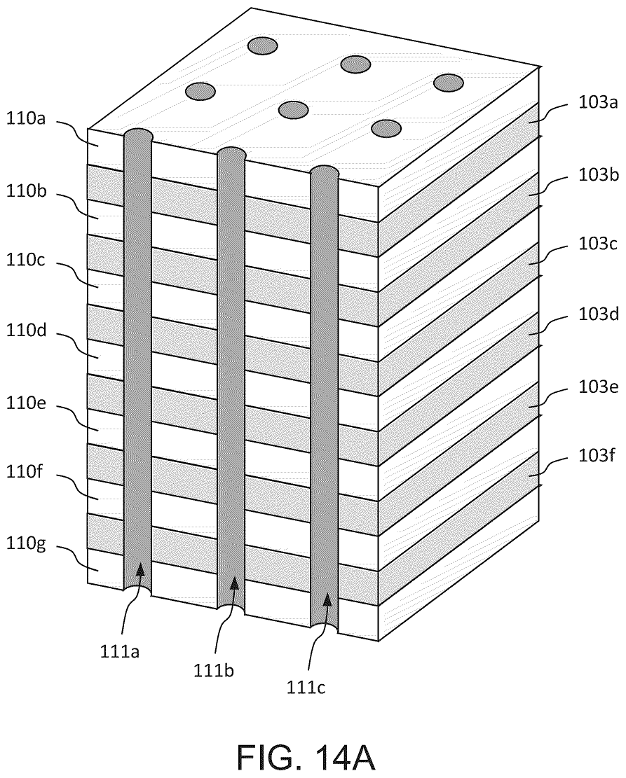

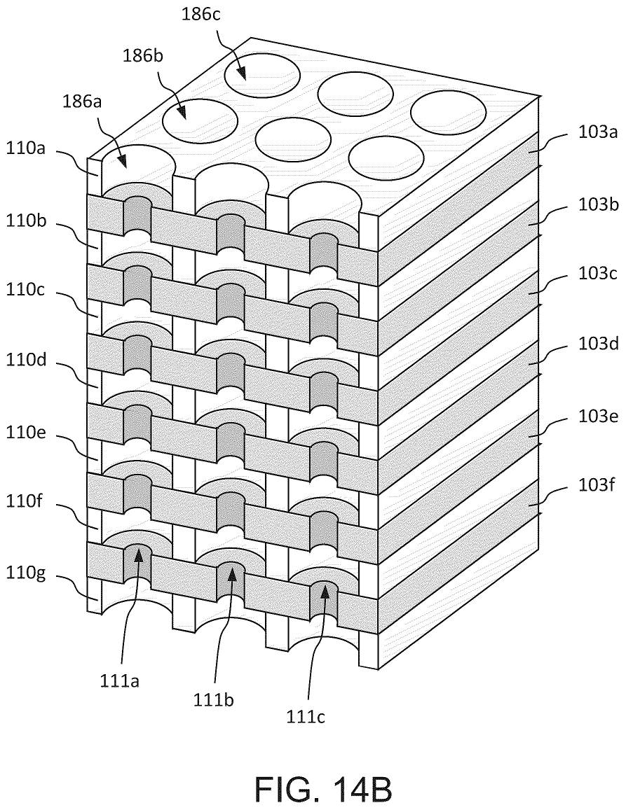

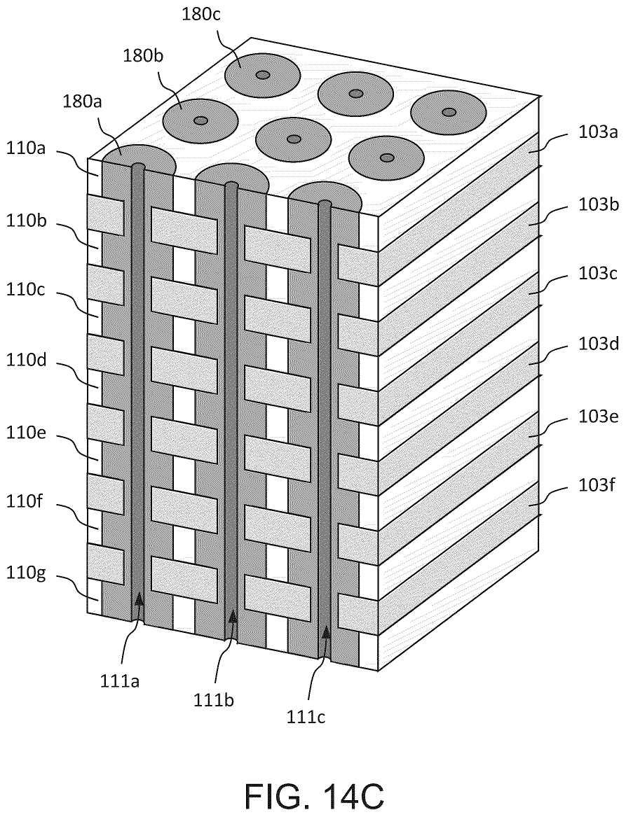

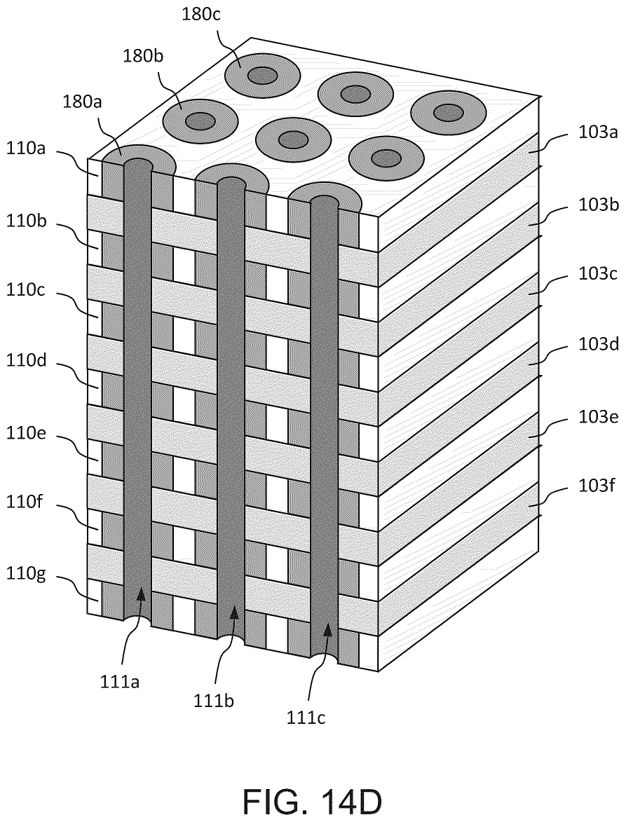

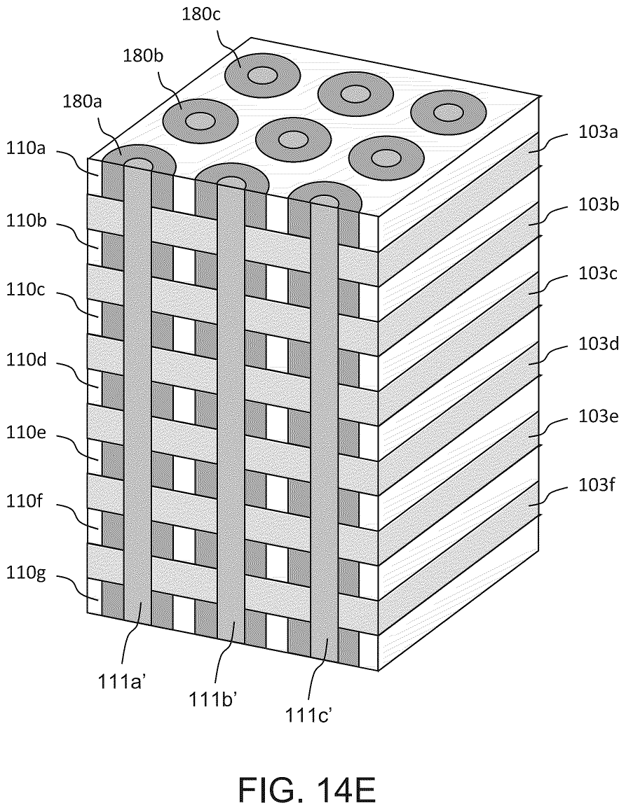

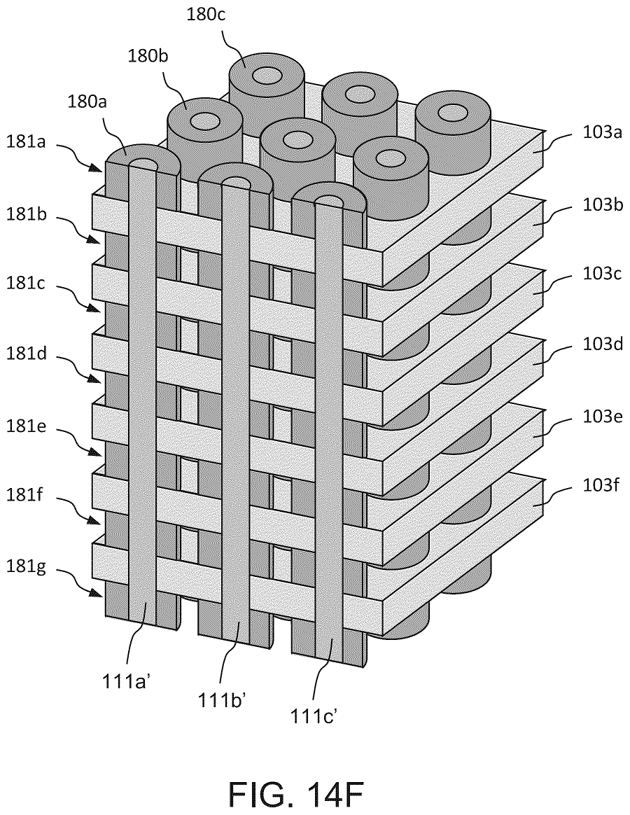

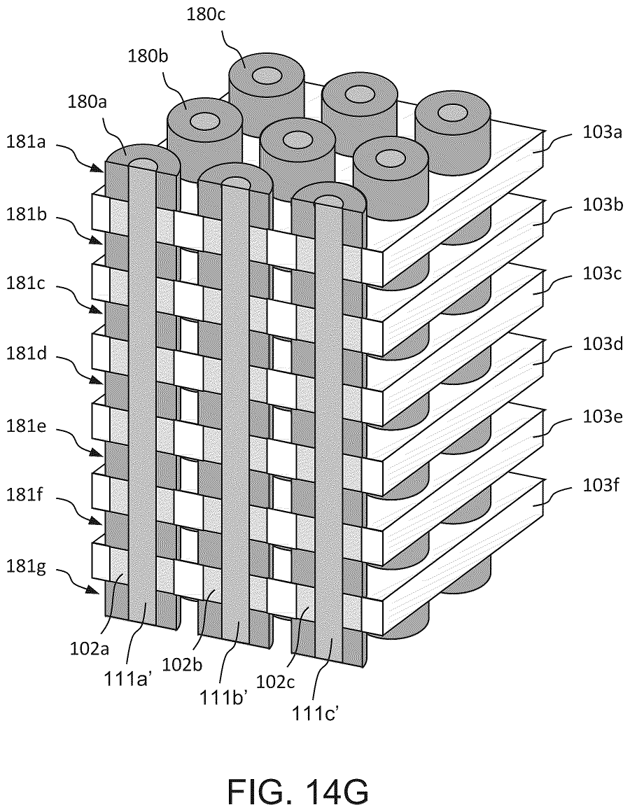

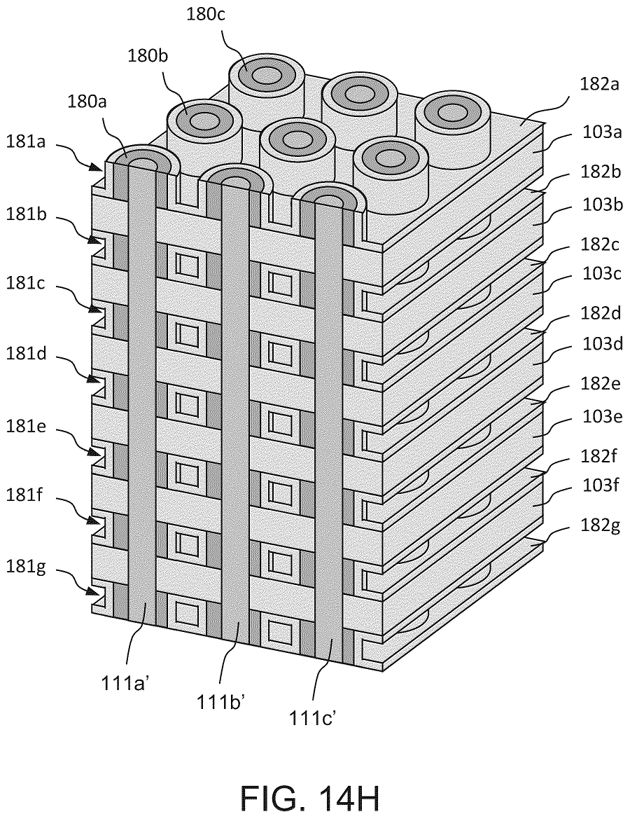

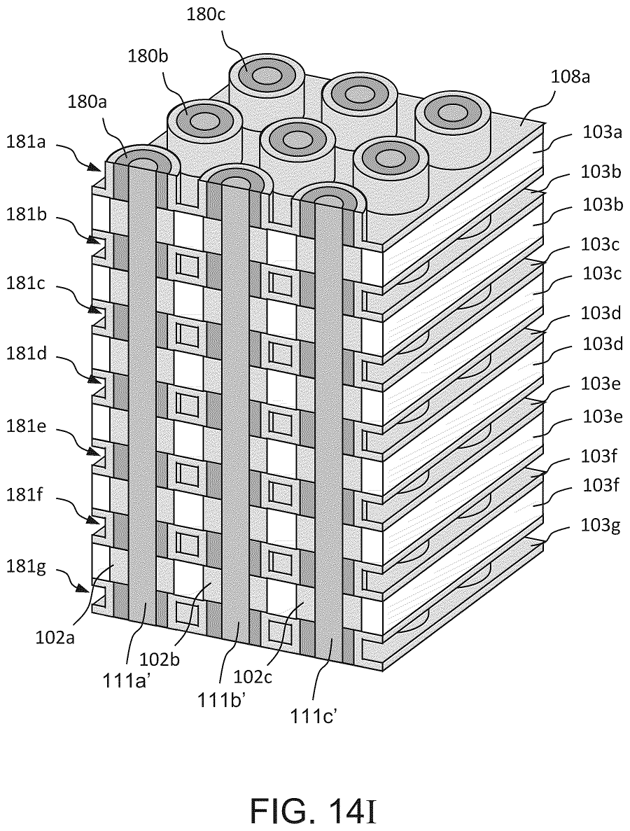

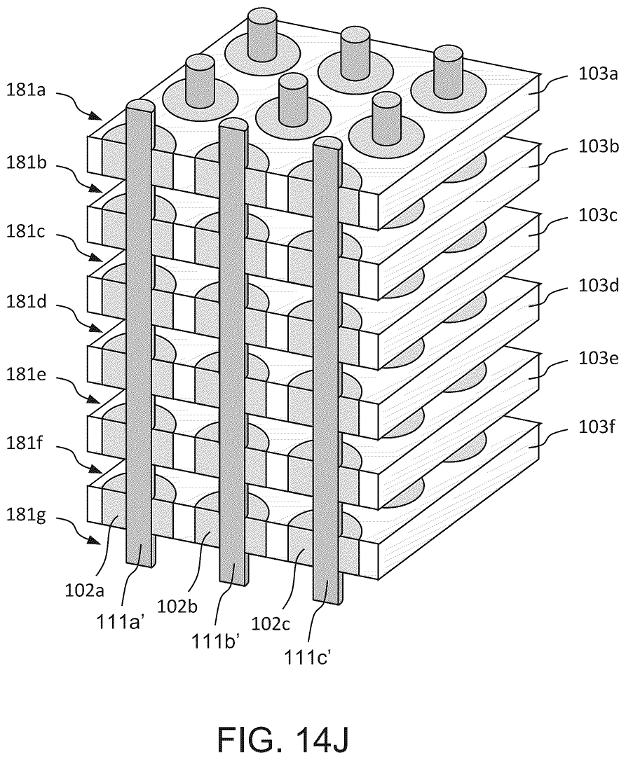

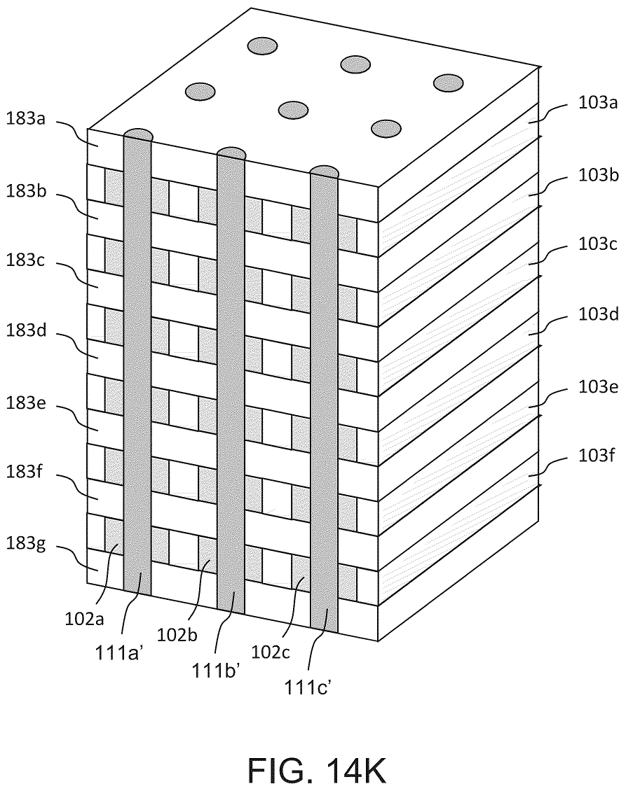

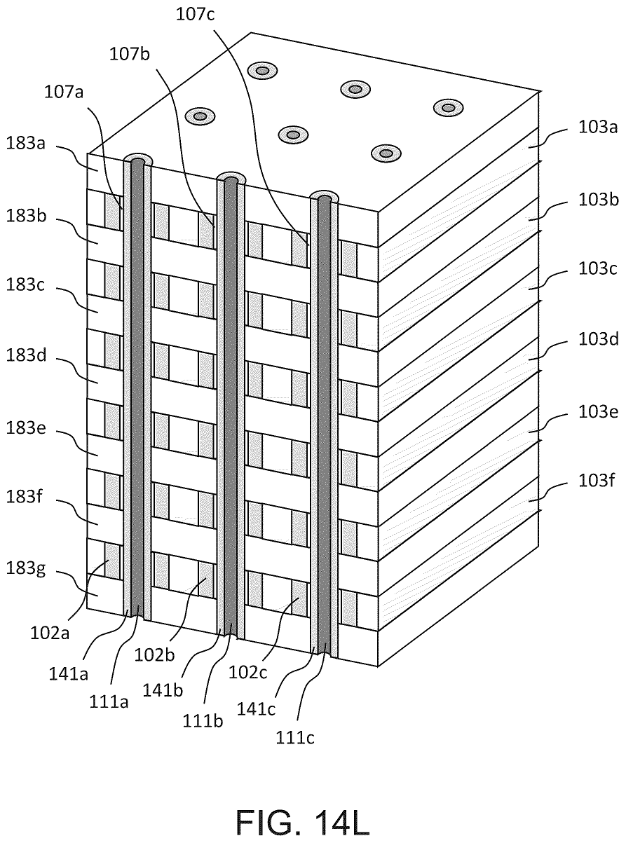

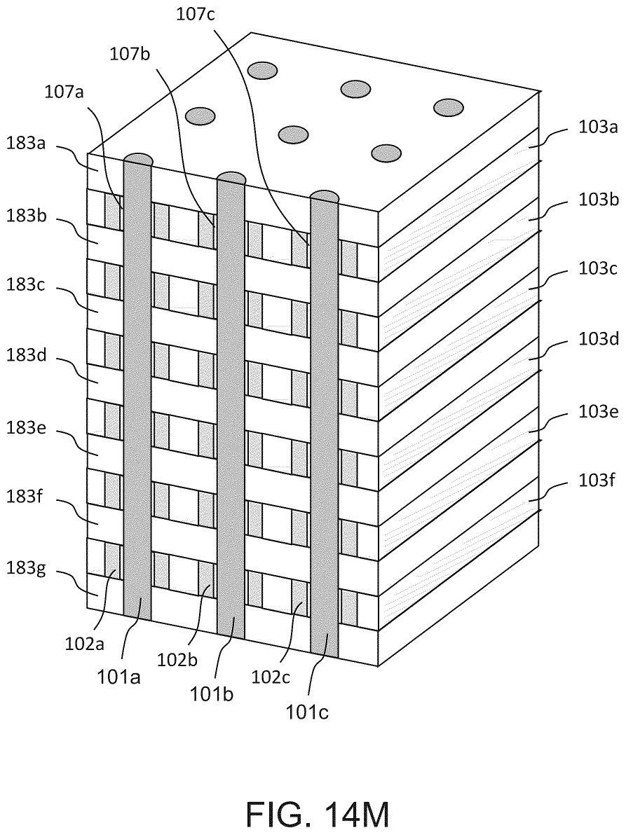

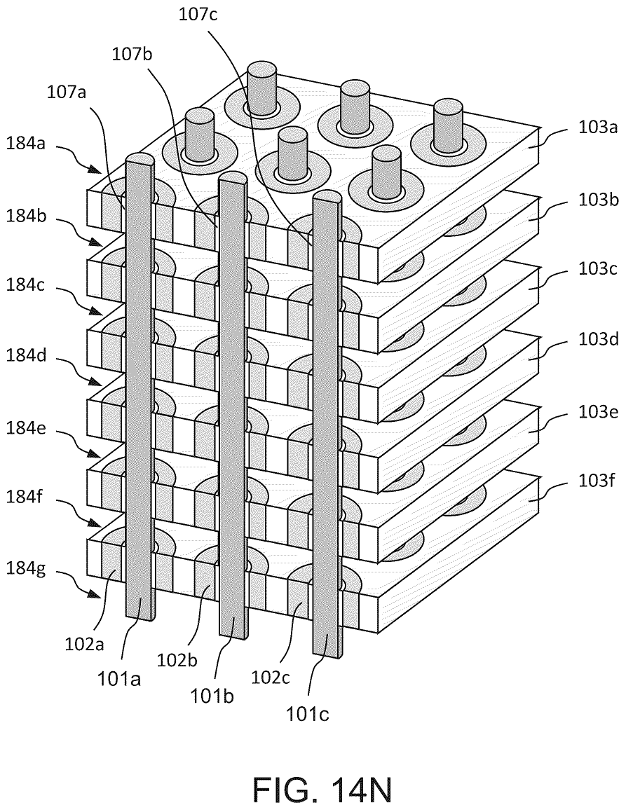

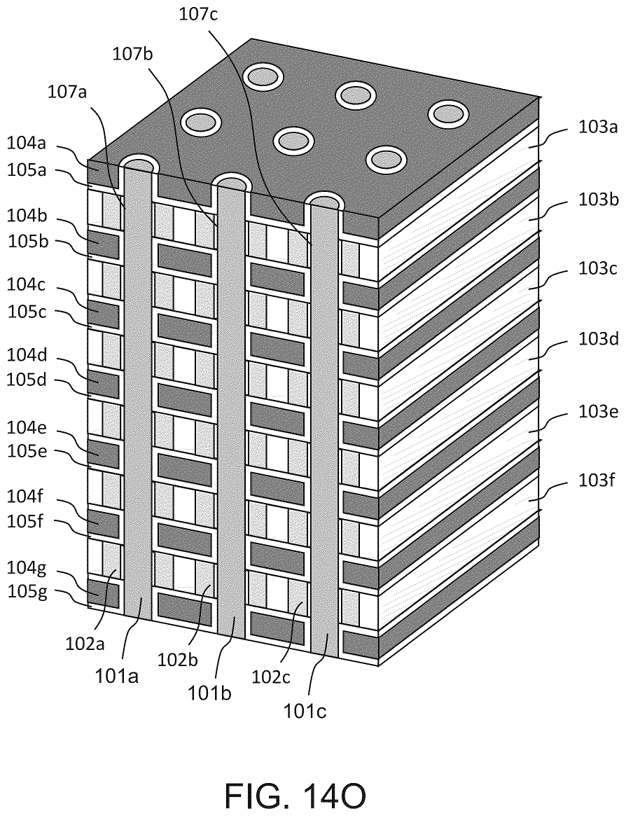

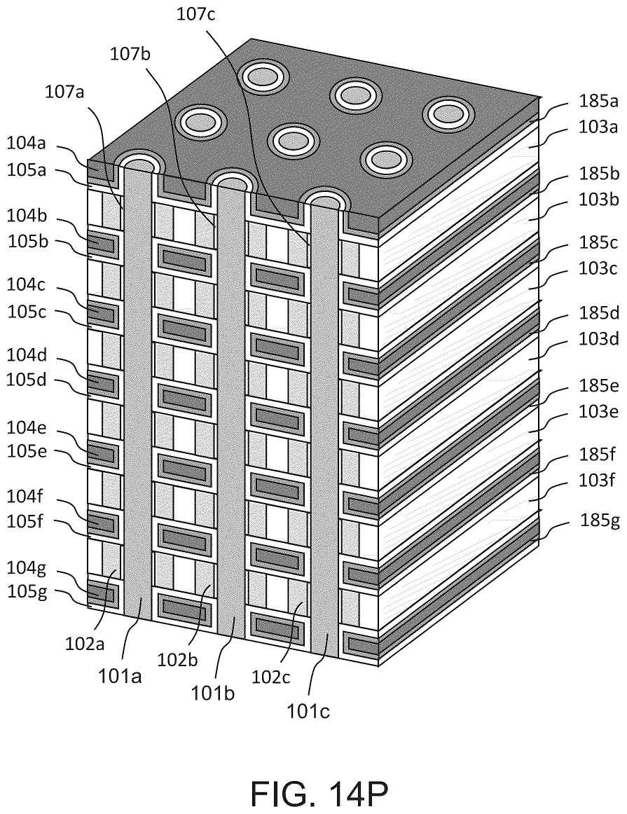

FIGS. 14A-N show embodiments of brief process steps to form an array having the cell structure shown in FIG. 1E according to the invention.

FIG. 14A shows how multiple semiconductor layers 103a to 103f and multiple sacrificial layers 110a to 110g are alternately deposited to form a stack. In one embodiment, the semiconductor layers 103a to 103f are formed of any suitable semiconductor material, such as mono-silicon, amorphous silicon, polysilicon, or oxide-based semiconductors, such as indium gallium zinc oxide (IGZO) and many others.

In one embodiment, the semiconductor layers 103a to 103f are lightly doped with P-type of dopants, such as boron or N-type of dopants such phosphorus using in-situ doping processes. In another embodiment, the semiconductor layers 103a to 103f are intrinsic. In one embodiment, the sacrificial layers 110a to 110g are silicon oxide (SiO2) or silicon nitride (Si3N4) layers. The reader is referred to FIG. 4A for a detailed description for forming the semiconductor layers 103a to 103f and the sacrificial layers 110a to 110g.

After the deposition, multiple vertical bit line holes, such as holes 111a to 111c are formed by using photolithography steps to define a pattern, and then using an anisotropic etching process, such as deep trench process or a dry etching process, such as plasma etching or reactive ion etching (RIE) to etch through the multiple semiconductor layers 103a to 103f and the sacrificial layers 110a to 110g to form the holes 111a to 111c.

FIG. 14B shows how an isotropic etching process such as wet etching is performed through the vertical bit line holes, such as 111a to 111c, to selectively etch the sacrificial layers 110a to 110g to form recesses such as 186a to 186c. The dimension of the recesses 186a to 186c are controlled by the etching rate of the etching solution, etching time, and the temperature.

FIG. 14C shows how the recesses, such as recesses 186a to 186c, are filled with a second sacrificial material, such as sacrificial material 180a top 180c through the vertical bit line holes 111a to 111c. The second sacrificial material is deposited by using chemical vapor deposition (CVD), atomic layer deposition (ALD), low pressure chemical vapor deposition (LPCVD), or any other suitable deposition processes.

FIG. 14D shows how an anisotropic etching process, such as dry etching is applied to etch the second sacrificial material to re-form the vertical bit line holes, such as bit line holes 111a to 111c.

FIG. 14E shows how the vertical bit line holes, such as bit line holes 111a to 111c, are filled with a third sacrificial material 111a‘-c’ by using a suitable deposition process, such as CVD.

FIG. 14F shows how the sacrificial layers 110a to 110g are selectively etched by using an isotropic etching process, such as wet etching. After the etching, spaces 181a to 181g are formed between the semiconductor layers 103a to 103f.

FIG. 14G shows embodiments of process steps for doping source line regions. In one or more embodiments, a suitable doping process, such as a diffusion process, is applied through the spaces 181a to 181g to dope the semiconductor layers 103a-f to form the source line 103 shown in FIG. 1E. The sacrificial materials, such as materials 180a-c are used as hard masks to define the floating bodies 102 for the doping process. The regions of the semiconductor layers 103a-f that are not covered by the sacrificial materials 180a-c will be doped to form the source lines 103. The regions of the semiconductor layers 103a-f covered by the sacrificial materials, such as regions 180a-c will not be doped and will become the floating bodies 102.

In one embodiment, the dopants provide the opposite type of doping from the semiconductor layers 103a to 103f. For example, if the semiconductor layers 103a to 103f have P− or N− type of light doping, the doping through the spaces 181a to 181g use N+ type of dopants such as phosphorus or P+ type of dopants such as boron, respectively.

In another embodiment, the dopants provide the same type of doping as the semiconductor layers 103a to 103f. This configuration forms a junction-less device. For example, if the semiconductor layers 103a to 103f have P− or N− type of light doping, the doping through the spaces 181a to 181g use P+ type of dopants such as boron or N+ type of dopants such as phosphorus, respectively.

The doping process uses gas-phase diffusion, such as plasma doping or dopant containing gas doping, or liquid-phase diffusion, such as using spin-on coating with organic or inorganic dopants that contains phosphorus or boron, or solid-phase diffusion, such as using CVD or ALD to deposit phosphorus or boron containing silicon dioxide (SiO2) materials. These doping processes have been described in FIG. 4C. The reader is referred to FIG. 4C for detailed descriptions.

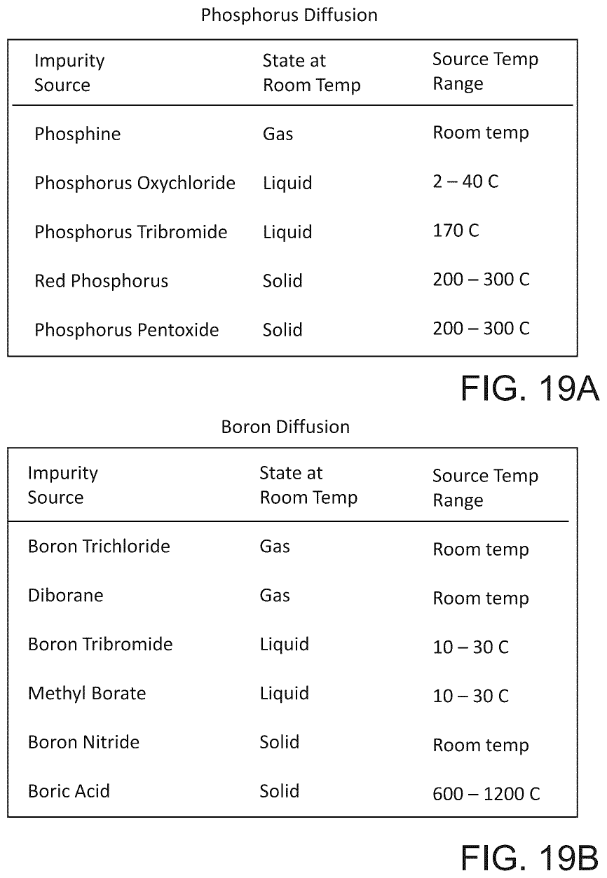

As an example, FIGS. 19A-B show examples of the processes of phosphorus diffusion and boron diffusion, respectively. The reader is referred to FIGS. 19A-B for the details. It should also be noted that the processes shown in FIGS. 19A-B are examples only and using any other doping processes shall remain in the scope of the invention.

FIG. 14G shows the results after a gas-phase or liquid-phase type of doping. The regions in the semiconductor layers 103a to 103f that are not covered by the second sacrificial materials 180a to 180c will be heavily doped. These regions become source lines. The regions in the semiconductor layers 103a to 103f that are covered by the second sacrificial materials 180a to 180c will remain lightly doped. These regions become floating bodies, such as floating bodies 102a to 102c.

FIG. 14H shows embodiments of process steps for solid-phase diffusion. After the processes shown in FIG. 14F are completed, a thin layer of dopant source materials 182a to 182g, such as boron or phosphorus containing silicon dioxide (SiO2) also called boron silicate glass (BSG) and phosphorus silicate glass (PSG) is deposited on the surface of the semiconductor layers 103a to 103f through the spaces 181a to 181g by ALD or CVD processes. Then, a thermal predeposition and drive-in process is performed to cause the dopants to diffuse from the dopant source materials 182a to 182g into the semiconductor layers 103a to 103f.

FIG. 14I shows exemplary results after liquid-phase or solid-phase type of doping. The regions in the semiconductor layers 103a to 103f that are not covered by the second sacrificial materials 180a to 180c will be heavily doped. These regions become source lines. The regions in the semiconductor layers 103a to 103f that are covered by the second sacrificial materials 180a to 180c will remain lightly doped. These regions become floating bodies such as 102a to 102c.

FIG. 14J illustrates how after the doping process, the dopant source materials 182a to 182g are removed by using isotropic etching processes, such as wet etching, to re-form the spaces 181a to 181g. Next, the second sacrificial material, such as materials 180a to 180c are selectively etched by using an isotropic etching process, such as wet etching, through the spaces 181a to 181g.

FIG. 14K shows how the spaces 181a to 181g are filled with sacrificial materials, such as oxide or nitride, by using a suitable deposition process, such as CVD to form sacrificial layers 183a to 183g.

FIGS. 14L-P show embodiments of process steps to form the drain regions of the cells.

FIG. 14L shows how an anisotropic etching process, such as dry etching, is applied to selectively etch the sacrificial material (111a‘-c’) in the vertical bit line holes, to reform the bit line holes 111a to 111c. Next, a doping process is applied through the vertical bit line holes 111a to 111c to form the drain regions, such as regions 107a to 107c.

In one embodiment, the doping process uses gas-phase doping, such as plasma doping, or liquid-phase doping, such as using a spin-on coating with organic or inorganic dopants that contain phosphorus or boron, or solid-phase doping such as using CVD or ALD to deposit phosphorus or boron containing silicon dioxide (SiO2) materials. These doping processes have been described herein with reference to FIG. 4C and the reader is referred to FIG. 4C for detailed descriptions.

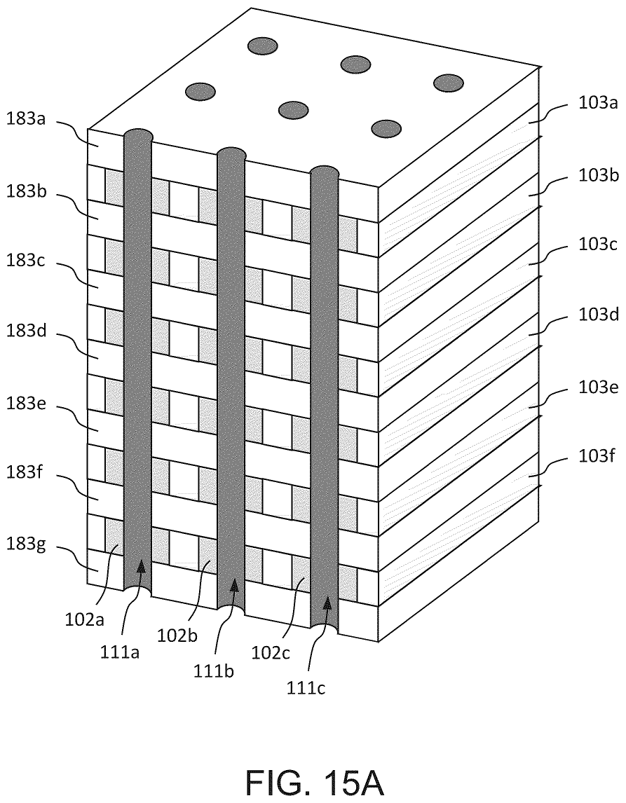

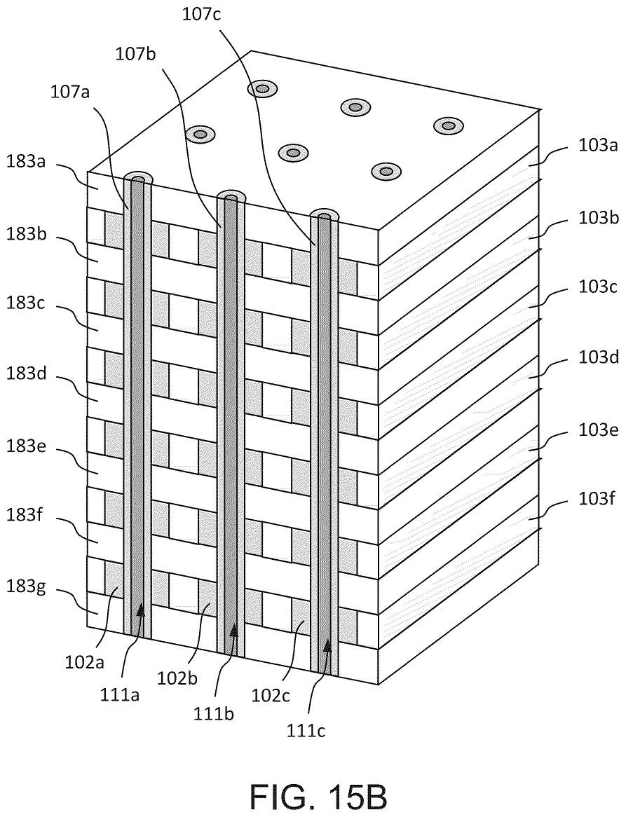

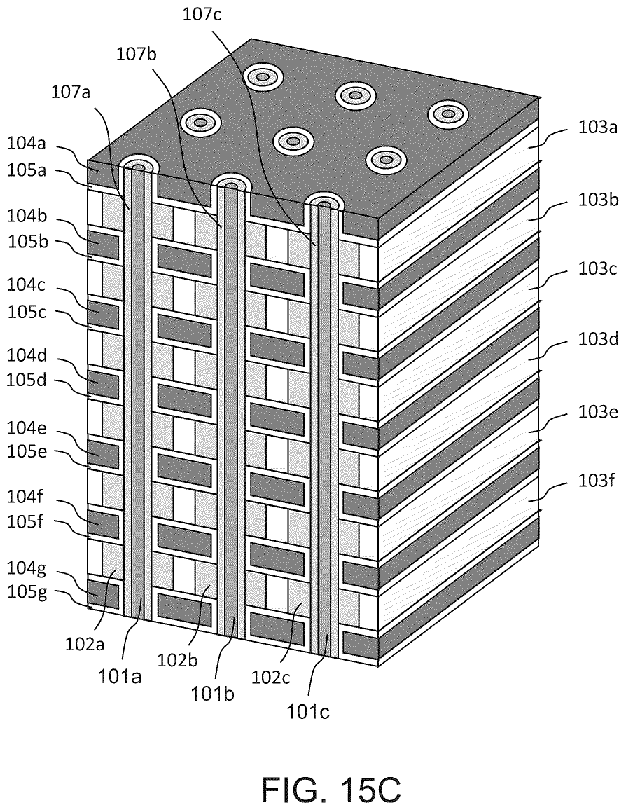

FIG. 14L shows an embodiment using solid-phase doping. In this embodiment, boron containing SiO2 material 141a to 141c are deposited by using CVD or ALD processes. In another embodiment, the drain region is formed by using polysilicon deposition processes shown in FIGS. 15A-C.

In one embodiment, the doping process uses the opposite type of doping from the floating bodies, such as the floating bodies 102a to 102c. For example, if the floating bodies 102a to 102c have P− or N− type of light doping, the doping process uses N+ type of dopants such as phosphorus or P+ type of dopants such as boron, respectively. In another embodiment, the doping process uses the same type of doping as the floating bodies 102a to 102c. This configuration forms a junction-less device. For example, if the floating bodies 102a to 102c have P− or N− type of light doping, the doping process uses P+ type of dopants such as boron or N+ type of dopants such as phosphorus, respectively.

FIG. 14M shows how boron containing SiO2 material 141a to 141c are removed from the structure. Next, the vertical bit line holes are filled with conductor material, such as metals or heavily doped polysilicon by using a deposition process, such as CVD to form vertical bit lines 101a to 101c.

FIG. 14N shows how the sacrificial layers 183a to 183g are selectively etched by using an isotropic etching process such as wet etching. This process forms spaces 184a to 184g between the semiconductor layers 103a to 103f.

FIG. 14O shows how gate dielectric layers 105a to 105g are deposited on the surface of the structure through the spaces 184a to 184g using suitable deposition processes, such as CVD, PECVD, or ALD. Next, the spaces 184a to 184g are filled with conductor material, such as metals or heavily doped polysilicon using suitable deposition processes, such as CVD, PECVD, or ALD to form the front gates and back gates 104a to 104g.

FIG. 14P shows one embodiment in which the gates 104a to 104g are formed of tungsten (W) and titanium nitride (TiN) material. In this embodiment, after the gate dielectric layers 105a to 105g are deposited by using ALD or CVD, gluing layers 185a to 185g, comprising material such as titanium nitride TiN are deposited on the surface of the gate dielectric layers 105a to 105g by using ALD or CVD. Next, tungsten is deposited using ALD or CVD to fill the spaces between the gluing layers 185a to 185g to form the gates 104a to 104g.

FIGS. 15A-C shows embodiments of brief process steps configured to form an array using the cell structure shown in FIG. 1C according to the invention.

FIG. 15A shows a process step performed after the process steps used to form the structure shown in FIG. 14K. The sacrificial materials in the vertical bit line holes, such as holes 111a to 111c are etched by using anisotropic etching processes, such as dry etching.

FIG. 15B shows how a semiconductor layer is formed on the sidewalls of the vertical bit line holes 111a to 111c to form the drain regions 107a to 107c. The semiconductor layer is formed by using an epitaxial growth process to form a mono-silicon layer or by using deposition processes, such as CVD, PECVD, or ALD, to form a polysilicon layer. Next, the process steps shown in FIGS. 14N-P are applied to form the 3D array structure shown in FIG. 15C.

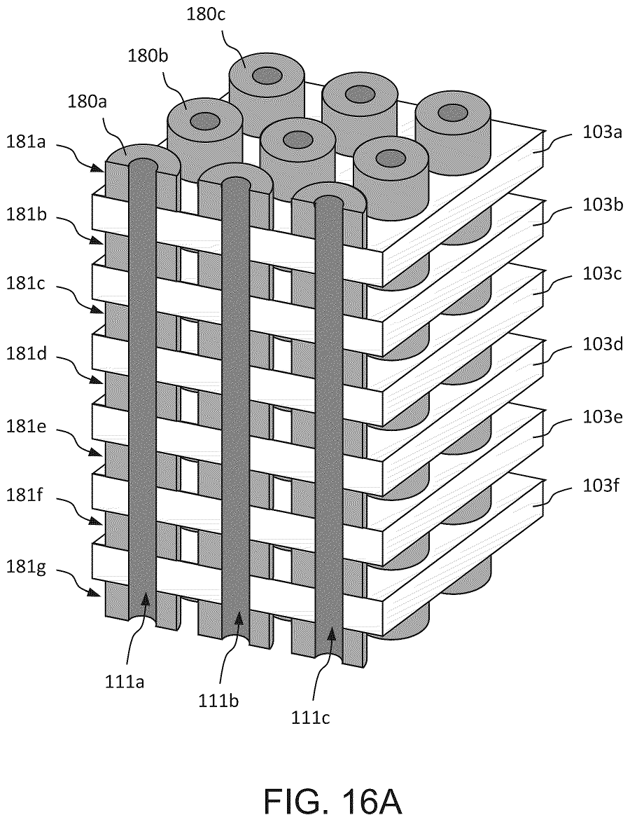

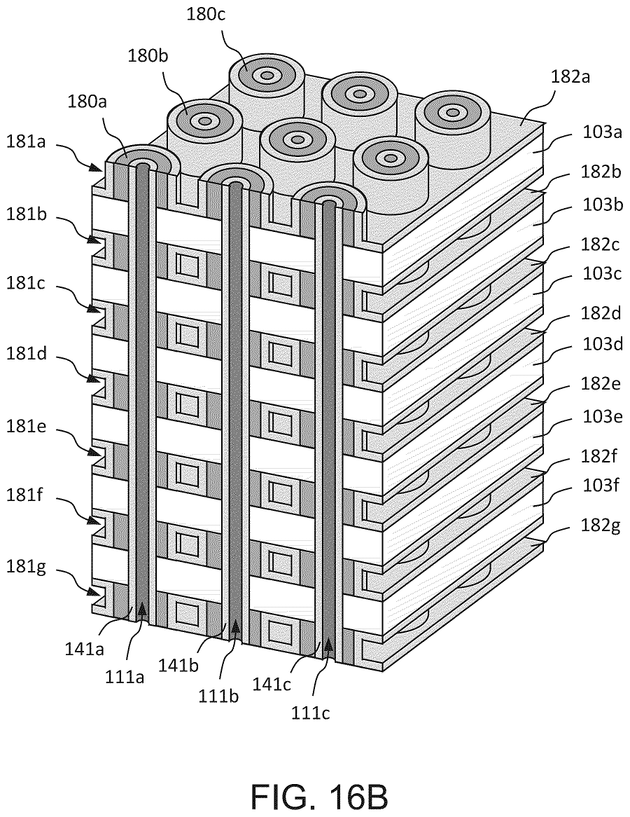

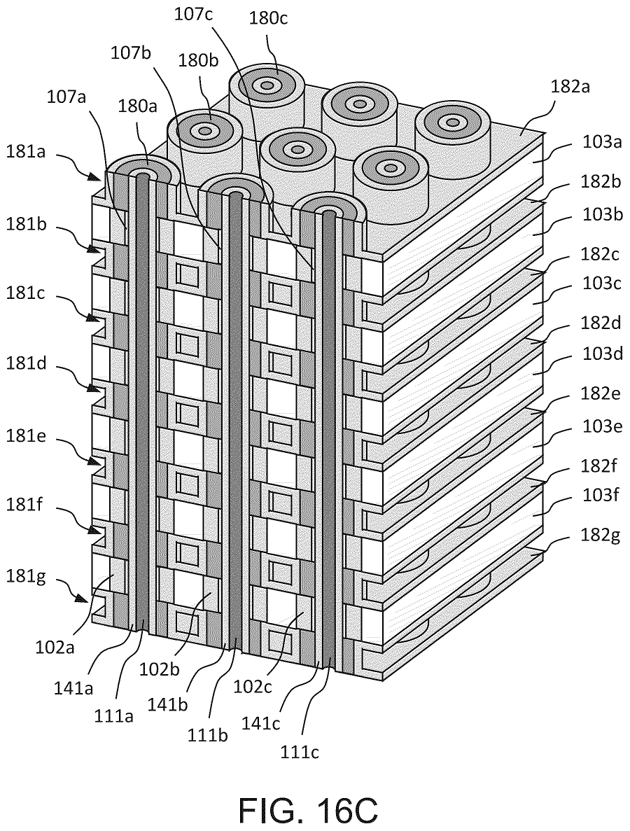

FIGS. 16A-C show embodiments of process steps configured to dope source lines and drain regions together.

FIG. 16A shows a process step that is performed after the process step shown in FIG. 14F. The sacrificial material in the vertical bit line holes 111a to 111c is removed by using an anisotropic etching process, such as dry etching, to re-form the vertical bit line holes 111a to 111c.

FIG. 16B shows an embodiment in which a doping process, such as the solid-phase diffusion process described with reference to FIG. 4C is used. A layer of boron or phosphorus containing SiO2 material 182a to 182g and 141a to 141c is formed on the surface of the semiconductor layers 103a to 103f and the sidewalls of the vertical bit line holes 111a to 111c, respectively.

FIG. 16C shows an embodiment of a thermal predeposition and drive-in process applied to cause atoms of the dopants to diffuse into the exposed region of the semiconductor layers 103a to 103f to form the source lines 103a to 103f, the drain regions 107a to 103c, and the floating bodies 102a to 102c.

After that, the boron or phosphorus containing SiO2 material 182a to 182g and 141a to 141c are removed using a wet etching process to form the array structure shown in FIG. 14N, and then the process steps shown in FIGS. 14O-P are performed to form the 3D array.

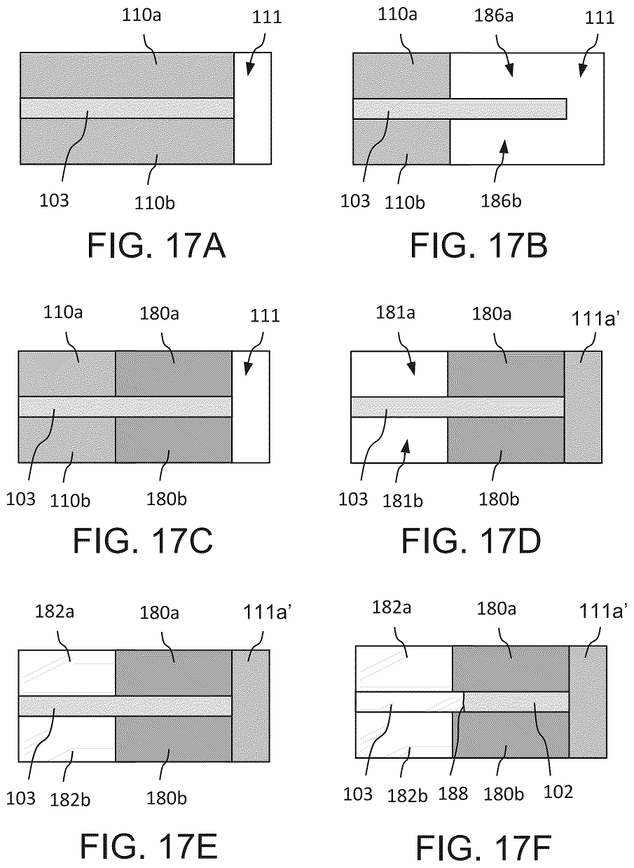

FIGS. 17A-F shows embodiments of complete process steps for the source line diffusion process shown in FIGS. 14F-I.

FIG. 17A shows how multiple sacrificial layers 110a and 110b and multiple semiconductor layers such as 103 are alternately deposited to form a stack. Next, vertical bit line holes, such as hole 111, are formed by using an anisotropic etching process, such as deep trench or dry etching.

FIG. 17B shows how an isotropic etching process, such as wet etching, is performed through the vertical bit line hole 111 to selectively etch the sacrificial layers 110a and 110b to form recesses 186a and 186b.

FIG. 17C shows how the recesses 186a and 186b are filled with the second sacrificial material 180a-b, respectively, by using a suitable deposition process, such as CVD. Next, an anisotropic etching process, such as dry etching, is performed to re-form the vertical bit line hole 111.

FIG. 17D shows how the vertical bit line hole 111 is filled with sacrificial material 111a′ by using deposition processes, such as CVD. Next, an isotropic etching process, such wet etching is performed to selectively etch the sacrificial layers 110a and 110b to form recesses 181a and 181b.

Next, a suitable doping process, such as a diffusion process is performed to dope the semiconductor layer 103 to form the source region. The diffusion process comprises a gas-phase, liquid-phase, or solid-phase process. If gas-phase is used, dopant containing gas or plasma is applied to the recesses 181a and 181b to cause the atoms of the dopants to diffuse into the exposed region of the semiconductor layer 103. If liquid-phase is used, dopants containing liquid are applied to the recesses 181a and 181b by using spin-on coating to cause the atoms of the dopants to diffuse into the exposed region of the semiconductor layer 103. If solid-phase is used, dopants containing materials are formed in the recesses 181a and 181b by using a suitable deposition process, such as CVD, to form dopant source material 182a and 182b as shown in FIG. 17E.

FIG. 17F shows how a thermal predeposition and drive-in process is performed to cause the atoms of the dopants to diffuse into the exposed region of the semiconductor layer 103. The region of the semiconductor layer 103 covered by the sacrificial materials 180a and 180b will not be doped, thus it becomes a floating body 102. Also shown is a junction 188 between the floating body 102 and the source line 103.

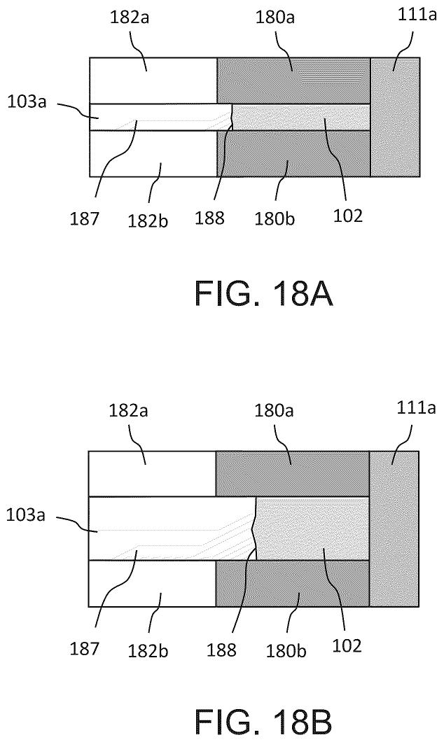

FIGS. 18A-B shows embodiments of cell structures after the diffusion processes shown in FIGS. 14F-I and FIGS. 17A-F. It should be noted that due to lateral diffusion, the channel length of the floating body 102 will be shorter than the dimension of the sacrificial materials 180a and 180b.

FIGS. 18A-B shows examples of cells having thinner and thicker semiconductor layers 103a for comparison. Also shown is junction 188 between the floating body 102 and the source line 103.

FIG. 18B shows how diffusing dopants into the thicker semiconductor layer results in larger lateral diffusion, as shown by junction 188. Therefore, the channel length of the floating body 102 in FIG. 18B is shorter than that in FIG. 18A. This variable can be taken into consideration during the process design.

In the previously described doping process for the semiconductor layer, the doping process uses gas-phase diffusion, such as plasma doping or dopant containing gas doping, or liquid-phase diffusion, such as using spin-on coating with organic or inorganic dopants that contain phosphorus or boron, or solid-phase diffusion, such as using CVD or ALD to deposit phosphorus or boron containing silicon dioxide (SiO2) materials. These doping processes have been described with reference to FIG. 4C. The reader is referred to FIG. 4C for the detailed descriptions.

FIGS. 19A-B shows tables providing some examples of the processes of phosphorus diffusion and boron diffusion, respectively. It should be noted that the processes shown in FIGS. 19A-B are exemplary and do not limit the types of processes that can be used. Using any other doping processes in the process steps shown in FIG. 14F is within the scope of the invention.

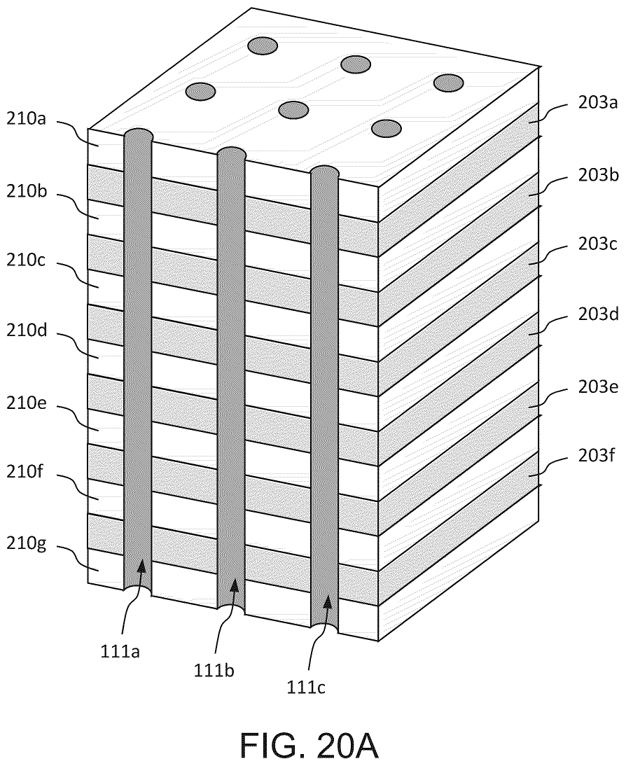

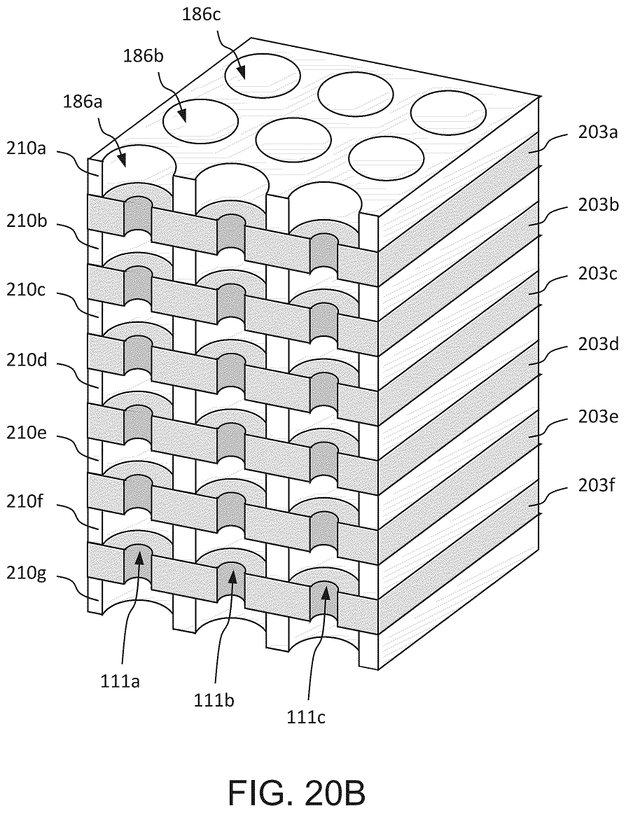

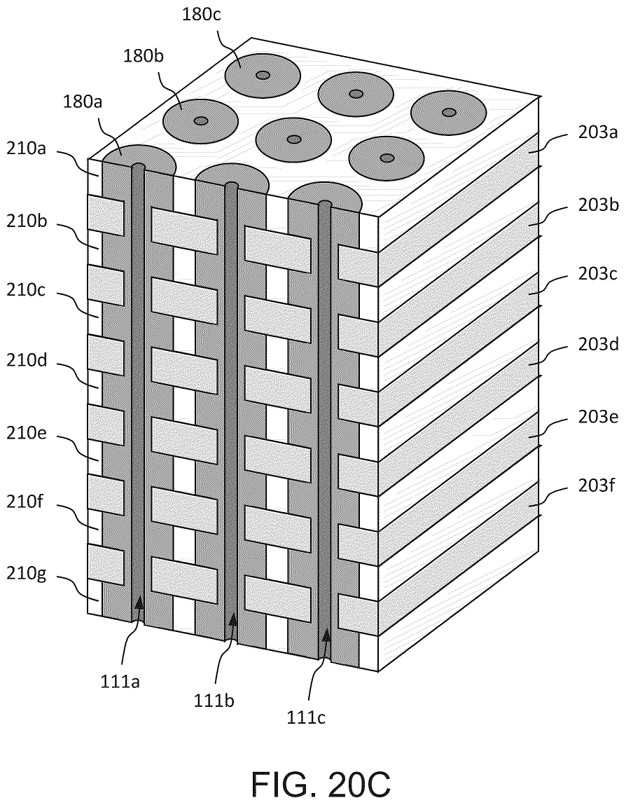

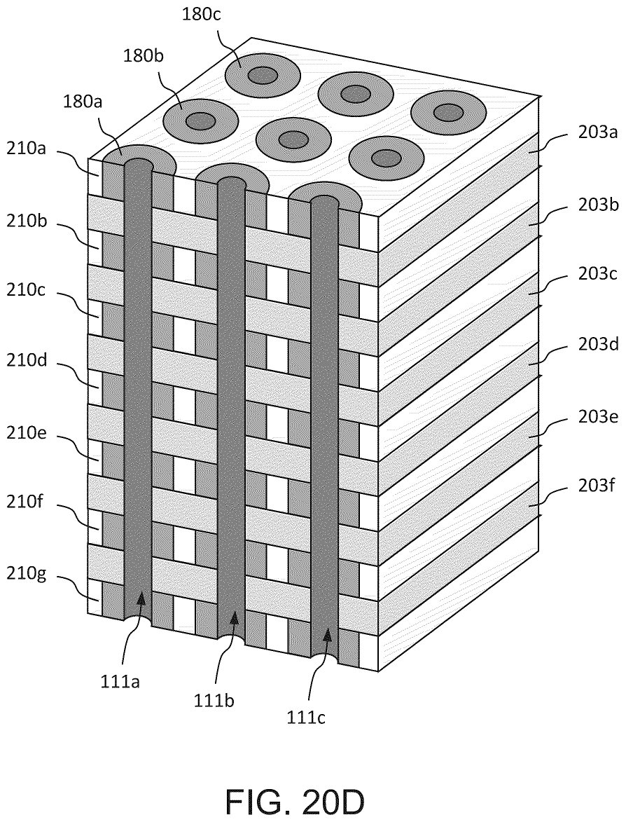

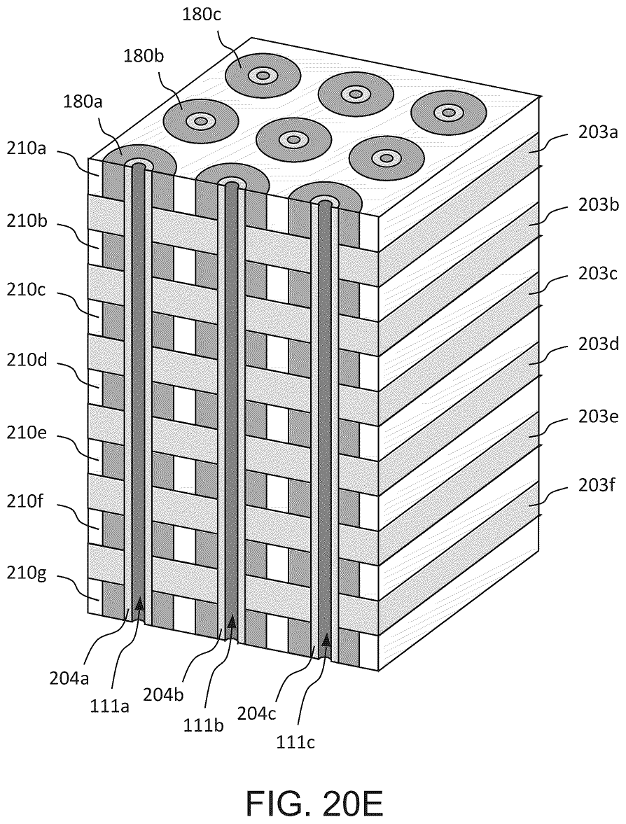

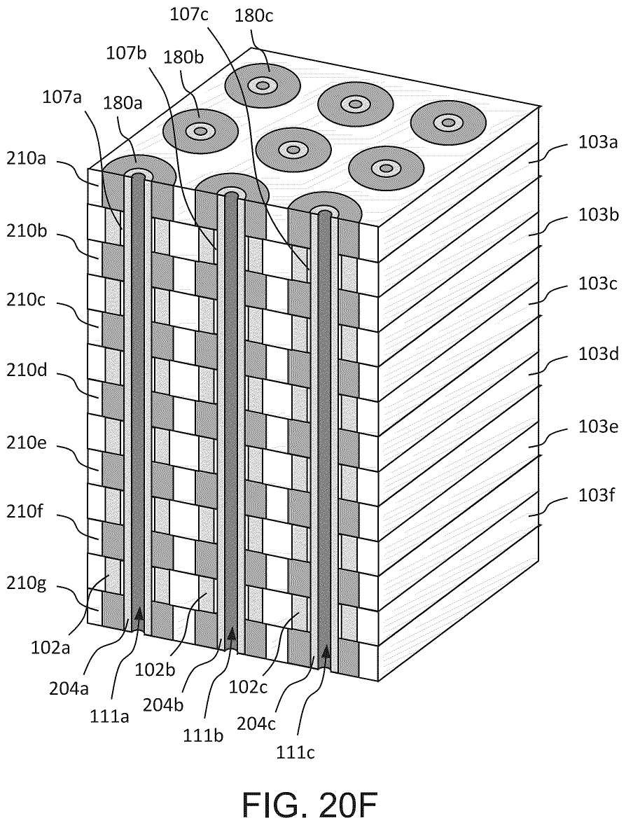

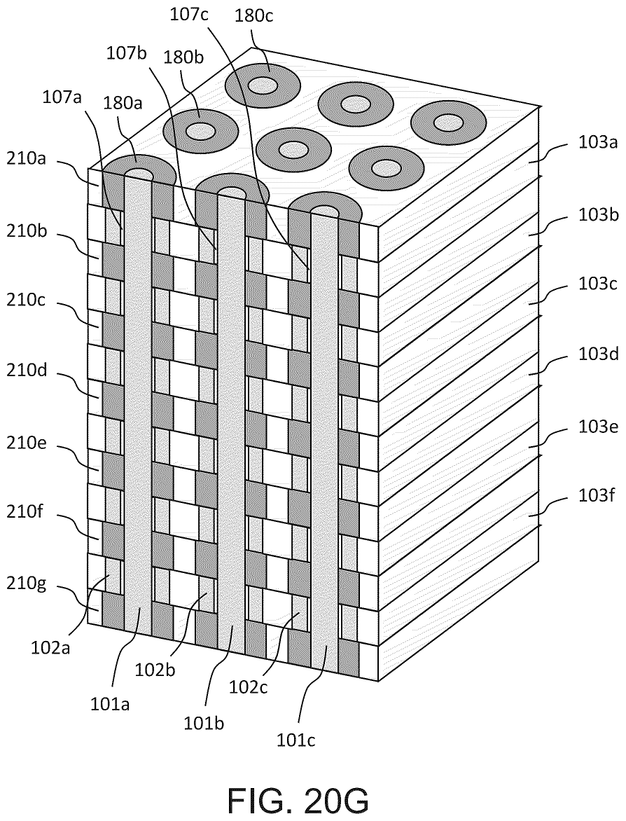

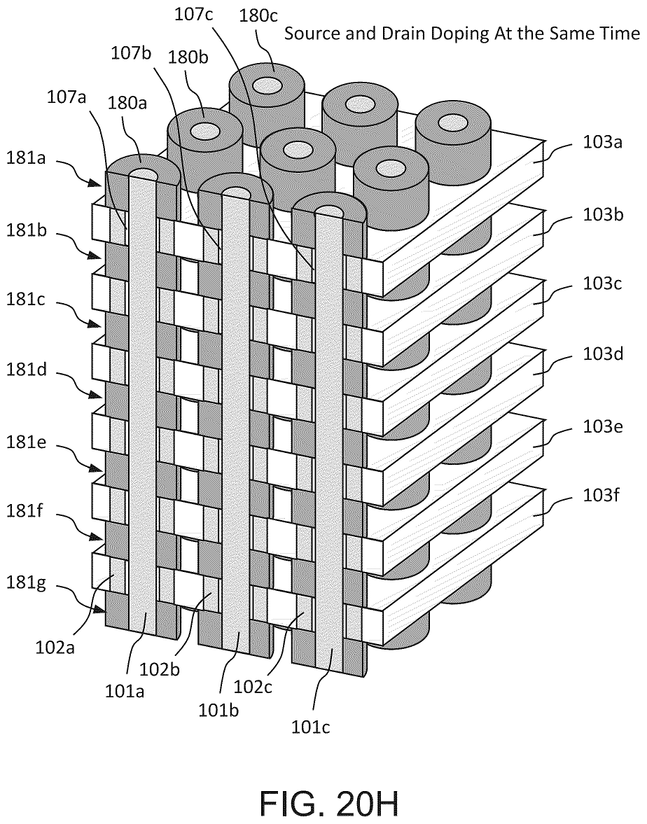

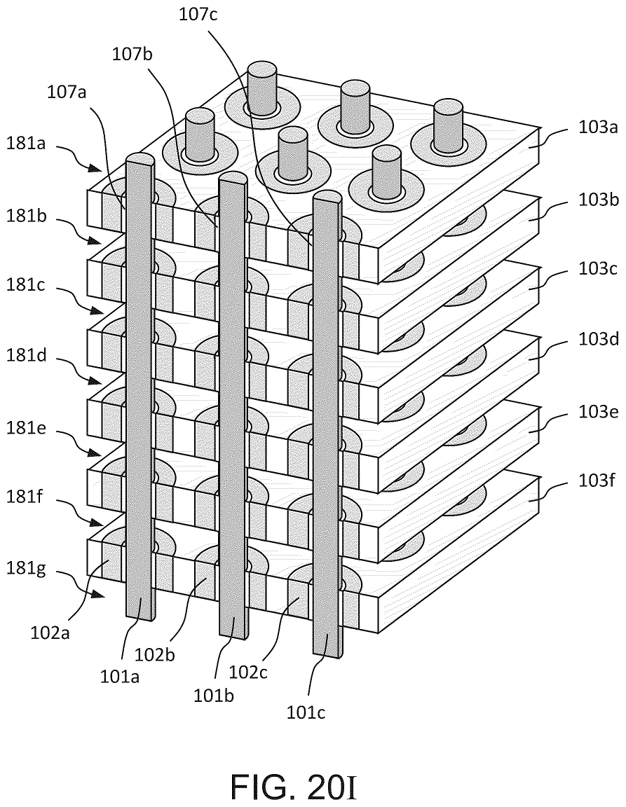

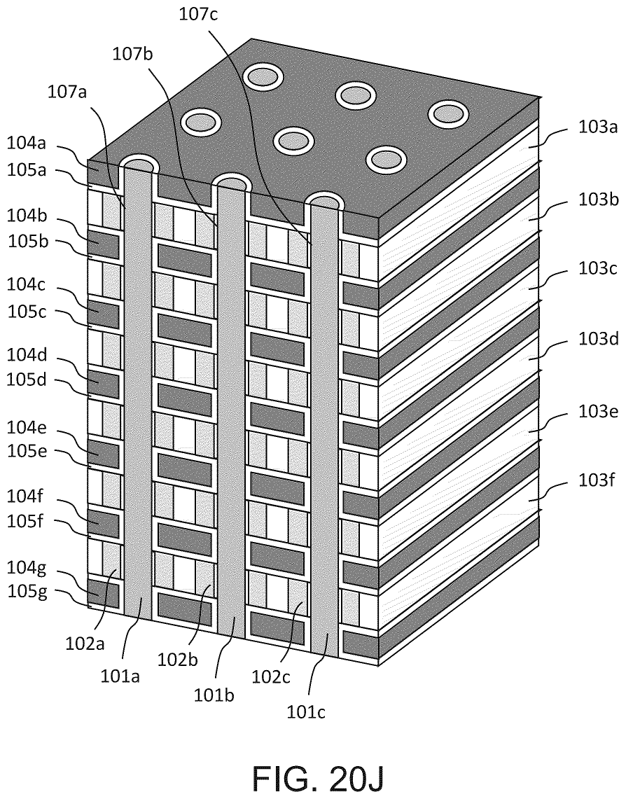

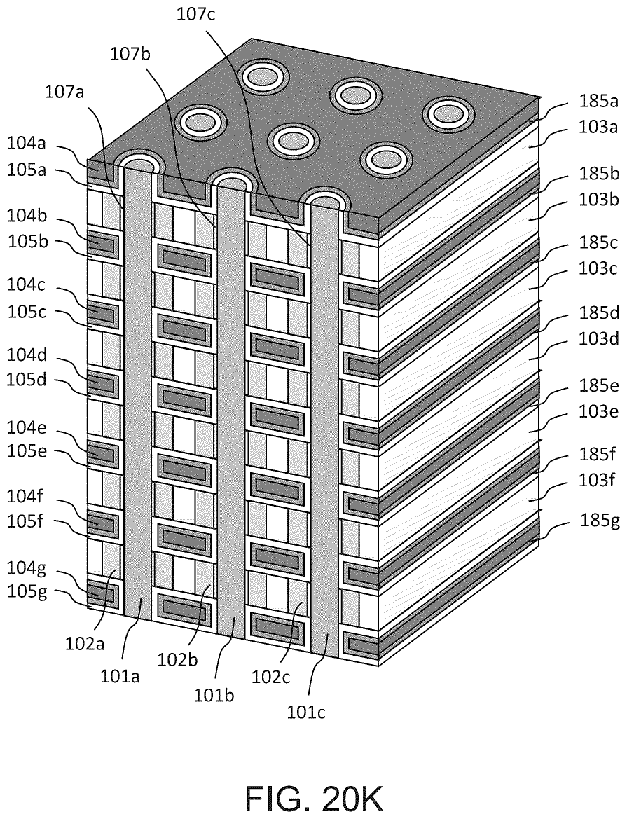

FIGS. 20A-L shows embodiments of brief process steps to form an array using the cell structure shown in FIG. 1E according to the invention.

FIG. 20A shows how multiple semiconductor layers 203a to 203f and multiple sacrificial layers 210a to 210g are alternately deposited to form a stack. In one embodiment, the semiconductor layers 203a to 203f can be any suitable semiconductor material, such as mono-silicon formed by using an epitaxial growth process, amorphous silicon form by using CVD or ALD processes, or oxide-based semiconductors, such as indium gallium zinc oxide IGZO formed by using CVD or ALD or any other suitable processes. The reader is referred to FIG. 4A for a detailed description for forming the semiconductor layers 203a to 203f.

In one embodiment, the sacrificial layers 210a to 210g are phosphorus or boron containing silicon dioxide SiO2 material, such as phosphorus silicate glass PSG or boron silicate glass BSG. The sacrificial layers 210a to 210g are deposited by any suitable process, such as CVD. In accordance with the invention, the sacrificial layers 210a to 210g are used to provide the dopants for the diffusion process.

After deposition of the layers, multiple vertical bit line holes or openings, such as holes 111a to 111c are formed by using photolithography steps to define a pattern, and then using an anisotropic etching process, such as a deep trench etching process or a dry etching process, such as plasma etching or reactive ion etching RIE to etch through the multiple semiconductor layers 203a to 203f and the sacrificial layers 210a to 210g to form the holes or openings.

FIG. 20B shows how an isotropic etching process, such as wet etching is performed through the vertical bit line holes, such as holes 111a to 111c, to selectively etch the sacrificial layers 210a to 210g to form recesses, such as recesses 186a to 186c. The dimensions of the recesses 186a to 186c are controlled by the etching rate of the etching solution, etching time, and the temperature.

FIG. 20C shows how the recesses, such as recesses 186a to 186c, are filled with a second sacrificial material, such as sacrificial material 180a to 180c through the vertical bit line holes 111a to 111c. The second sacrificial material can be deposited by using any suitable deposition process, such as chemical vapor deposition CVD or atomic layer deposition ALD. In one embodiment, the second sacrificial material 180a to 180c is hydrogenated silicon nitride SiNx:H, which releases hydrogen atoms during thermal treatment. The hydrogen atoms will diffuse into grain boundaries of the polysilicon and accumulate in them to pacify the grain boundaries. In another embodiment, the second sacrificial material 180 is any suitable sacrificial material, such as silicon nitride SiN, silicon dioxide SiO2, or silicon germanium SiGe.

FIG. 20D shows how an anisotropic etching process, such as dry etching is performed to etch the second sacrificial material to re-form the vertical bit line holes, such as vertical bit line holes 111a to 111c.

FIG. 20E shows how a phosphorus or boron material containing silicon dioxide (SiO2) material, such as phosphorus silicate glass (PSG) or boron silicate glass (BSG) is deposited on the sidewall of the vertical bit line holes, such as bit line holes 111a to 111c by using any suitable deposition process, such as ALD or CVD to form dopant containing layers 204a to 204c.

FIG. 20F shows how a thermal predeposition and drive-in process is performed to cause the phosphorus or boron to diffuse from the sacrificial layers 210a to 210g into the semiconductor layers 203a to 203f using the second sacrificial materials 180a to 180c as hard masks. The regions of the semiconductor layers 103a to 103f that are not covered by the second sacrificial materials 180a to 180c will be doped to become source lines 103a to 103f. The regions of the semiconductor layers 103a to 103f that are covered by the second sacrificial materials 180a to 180c will not be doped. These covered regions will become floating bodies, such as floating bodies 102a to 102c.

The thermal predeposition and drive-in process will cause the phosphorus or boron to diffuse from the dopant containing layer 204a to 204c into the semiconductor layers 203a to 203f to form drain regions such as 107a to 107c. The high temperature of the thermal predeposition and drive-in process will also convert the amorphous silicon into polysilicon.

If the second sacrificial materials 180a to 180c is hydrogenated silicon nitride (SiNx:H), the high temperature thermal cycle will release hydrogen atoms from the silicon nitride that diffuse into the floating bodies 102a to 102c to pacify the defects in the grain boundaries of the polysilicon. This will improve the polysilicon quality.

FIG. 20G shows how the dopant containing layers 204a to 204c are etched by using an isotropic etching process, such as wet etching. Next, the vertical bit line holes are filled with conductor material, such as metal or heavily doped polysilicon by using a suitable deposition process, such as CVD, to form vertical bit lines 101a to 101c.

FIG. 20H shows how the sacrificial layers 210a to 210g are selectively etched by using an isotropic etching process, such as wet etching, to form spaces 181a to 181g between the semiconductor layers 103a to 103f.

FIG. 20I shows how the second sacrificial material 180a to 180c is selectively etched by using an isotropic etching process, such as wet etching.

FIG. 20J shows how a gate dielectric layer 105a to 105g is deposited on the surface of the structure through the spaces 181a to 181g using a suitable deposition process, such as ALD or CVD. Next, the spaces 181a to 181g are filled with conductor material, such as metal or heavily doped polysilicon by using any suitable deposition process, such as CVD or ALD to form the front gates and back gates 104a to 104g.

FIG. 20K shows another embodiment in which the gates 104a to 104g are formed of tungsten (W) and titanium nitride (TiN) material. In this embodiment, after the gate dielectric layers 105a to 105g are deposited, gluing layers 185a to 185g comprising material such as titanium nitride TiN, are deposited on the surface of the gate dielectric layers 105a to 105g by using ALD or CVD. Next, tungsten material is deposited by using ALD or CVD to fill the spaces between the gluing layers 185a to 185g to form the gates 104a to 104g.

Thus, in accordance with the above operations, a method for forming a cell structure comprises forming a stack comprising alternating layers of a first material and a second material, forming a hole through the alternating layers of the stack, and removing portions of the second material around the hole to form recesses in the second material around the hole. The method also comprises filling the recesses with a third material and diffusing dopants from the second material into the first material while the third material acts as a hard mask.

Furthermore, in accordance with the above embodiments, a cell structure is formed that comprises a stack comprising alternating layers of a first material and a second material, a hole through the alternating layers of the stack, recesses in the second material around the hole, a third material filling the recesses, and dopants diffused from the second material into the first material while the third material acts as a hard mask.

Still further, in accordance with the above embodiments, a memory cell structure is formed by a process of forming a stack comprising alternating layers of a first material and a second material, forming a hole through the alternating layers of the stack, removing portions of the layers of the second material around the hole to form recesses in the second material around the hole, filling the recesses with a third material, and diffusing dopants from the second material into the first material while the third material acts as a hard mask.

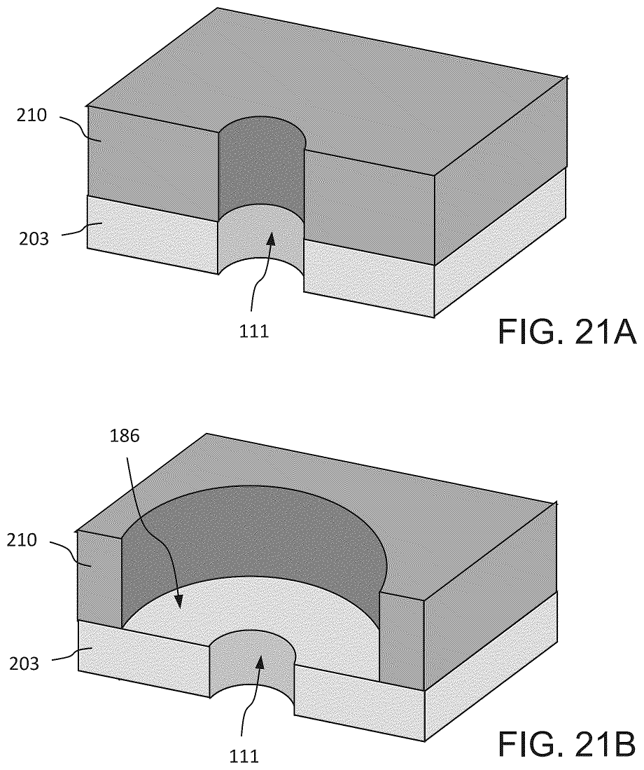

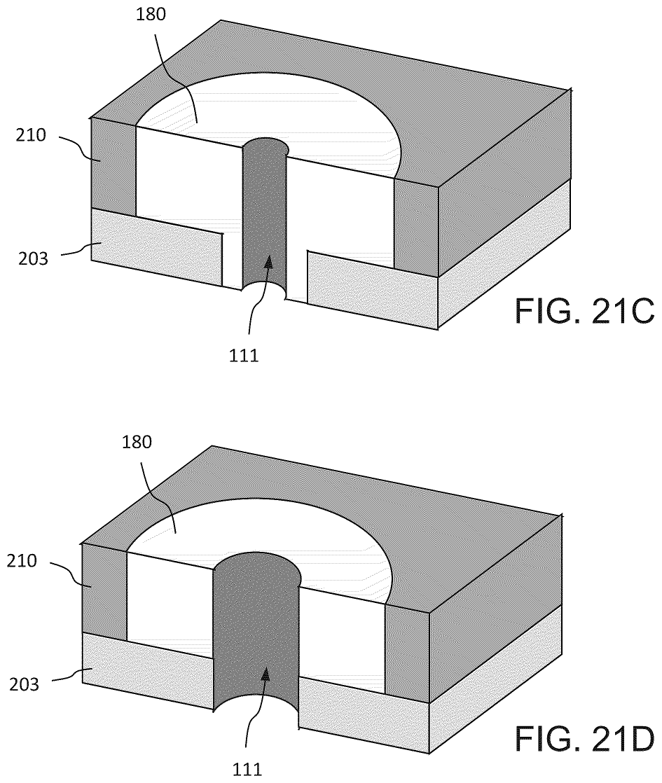

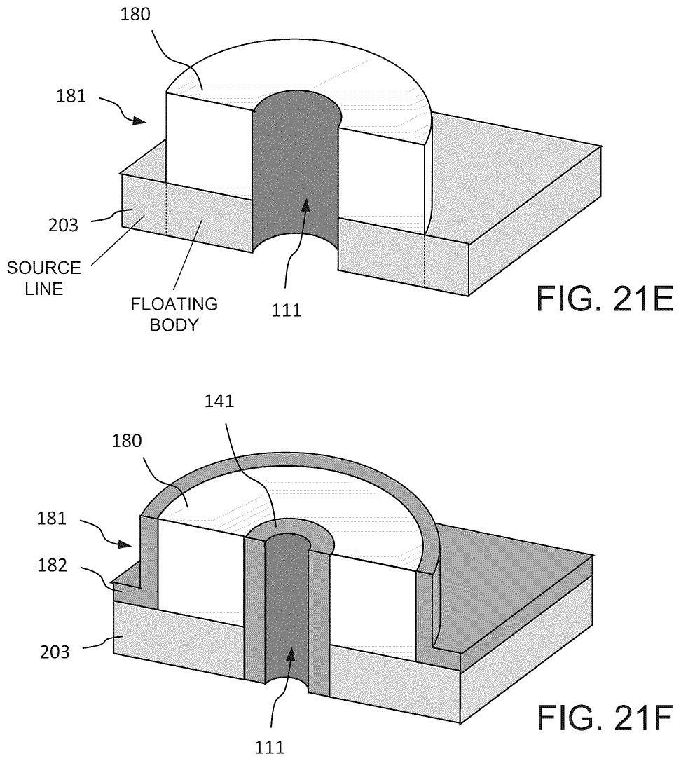

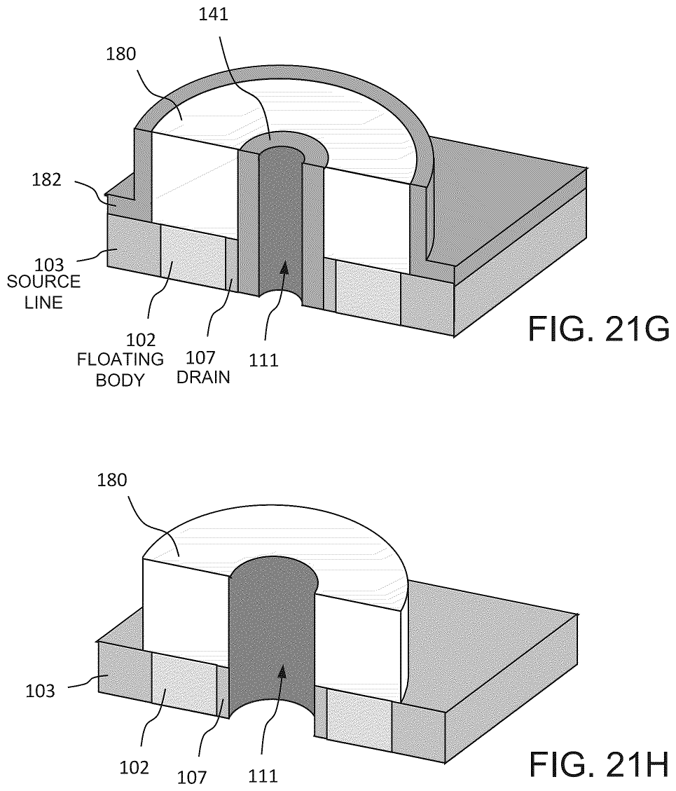

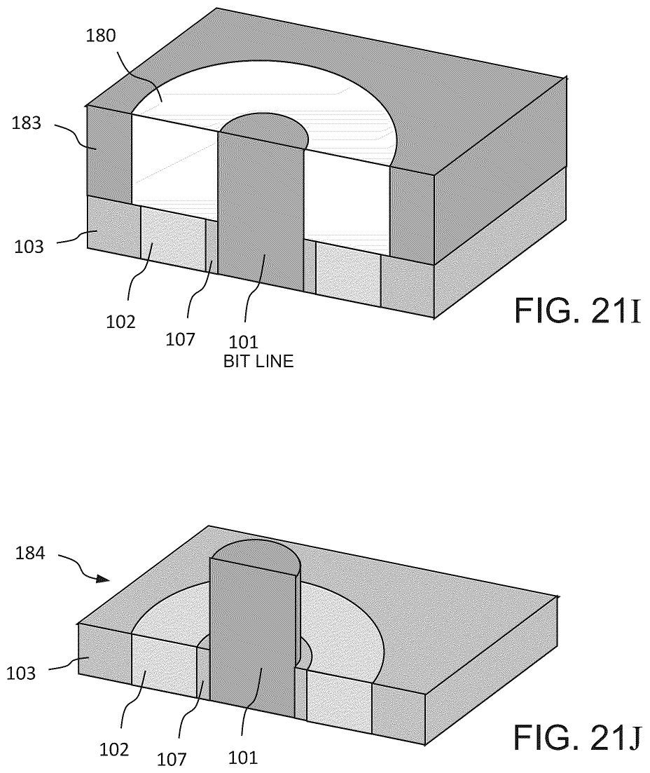

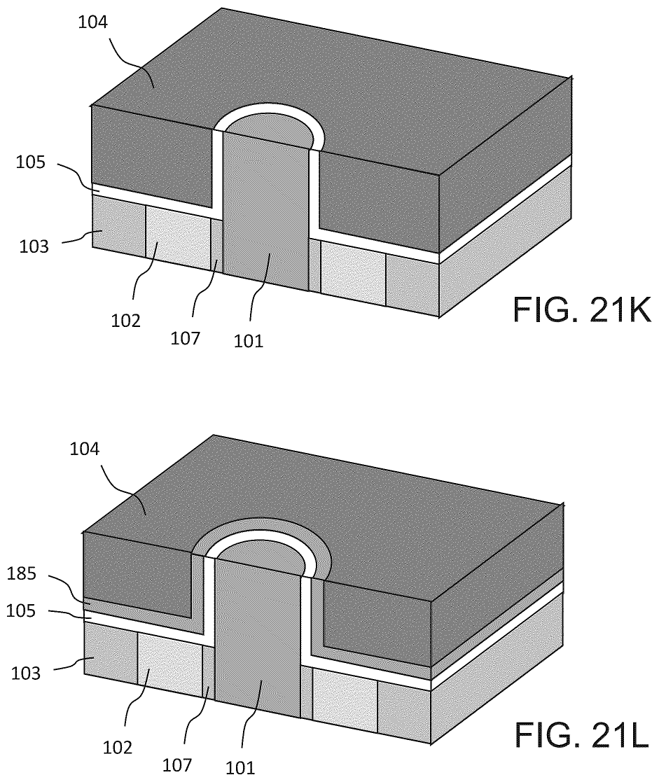

FIGS. 21A-L show process steps performed using a single cell to demonstrate the process steps shown in FIGS. 14A-F and FIGS. 16A-C.

FIG. 21A shows how multiple semiconductor layers, such as layer 203 and multiple sacrificial layers, such as layer 210, are alternately deposited to form a stack. The semiconductor layer 203 comprises any suitable semiconductor material, such as mono-silicon, amorphous silicon, polysilicon, or oxide-based semiconductor material, such as indium gallium zinc oxide (IGZO) and many others.

In one embodiment, semiconductor layer 203 is lightly doped with P-type of dopants, such as boron or N-type of dopants, such phosphorus, using an in-situ doping process. In another embodiment, semiconductor layer 203 is intrinsic. In one embodiment, the sacrificial layer 210 comprises silicon oxide (SiO2) or silicon nitride (Si3N4) layers. The reader is referred to the description of FIG. 4A for a detailed description for forming the semiconductor layer 203 and the sacrificial layer 210.

After the deposition of the layers, multiple vertical bit line holes, such as hole 111, are formed through the layers by using photolithography steps to define a pattern, and then using an anisotropic etching process, such as a deep trench etching process or a dry etching process, such as plasma etching or reactive ion etching (RIE), to etch through the multiple semiconductor layer 203 and the sacrificial layer 210.

FIG. 21B shows how an isotropic etching process, such as wet etching, is performed through the vertical bit line hole 111 to selectively etch the sacrificial layer 210 to form recess 186. The dimensions of the recess 186 are controlled by the etching rate of the etching solution, etching time, and the temperature.

FIG. 21C shows how the recesses 186 are filled with a second sacrificial material 180 through the vertical bit line hole 111. The second sacrificial material 180 is deposited using any suitable deposition process, such as CVD or ALD. In one embodiment, the second sacrificial material 180 comprises any suitable sacrificial material, such as silicon nitride (SiN), silicon dioxide (SiO2), or silicon germanium (SiGe). In another embodiment, the second sacrificial material 180 is hydrogenated silicon nitride (SiNx:H), that releases hydrogen atoms during thermal treatment. The hydrogen atoms diffuse into grain boundaries of the polysilicon and accumulate in them to pacify the grain boundaries.

Depending on the process control, in one embodiment, a small vertical bit line hole 111 will exist after the deposition process. This small hole allows the second sacrificial material 180 to be etched using an isotropic etching process, such as wet etching in the next process step. In another embodiment, the second sacrificial material fills the entire vertical bit line hole 111. Then, the second sacrificial material 180 is etched by using an anisotropic etching process, such as dry etching.

FIG. 21D shows how an isotropic etching process, such as wet etching or an anisotropic etching process, such as dry etching, is performed to etch the second sacrificial material 180 to re-form the vertical bit line hole 111.

FIG. 21E shows how the sacrificial layer 210 is selectively etched using an isotropic etching process, such as wet etching to form spaces 181.

According to the invention, a doping process, such as a diffusion process, is performed through the space 181 to dope the semiconductor layer 203 to form the source line 103 shown in FIG. 1E. The second sacrificial material 180 is used as hard masks to define the floating bodies for the doping process. The regions of the semiconductor layer 203 not covered by the second sacrificial material 180 are doped to form the source lines. The regions of the semiconductor layer 103 covered by the second sacrificial material 180 will not be doped and become the floating bodies.

In one embodiment, the dopants have the opposite type of doping from the semiconductor layer 203. For example, if the semiconductor layer 203 has P− or N− type of light doping, the doping through the space 181 has N+ type of dopants, such as phosphorus or P+ type of dopants such as boron, respectively. In another embodiment, the dopants have the same type as the doping of the semiconductor layer 203. This configuration forms a junction-less device. For example, a junction-less device is formed when the semiconductor layer 203 has P− or N− type of light doping, the doping through the spaces 181 has P+ type of dopants, such as boron, or N+ type of dopants, such as phosphorus, respectively.

In one embodiment, the doping process uses gas-phase diffusion, such as plasma doping or dopant containing gas doping, or liquid-phase diffusion, such as using spin-on coating with organic or inorganic dopants that contain phosphorus or boron, or solid-phase diffusion, such as using CVD or ALD to deposit phosphorus or boron containing silicon dioxide (SiO2) materials. These doping processes have been described with reference to FIG. 4C. The reader is referred to FIG. 4C for detailed descriptions. FIGS. 19A-B shows some examples of the processes of phosphorus diffusion and boron diffusion, respectively. The reader is referred to FIGS. 19A-B for detailed descriptions. It should be noted that the processes shown in FIGS. 19A-B are examples only. Using any other doping processes shall remain within the scope of the invention.

FIG. 21F shows an embodiment of process steps using solid-phase diffusion. After the process shown in FIG. 21E, thin layers of dopant source material 182 and 141, comprising material such as boron or phosphorus containing silicon dioxide (SiO2) or a material called boron silicate glass (BSG) and phosphorus silicate glass (PSG), are deposited on the surface of the semiconductor layer 203 and the sidewall of the vertical bit line hole 111 using ALD or CVD processes. Then, a thermal predeposition and drive-in process is performed to cause the dopants to diffuse from the dopant source material 182 and 141 into the semiconductor layer 203.

FIG. 21G shows the result after the solid-phase type of diffusion. The regions of the semiconductor layer 203 that are not covered by the second sacrificial material 180 will be heavily doped. These regions become source lines 103. The regions of the semiconductor layer 103 that are covered by the second sacrificial material 180 will remain lightly doped. These regions become floating bodies 102. The dopants form the dopant source material 141 will diffuse into the semiconductor layer 203 to form the drain region 107. Thus, after the process steps shown in FIG. 21G, the semiconductor layer 203 shown in FIG. 20F is doped and becomes two regions, namely, the source line 103 and the floating body 102.

FIG. 21H shows that after the doping process, the dopant source materials 182 and 141 are removed using an isotropic etching process, such as wet etching.

FIG. 21I show how a sacrificial material 183 is deposited to fill the space 181 by using an appropriate deposition processes, such as CVD or ALD. After that, the vertical bit line hole 111 is filled with conductor material, such as metal or heavily doped polysilicon by using proper deposition processes, such as CVD to form a vertical bit line 101.

FIG. 21J shows how the sacrificial layers 183 and 180 are selectively etched by using an isotropic etching process, such as wet etching to form spaces 184.

FIG. 21K shows how a gate dielectric layer 105 is deposited on the surface of the structure through the space 184 using a suitable deposition process, such as ALD or CVD. Then, the space 184 is filled with conductor material, such as metal or heavily doped polysilicon by using a suitable proper deposition process, such as ALD or CVD to form the front gates and back gates 104.

FIG. 21L shows an embodiment in which the gate 104 is formed of tungsten (W) material. In this embodiment, after the gate dielectric layer 105 is deposited, a gluing layer 185, comprising material such as titanium nitride (TiN), is deposited on the surface of the gate dielectric layer 105. Then, tungsten is deposited to form gate 104.

Although the embodiments shown in FIGS. 21A-L show that the source line 103 and the drain region 107 are doped at together, in other embodiments, the source line 103 and the drain region 107 are doped separately, as shown in FIGS. 14E-P. In another embodiment, the drain region 107 is formed by using a deposition process instead of a doping process, as shown in FIGS. 15A-C. The reader is referred to these embodiments for detailed descriptions.

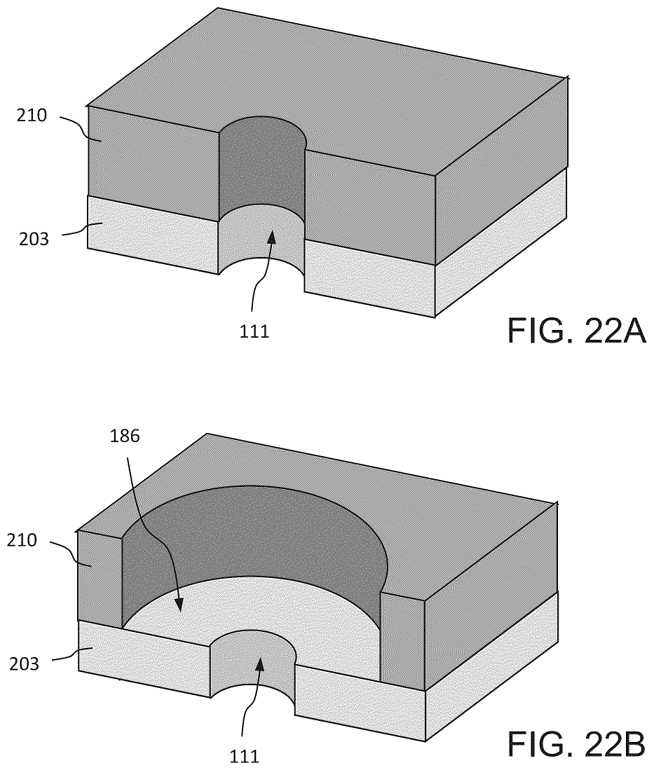

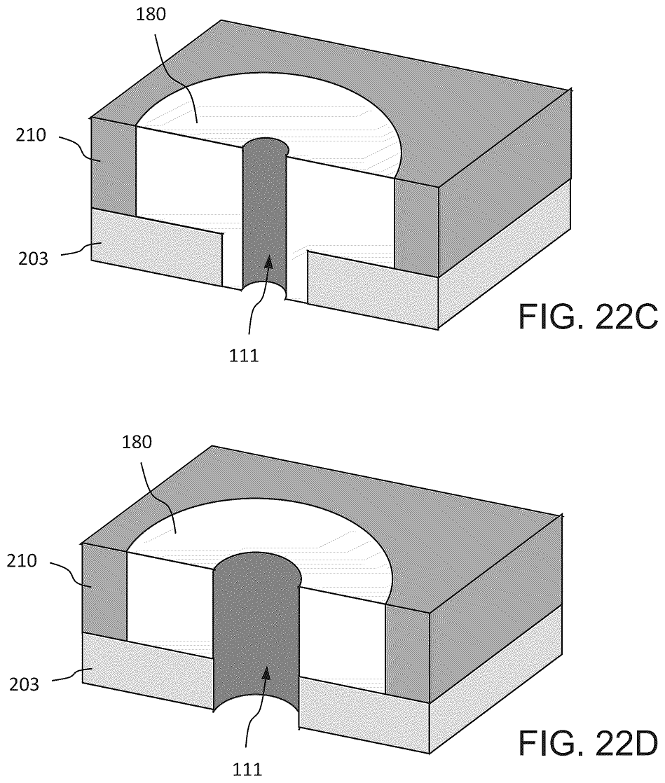

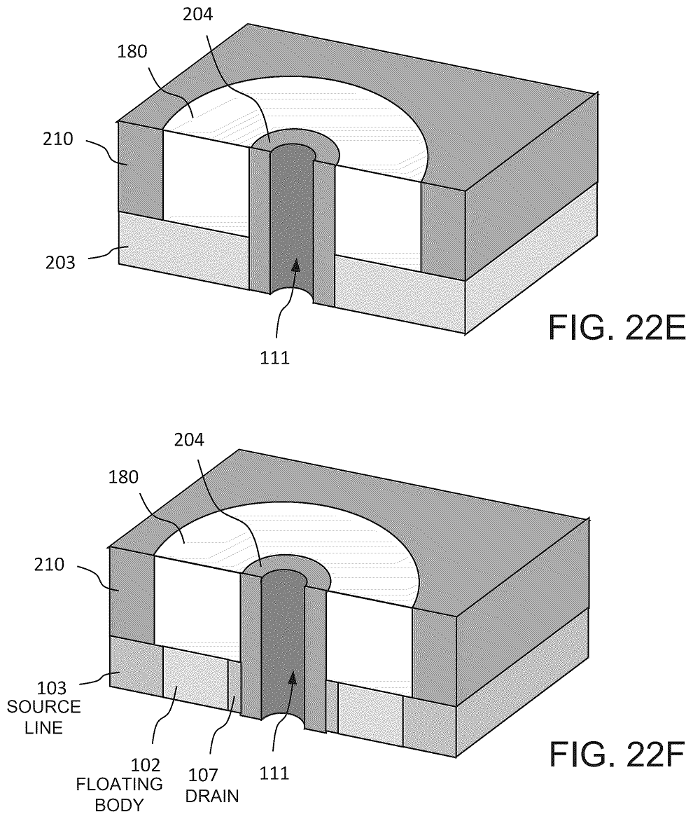

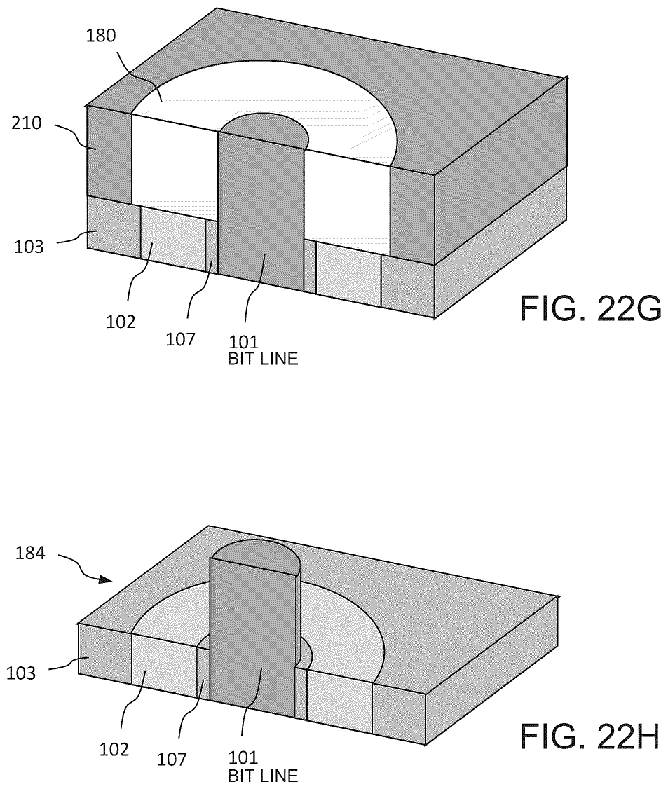

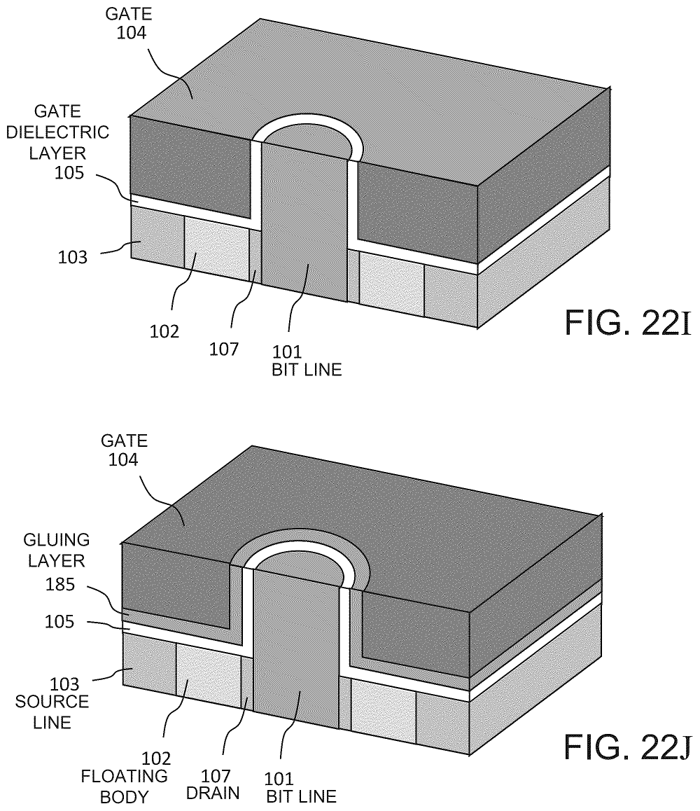

FIGS. 22A-J show embodiments of process steps using a single cell to demonstrate the process steps shown in FIGS. 20A-K.

FIG. 22A shows how multiple semiconductor layers 203 and multiple sacrificial layers 210 are alternately deposited to form a stack. The semiconductor layer 203 comprises any suitable semiconductor material, such as mono-silicon formed by using epitaxial growth process, amorphous silicon form by using CVD or ALD processes, or oxide-based semiconductors, such as indium gallium zinc oxide (IGZO) formed by using CVD or ALD or any other suitable processes. The reader is referred to FIG. 4A for a detailed description for forming the semiconductor layer 203.

In one embodiment, the sacrificial layer 210 comprises phosphorus or boron containing silicon dioxide (SiO2) material, such as phosphorus silicate glass (PSG) or boron silicate glass (BSG). The sacrificial layer 210 is deposited using any suitable process, such as CVD or ALD. In accordance with the invention, the sacrificial layer 210 can be used to provide the dopants for the diffusion process.

After the deposition, multiple vertical bit line holes, such as hole 111, are formed by using photolithography steps to define a pattern, and then using anisotropic etching process, such as deep trench process or dry etching process, such as plasma etching or reactive ion etching (RIE), to etch through the multiple semiconductor layers 203 and the sacrificial layers 210 of the stack.

FIG. 22B shows how an isotropic etching process, such as wet etching, is performed through the vertical bit line hole 111 to selectively etch the sacrificial layer 210 to form recesses, such as recess 186. The dimensions of the recess 186 is controlled by the etching rate of the etching solution, etching time, and the temperature.

FIG. 22C shows how the recess 186a is filled with second sacrificial material, such as material 180 through the vertical bit line hole 111. In one embodiment, the second sacrificial material 180 is deposited using any suitable deposition process, such as CVD or ALD. In one embodiment, the second sacrificial material 180 comprises any suitable sacrificial material, such as silicon nitride (SiN), silicon dioxide (SiO2), or silicon germanium (SiGe). In another embodiment, the second sacrificial material 180 comprises hydrogenated silicon nitride (SiNx:H), that releases hydrogen atoms during thermal treatment. The hydrogen atoms will diffuse into grain boundaries of the polysilicon and accumulate in them to pacify the grain boundaries.

Depending on the process control, in one embodiment, a small vertical bit line hole 111 exists after the deposition. This hole allows the second sacrificial material 180 to be etched using an isotropic etching process, such as wet etching in the next process step. In another embodiment, the second sacrificial material fills the entire vertical bit line hole 111. In this case, the second sacrificial material 180 is etched by using an anisotropic etching process, such as dry etching.

FIG. 22D shows how an isotropic etching process, such as wet etching or an anisotropic etching process, such as dry etching is performed to etch the second sacrificial material 180 to re-form the vertical bit line hole 111.

FIG. 22E shows how a phosphorus or boron material containing silicon dioxide (SiO2) material such as phosphorus silicate glass (PSG) or boron silicate glass (BSG) is deposited on the sidewall of the vertical bit line hole 111 by using a suitable deposition process, such as ALD or CVD to form a dopant containing layer 204.

FIG. 22F shows how a thermal predeposition and drive-in process is performed to cause the phosphorus or boron to diffuse from the sacrificial layer 210 into the semiconductor layer 203 using the second sacrificial material 180 as a hard mask. The regions of semiconductor layer 203 that are not covered by the second sacrificial material 180 will be doped to become the source line 103. The regions of the semiconductor layer 103 that are covered by the second sacrificial material 180 will not be doped. These regions will become floating bodies 102.

The thermal predeposition and drive-in process causes the phosphorus or boron to diffuse from the dopant containing layer 204 into the semiconductor layer 203 to form drain region 107. The high temperature of the thermal predeposition and drive-in process also converts the amorphous silicon into polysilicon.

If the second sacrificial material 180 is hydrogenated silicon nitride (SiNx:H), the high temperature thermal cycle releases hydrogen atoms from the silicon nitride and these atoms diffuse into the floating body 102 to pacify the defects in the grain boundaries of the polysilicon. This process improves the polysilicon quality.

FIG. 22G shows how the dopant containing layer 204 is etched by using an isotropic etching process, such as wet etching. Next, the vertical bit line holes 111 are filled with conductor material, such as metal or heavily doped polysilicon by using a deposition process, such as CVD, to form a vertical bit line 101.

FIG. 22H shows how the sacrificial layers 210 and the second sacrificial material 180 are selectively etched by using an isotropic etching process, such as wet etching, to form a space 184.

FIG. 22I shows how a gate dielectric layer 105 is deposited on the surface of the structure through the space 181 using a suitable deposition process, such as ALD or CVD. Next, the space 181 is filled with conductor material, such as metal or heavily doped polysilicon by using a suitable deposition process, such as CVD or ALD to form the gate 104.

FIG. 22J shows an embodiment in which the gate 104 is formed of tungsten W material. In this embodiment, after the gate dielectric layer 105 is deposited, a gluing layer 185 comprising material such as titanium nitride TiN, is deposited on the surface of the gate dielectric layer 105. Next, tungsten material is deposited to form the gates 104.

Although the embodiments shown in FIGS. 22A-J show that the source line 103 and the drain region 107 are doped together, in another embodiment, the source line 103 and the drain region 107 are doped separately, as shown in FIGS. 14E-P. In another embodiment, the drain region 107 is formed using a deposition process instead of doping process, as shown in FIGS. 15A-C. The reader is referred to those embodiments for detailed descriptions.

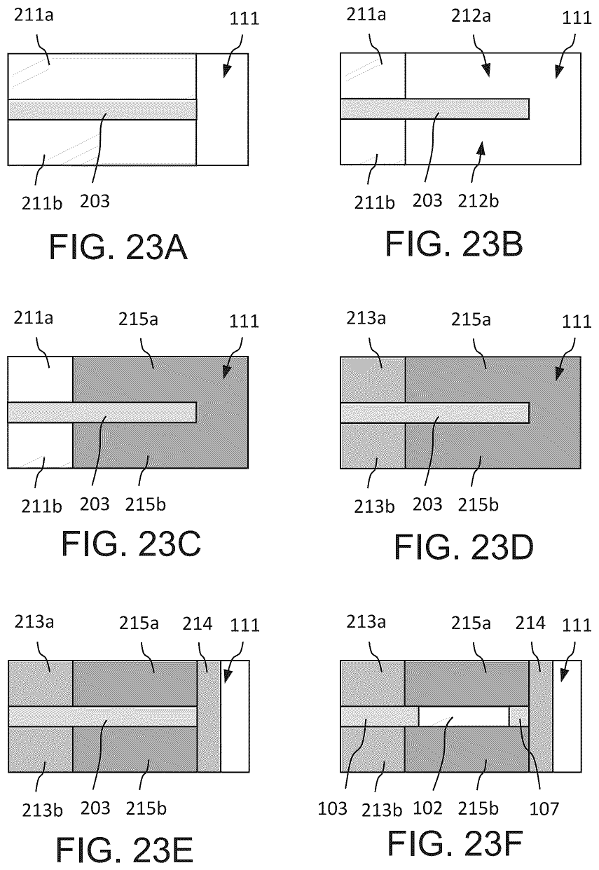

FIGS. 23A-F show embodiments of process steps to form the cell structure shown in FIG. 1E.

FIG. 23A shows how multiple semiconductor layers, such as layers 203 and multiple sacrificial layers, such as layers 211a and 211b are alternately deposited to form a stack. The semiconductor layer 203 comprises any suitable semiconductor material, such as mono-silicon, amorphous silicon, or oxide-based semiconductors such as indium gallium zinc oxide (IGZO). In this embodiment, the semiconductor layer 203 is intrinsic (un-doped). The sacrificial layers 211a and 211b comprise any suitable materials, such as oxide or nitride. After the deposition process, an anisotropic etching process, such as a dry etching or a deep trench process, is performed to etch through the stack to form vertical bit line holes 111.

FIG. 23B shows how an isotropic etching process, such as wet etching, is performed through the vertical bit line hole 111 to selectively etch the sacrificial layers 211a and 211b to form recesses 212a and 212b.

FIG. 23C shows how dopant containing materials 215a and 215b, such as boron or phosphorus containing silicon dioxide (SiO2) or called boron silicate glass (BSG) and phosphorus silicate glass (PSG), are deposited through the vertical bit line hole 111 to fill the recesses 212a and 212b by using a suitable deposition process, such as ALD or CVD.

FIG. 23D shows how the sacrificial layers 211a and 211b are etched by using an isotropic etching process, such as wet etching. Next, dopant containing materials 213a and 213b, such as boron or phosphorus containing silicon dioxide (SiO2) or called boron silicate glass (BSG) and phosphorus silicate glass (PSG), are deposited by using a suitable deposition process, such as ALD or CVD to fill the space previously occupied by the sacrificial layers 211a and 211b.

The dopant containing materials 213a and 213b have the opposite type of doping from the dopant containing materials 215a and 215b. For example, in one embodiment, the dopant containing materials 215a and 215b have P type of dopants, such as boron, and the dopant containing materials 213a and 213b have N type of dopants, such as phosphorus. The dopant concentrations of the dopant containing materials 213a and 213b are higher than that of the dopant containing materials 215a and 215b. This configuration causes the source line 103 and the floating body 102 shown in FIG. 23F to be doped with N+ and P− type of doping, respectively.

FIG. 23E shows how an anisotropic etching process, such as dry etching, is performed to re-form the vertical bit line hole 111. Next, a dopant containing material 214, such as boron or phosphorus containing silicon dioxide (SiO2) or called boron silicate glass (BSG) and phosphorus silicate glass (PSG), is deposited using a suitable deposition process, such as ALD or CVD to form a layer on the sidewall of the vertical bit line hole 111.

FIG. 23F shows how a thermal predeposition and drive-in process is performed to cause dopants to diffuse from the dopant containing materials 213a, 213b, 215a, 215b, and 214 into the semiconductor layer 203 to form the source line 103, floating body 102, and drain region 107, respectively. Next, the dopant containing materials 213a, 213b, 215a, 215b, and 214 are etched by using an isotropic etching process, such as wet etching. After that, process steps such as those described with respect to FIG. 22I-J are applied to form the gate dielectric layer 105 not shown and the gate 104 not shown. The reader is referred to the descriptions of FIGS. 22I-J detailed descriptions.

In another embodiment, the drain region 107 is formed by using a deposition and in-situ doping process as shown in FIGS. 15A-B instead of using a doping process. The reader is referred to FIG. 15A-B for detailed descriptions.

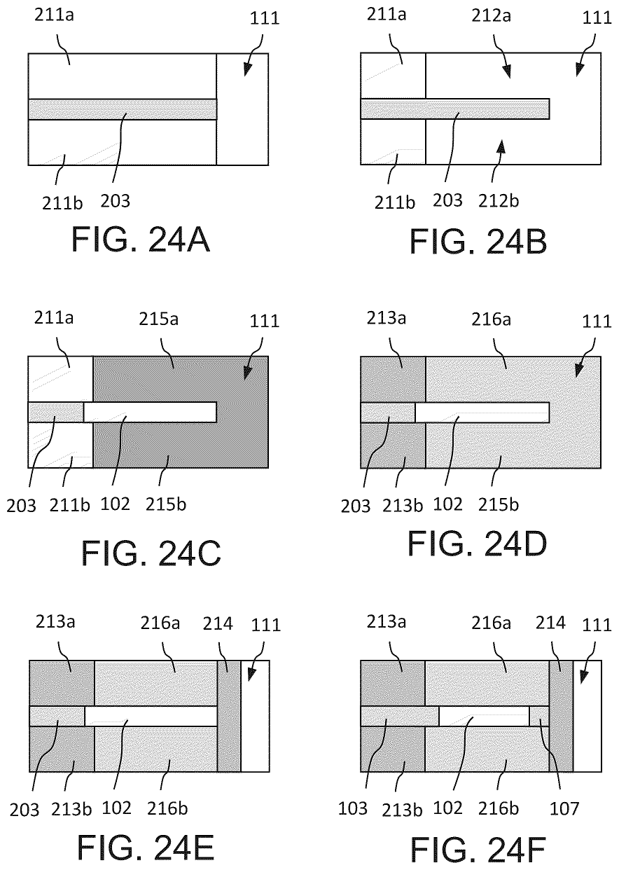

FIGS. 24A-F show embodiments of process steps to form the cell structure shown in FIG. 1E.

FIG. 24A shows how multiple semiconductor layers, such as layer 203 and multiple sacrificial layers, such as layers 211a and 211b, are alternately deposited to form a stack. The semiconductor layer 203 comprises any suitable semiconductor material, such as mono-silicon, amorphous silicon, or oxide-based semiconductors such as indium gallium zinc oxide (IGZO). In this embodiment, the semiconductor layer (203) is intrinsic (un-doped). The sacrificial layers (211a) and (211b) comprise any suitable materials, such as oxide or nitride. After the deposition process, an anisotropic etching process, such as dry etching or a deep trench process, is performed to etch through the stack to form vertical bit line holes (111).

FIG. 24B shows how an isotropic etching process, such as wet etching, is performed through the vertical bit line hole 111 to selectively etch the sacrificial layers 211a and 211b to form recesses 212a and 212b.

FIG. 24C shows how dopant containing materials 215a and 215b, such as boron or phosphorus containing silicon dioxide (SiO2) or called boron silicate glass (BSG) and phosphorus silicate glass (PSG), are deposited through the vertical bit line hole 111 to fill the recesses 212a and 212b by using any suitable deposition process, such as ALD or CVD.

Next, a thermal predeposition and drive-in process is performed to cause the dopant to diffuse from the dopant containing materials 215a and 215b into the semiconductor layer 203 to form a floating body 102.

FIG. 24D shows how the dopant containing materials 215a and 215b are etched using an isotropic etching process, such as wet etching, to re-form the recesses 212a and 212b and bit line hole 111. Next, second sacrificial material layers 216a and 216b, such as oxide or nitride, are deposited through the vertical bit line hole 111 to fill the recesses 212a and 212b. Next, the sacrificial layers 211a and 211b are etched using an isotropic etching process, such as wet etching. Next, dopant containing materials 213a and 213b, such as boron or phosphorus containing silicon dioxide (SiO2) or called boron silicate glass (BSG) and phosphorus silicate glass (PSG) are deposited by using any suitable deposition process, such as ALD or CVD to fill the space previously occupied by the sacrificial layers 211a and 211b.

The dopant containing materials 213a and 213b have the opposite type of doping from the dopant containing materials 215a and 215b. For example, in one embodiment, the dopant containing materials 215a and 215b comprises P type of dopants, such as boron, and the dopant containing materials 213a and 213b comprises N type of dopants, such as phosphorus. The dopant concentrations of the dopant containing materials 213a and 213b are higher than that of the dopant containing materials 215a and 215b. This configuration causes the source line 103 and the floating body 102 shown in FIG. 23F to be doped with N+ and P− type of doping, respectively.

FIG. 24E shows how an anisotropic etching process, such as dry etching, is performed to re-form the vertical bit line hole 111. Next, a dopant containing material 214, such as boron or phosphorus containing silicon dioxide (SiO2) or called boron silicate glass (BSG) and phosphorus silicate glass (PSG) is deposited using any suitable deposition process, such as ALD or CVD to form a layer on the sidewall of the vertical bit line hole 111.

FIG. 24F shows how a thermal predeposition and drive-in process is performed to cause dopant to diffuse from the dopant containing materials 213a, 213b, and 214 into the semiconductor layer 203 to form the source line 103 and the drain region 107, respectively. Next, the dopant containing materials 213a, 213b, and 214 are etched using an isotropic etching process, such as wet etching. Next, the process steps described with reference to FIGS. 22I-J are performed to form a gate dielectric layer 105 (not shown) and a gate 104 (not shown). The reader is referred to FIGS. 22I-J for detailed descriptions.

In another embodiment, the drain region 107 is formed using a deposition and in-situ doping process as shown in FIGS. 15A-B instead of using a doping process. The reader is referred to FIGS. 15A-B for detailed descriptions.

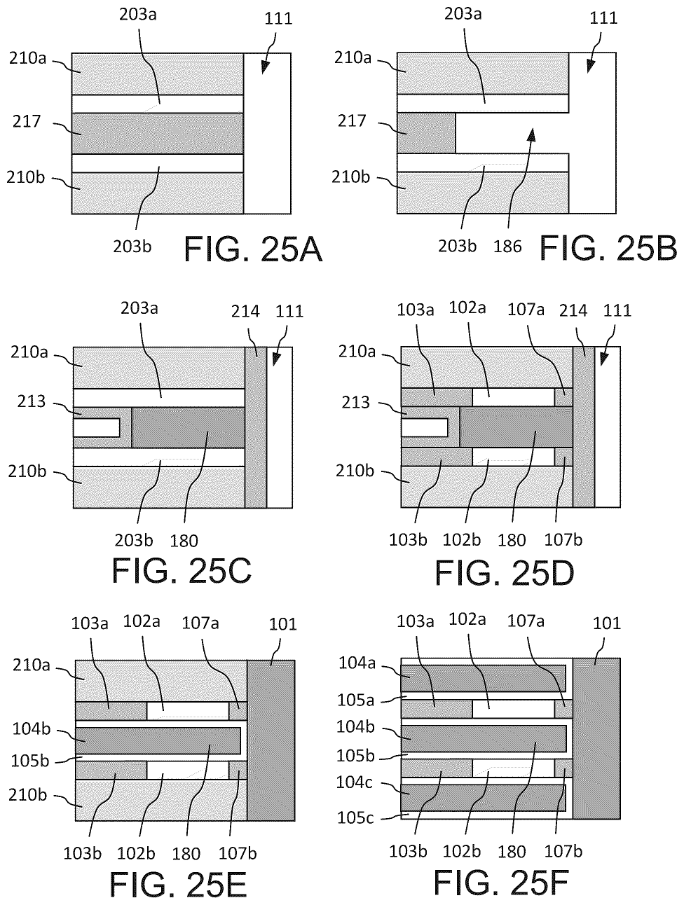

FIGS. 25A-F show embodiments of process steps to form the cell structure shown in FIG. 1E. These embodiments are similar to the embodiments shown in FIGS. 14A-N except that the even and odd sacrificial layers 110a to 110g comprise different materials. Because the semiconductor layers 103a to 103f are very thin, during the process steps shown in FIG. 14J, the semiconductor layers 103a to 103f may collapse. The process steps shown in FIGS. 25A-F solve this issue.

FIG. 25A shows how multiple semiconductor layers, such as layers 203a and 203b and multiple sacrificial layers, such as layers 210a, 217, and 210b are alternately deposited to form a stack. The even numbered sacrificial layers, such as layers 211a and 210b comprise a first sacrificial material, such as oxide (SiO2). The odd sacrificial layers, such as layer 217 comprise a second sacrificial material, such as nitride (Si3N4). These sacrificial materials are just examples, and any other suitable materials can be used. After the deposition of the layers, an anisotropic etching process, such as dry etching or a deep trench process, is performed to etch through the stack to form vertical bit line holes 111.

FIG. 25B shows how an isotropic etching process, such as wet etching, is performed through the vertical bit line holes 111 to selectively etch the second sacrificial layers 217 to form recesses 186.

FIG. 25C shows how a third sacrificial material 180 is deposited through the vertical bit line holes 111 to fill the recesses 186 using any suitable deposition process, such as CVD or ALD. After that, an anisotropic etching process is performed to etch the third sacrificial material 180 to re-form the vertical bit line holes 111.

Next, the second sacrificial layers 217 are selectively etched by performing an isotropic etching process, such as wet etching through the word line slits not shown. Next, layers of dopant source materials 213 and 214, such as boron or phosphorus containing silicon dioxide (SiO2) or called boron silicate glass (BSG) and phosphorus silicate glass (PSG) are deposited on the surface of the semiconductor layers 203a and 203b and the sidewall of the vertical bit line holes 111. The deposition is performed through the space previously occupied by the second sacrificial layers 217 by using ALD or CVD processes.

FIG. 25D shows how a thermal predeposition and drive-in process is performed to cause dopants to diffuse from the dopant source materials 213 to 214 into the semiconductor layers 203a and 203b. The regions of the semiconductor layers 203a and 203b that are not covered by the third sacrificial materials 180 will be heavily doped by the dopant source material 213 to become source lines 103a and 103b. The regions of the semiconductor layers 203a and 203b that are covered by the third sacrificial material 180 will not be doped. These regions become floating bodies 102a and 102b. In addition, the dopants will diffuse from the dopant source material 214 into the semiconductor layers 203a and 203b to form the drain regions 107a and 107b.

FIG. 25E shows how the dopant source materials 213 and 214 are removed by using an isotropic etching process, such as wet etching. Next, a conductor such as metal or heavily doped polysilicon is deposited in the vertical bit line holes 111 by using a suitable deposition process, such as CVD, to form vertical bit lines 101. Next, an isotropic etching process, such as wet etching, is performed through word line slits to etch the third sacrificial material 180.

Next, a gate dielectric layer 105b, such as hafnium oxide (HfO2), and a gate material, such as metals or heavily doped polysilicon, are sequentially deposited to form the odd gates 104b. During these process steps, the first sacrificial layers 210a and 210b prevent the semiconductor layers 203a and 203b from collapsing.

FIG. 25F shows how an isotropic etching process, such as wet etching, is performed through the word line slits to etch the first sacrificial materials 210a and 210b. Next, gate dielectric layers 105a and 105c, such as hafnium oxide (HfO2), and a gate material, such as metal or heavily doped polysilicon, are sequentially deposited to form the even gates 104a and 104c. During these process steps, the odd gates 104b prevent the semiconductor layers 203a and 203b from collapsing.

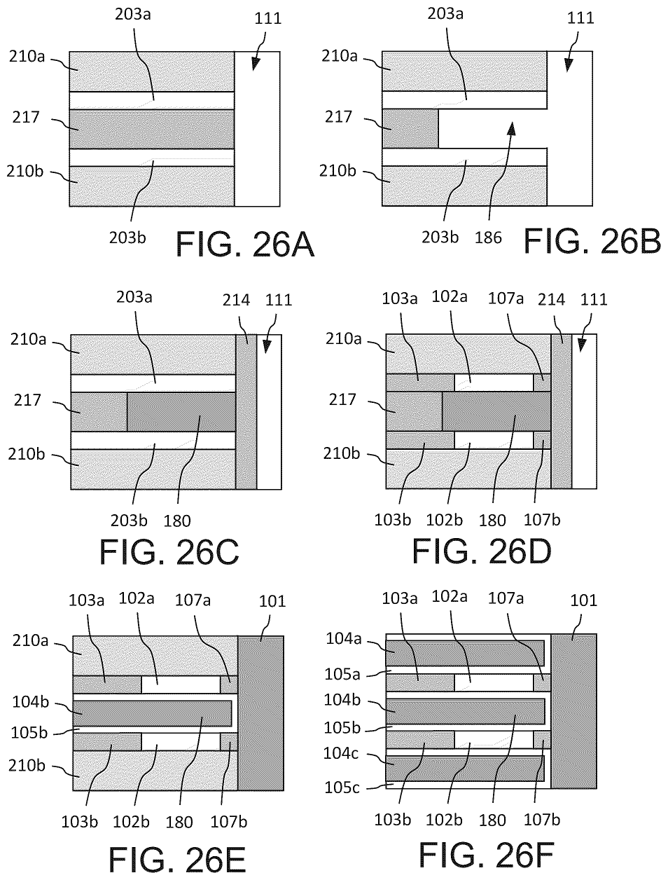

FIGS. 26A-F show embodiments of brief process steps performed to form the cell structure shown in FIG. 1E. These embodiments are similar to the embodiments shown in FIGS. 20A-K except that the even and odd sacrificial layers 110a to 110g use different materials. This configuration prevents the thin semiconductor layers 203a to 203f from collapsing during the process steps shown in FIG. 20I.

The process steps shown in FIGS. 26A-F are similar to the process steps shown in FIGS. 25A-F except that in the step shown in FIG. 26A, the odd layers 217 are formed of a dopant source material, such as boron or phosphorus containing silicon dioxide (SiO2) or called boron silicate glass (BSG) and phosphorus silicate glass (PSG). This configuration eliminates the process steps performed to etch the second sacrificial layers 217 and replaces it with a layer of dopant source material 213 shown in FIG. 25C. The reader is referred to FIGS. 25A-F for detailed descriptions of these process steps.

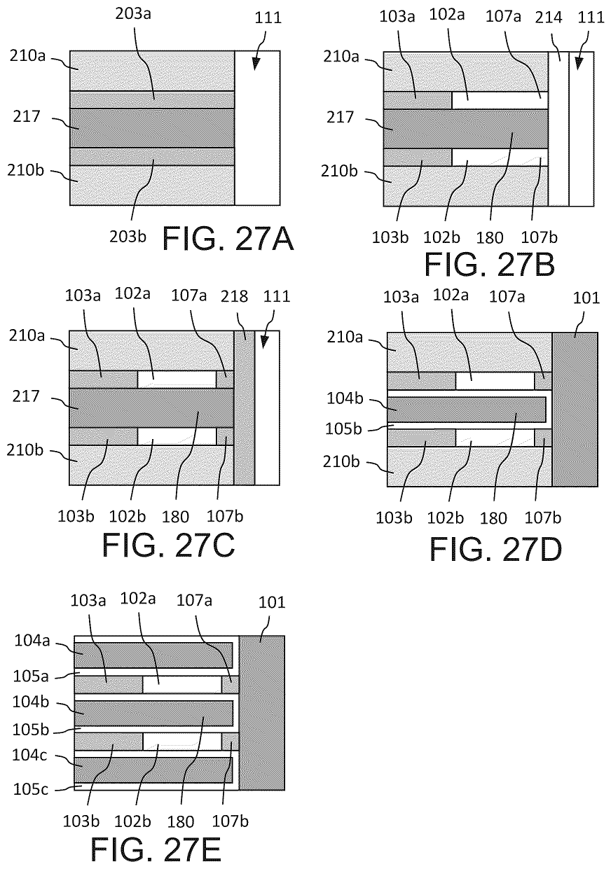

FIGS. 27A-E show embodiments of process steps performed to form the cell structure shown in FIG. 1E. These embodiments are similar to the embodiments shown in FIGS. 4A-K except that the even and odd sacrificial layers 110a to 110f comprise different materials. This configuration prevents the thin semiconductor layers 103a to 103g from collapsing during the process steps shown in FIG. 4H.

The process steps shown in FIGS. 27A-F are similar to the process steps shown in FIGS. 25A-F except that the semiconductor layers 203a to 203b are doped by using different process steps. In FIG. 27A, the semiconductor layers 203a and 203b are doped with the dopant concentration for the source lines by using an in-situ doping process.

FIG. 27B shows how a layer of dopant source material 214, such as boron or phosphorus containing silicon dioxide (SiO2) or called boron silicate glass (BSG) and phosphorus silicate glass (PSG), is deposited on the sidewall of the vertical bit line holes 111 by using process deposition processes, such as CVD or ALD. The dopant source material 214 has the opposite type of doping from the semiconductor layers 203a and 203b.

Next, a thermal predeposition and drive-in process is performed to cause the dopants to diffuse from the dopant source materials 214 into the semiconductor layers 203a and 203b to form the floating bodies 102a and 102b. The undoped regions of the semiconductor layers 203a and 203b become the source lines 103a and 103b.

FIG. 27C shows how the dopant source material 214 is removed using a suitable etching process, such as wet etching. Next, another layer of dopant source material 218, such as boron or phosphorus containing silicon dioxide (SiO2) or called boron silicate glass (BSG) and phosphorus silicate glass (PSG) is deposited on the sidewall of the vertical bit line holes 111 by using a suitable deposition process, such as CVD or ALD. The dopant source material 218 has the opposite type of doping from the floating bodies 102a and 102b.

Next, a thermal predeposition and drive-in process is performed to cause the dopants to diffuse from the dopant source materials 218 into the floating bodies 102a and 102b to form the drain regions 107a and 107b. Next, the process steps shown in FIGS. 26E-F are performed to form the gates 104a to 104c, as shown in FIGS. 27D-E.

It should be noted that the embodiments of the process steps shown in FIGS. 25A-27E use solid-phase doping processes as an example. In other embodiments, the process steps utilize gas-phase doping, such as plasma doping or liquid-phase doping as shown in FIG. 4C. These variations and modifications shall remain within the scope of the invention.

While exemplary embodiments of the present invention have been shown and described, it will be obvious to those with ordinary skills in the art that based upon the teachings herein, changes and modifications may be made without departing from the exemplary embodiments and their broader aspects. Therefore, the appended claims are intended to encompass within their scope all such changes and modifications as are within the true spirit and scope of the exemplary embodiments of the present invention.

What is claimed is:

1. A method for forming a cell structure, comprising:
forming a stack comprising alternating layers of a first material and a second material;
forming a hole through the alternating layers of the stack;
removing portions of the layers of the second material around the hole to form recesses in the second material around the hole;
filling the recesses with a third material; and
diffusing dopants from the second material into the first material while the third material acts as a hard mask.

2. The method of claim 1, wherein the operation of forming the stack comprises:
alternately depositing semiconductor layers as the first material and dopant-containing layers as the second material to form the stack.

3. The method of claim 2, wherein the semiconductor layers comprise amorphous silicon material, the dopant-containing layers comprise phosphorus silicate glass (PSG) material, and the third material comprises an oxide material.

4. The method of claim 1, wherein the operation of forming the hole comprises:
etching the hole through the alternating layers of the stack.

5. The method of claim 2, wherein the operation of removing portions of the layers of the second material comprises:
etching, through the hole, the dopant-containing layers, to form the recesses in the dopant-containing layers around the hole.

6. The method of claim 3, wherein the operation of filling the recesses comprises:
depositing the oxide material to fill the recesses and at least partially fill the hole.

7. The method of claim 2, wherein the operation of diffusing dopants comprises:
performing a thermal pre-deposition and drive-in process to diffuse the dopants from the dopant-containing layers into the semiconductor layers while the oxide material acts as a hard mask.

8. A cell structure, comprising:
a stack comprising alternating layers of a first material and a second material;
a hole through the alternating layers of the stack;
recesses in the second material around the hole;
a third material filling the recesses; and
dopants diffused from the second material into the first material while the third material acts as a hard mask.

9. The cell structure of claim 8, wherein the first material comprises semiconductor layers and the second material comprises dopant-containing layers.

10. The cell structure of claim 9, wherein the semiconductor layers comprise amorphous silicon material, the dopant-containing layers comprise phosphorus silicate glass (PSG) material, and the third material comprises an oxide material.

11. The cell structure of claim 8, wherein the dopants are diffused using a thermal pre-deposition and drive-in process.

12. A cell structure formed by a process of:
forming a stack comprising alternating layers of a first material and a second material;
forming a hole through the alternating layers of the stack;
removing portions of the layers of the second material around the hole to form recesses in the second material around the hole;
filling the recesses with a third material; and
diffusing dopants from the second material into the first material while the third material acts as a hard mask.

13. A method for forming a cell structure, comprising:
forming a stack comprising alternating layers of a first material and a second material;
forming a hole through the alternating layers of the stack;
removing portions of the layers of the second material around the hole to form recesses in the second material around the hole;
filling the recesses with a third material; and
diffusing dopants from the third material into the first material.

14. The method of claim 13, wherein the operation of forming the stack comprises:
alternately depositing semiconductor layers as the first material and sacrificial layers as the second material to form the stack.

15. The method of claim 14, wherein the semiconductor layers comprise amorphous silicon material and the sacrificial layers comprise oxide material.

16. The method of claim 13, wherein the operation of forming the hole comprises:
etching the hole through the alternating layers of the stack.

17. The method of claim 13, wherein the operation of removing portions of the layers of the second material comprises:
etching, through the hole, the sacrificial layers, to form the recesses in the sacrificial layers around the hole.

18. The method of claim 13, wherein the operation of filling the recesses comprises:
depositing dopant containing material to fill the recesses.

19. The method of claim 18, wherein the dopant containing material comprises a phosphorus silicate glass (PSG) material.

20. The method of claim 13, wherein the operation of diffusing dopants comprises:
performing a thermal pre-deposition and drive-in process to diffuse the dopants from the dopant-containing material into the semiconductor layers.

21. A cell structure, comprising:
a stack comprising alternating layers of a first material and a second material;
a hole through the alternating layers of the stack;
recesses in the second material around the hole;
a third material filling the recesses; and
dopants diffused from the third material into the first material.

22. The cell structure of claim 21, wherein the first material comprises semiconductor layers and the second material comprises sacrificial layers.

23. The cell structure of claim 22, wherein the semiconductor layers comprise amorphous silicon material, the sacrificial layers comprise oxide and the third material comprises phosphorus silicate glass (PSG) material.

24. The cell structure of claim 21, wherein the dopants are diffused using a thermal pre-deposition and drive-in process.

25. A cell structure formed by a process of:
forming a stack comprising alternating layers of a first material and a second material;
forming a hole through the alternating layers of the stack;
removing portions of the layers of the second material around the hole to form recesses in the second material around the hole;
filling the recesses with a third material; and
diffusing dopants from the third material into the first material.
